(19) United States
(12) Patent Application Publication
(10) Pub. No.: US 2022/0137513 A1
(43) Pub. Date: May 5, 2022

(54) PHOTOSENSITIVE TRANSFER FILM, MANUFACTURING METHOD OF ANTISTATIC PATTERN, MANUFACTURING METHOD OF PHOTOSENSITIVE TRANSFER FILM, LAMINATE, TOUCH PANEL, MANUFACTURING METHOD OF TOUCH PANEL, AND DISPLAY DEVICE WITH TOUCH PANEL

(71) Applicant: FUJIFILM CORPORATION, Tokyo (JP)

(72) Inventors: Tatsuya SHIMOYAMA, Fujinomiya-shi (JP); Keigo UEKI, Fujinomiya-shi (JP)

(21) Appl. No.: 17/475,356

(22) Filed: Sep. 15, 2021

Related U.S. Application Data
(63) Continuation of application No. PCT/JP2020/012526, filed on Mar. 19, 2020.

(30) Foreign Application Priority Data
Mar. 28, 2019 (JP) 2019-064595
May 14, 2019 (JP) 2019-091114
Sep. 26, 2019 (JP) 2019-175547

(51) Int. Cl. G03F 7/09; G06F 3/044; G03F 7/00; G03F 7/038

(52) U.S. Cl. CPC G03F 7/093; G06F 3/0445; G06F 2203/04103; G03F 7/038; G03F 7/0007

(57) ABSTRACT

Provided are a photosensitive transfer film including, in the following order, a photosensitive layer having a thickness of 10 μm or less and an antistatic layer, in which the photosensitive layer contains an alkali-soluble acrylic resin, a radically polymerizable compound having an ethylenically unsaturated group, and a photopolymerization initiator; and applications thereof.

### CROSS-REFERENCE TO RELATED APPLICATIONS

This application is a continuation application of International Application No. PCT/JP2020/012526, filed Mar. 19, 2020, the disclosure of which is incorporated herein by reference in its entirety. Further, this application claims priority from Japanese Patent Application No. 2019-064595, filed Mar. 28, 2019, Japanese Patent Application No. 2019-091114, filed May 14, 2019, and Japanese Patent Application No. 2019-175547, filed Sep. 26, 2019, the disclosures of which are incorporated herein by reference in their entireties.

### BACKGROUND OF THE INVENTION

### 1. Field of the Invention

The present disclosure relates to a photosensitive transfer film, a manufacturing method of an antistatic pattern, a manufacturing method of a photosensitive transfer film, a laminate, a touch panel, a manufacturing method of a touch panel, and a display device with a touch panel.

### 2. Description of the Related Art

In photolithography, various antistatic techniques have been studied.

JP2016-118727A discloses a protective film for a dry film resist including, on one surface of a polyester film, a coating layer formed from a coating liquid containing a long-chain alkyl group-containing compound, an antistatic agent, and an acrylic resin or polyvinyl alcohol, in which the maximum protrusion height (Rt) of a surface of the coating layer is 0.1 to 1.0 μm; and a photosensitive resin laminate having a configuration in which the protective film is laminated on a surface of a photosensitive resin layer formed on a base film.

JP2016-80964A discloses a forming method of a resist pattern, including a lamination step of applying a conductive composition to a surface of a substrate, which has a resist layer consisting of a negative type chemically amplified resist on one side, on the resist layer side to form an antistatic film, in which a negative resist film thinning rate is 0% to 12%.

JP2005-321716A discloses a dry film obtained by laminating a photosensitive resin layer (1) having antistatic properties or conductivity and a photosensitive resin layer (2) having insulating properties.

### SUMMARY OF THE INVENTION

In a resist pattern formed by using a dry film (also referred to as a photosensitive transfer film), in addition to its role as a mask in a development step, the resist pattern may be used, for example, as an electrode protective film. Therefore, it is required to prevent charging in the above-described resist pattern. In a case of preventing charge of a member having a predetermined shape, such as the above-described resist pattern, for example, in a case where an antistatic layer is formed in a region where antistatic is not required, desired electrical characteristics may not be obtained due to flow of electricity through the antistatic layer. In addition, in the resist pattern formed by using the dry film, transparency and bend resistance are also required.

However, for example, in the photosensitive resin laminate described in JP2016-118727A, since the protective film includes the antistatic agent, it is not possible to selectively form the antistatic layer for a region where antistatic is required. In addition, also in the prior art as described in JP2016-80964A and JP2005-321716A, there is room for improvement in that the antistatic layer is formed in a predetermined region where antistatic is required, and a cured film having excellent transparency and bend resistance is formed.

An object of one aspect of the present disclosure is to provide a photosensitive transfer film in which an antistatic layer can be patterned and a cured film having excellent transparency and bend resistance can be formed.

An object of another aspect of the present disclosure is to provide a manufacturing method of an antistatic pattern having excellent transparency and bend resistance, in which patterning properties of an antistatic layer are excellent.

An object of another aspect of the present disclosure is to provide a manufacturing method of a photosensitive transfer film, in which an antistatic layer can be patterned and a cured film having excellent transparency and bend resistance can be formed.

An object of another aspect of the present disclosure is to provide a laminate capable of preventing charging of a patterned electrode protective film.

An object of another aspect of the present disclosure is to provide a touch panel which includes a laminate capable of preventing charging of a patterned electrode protective film.

An object of another aspect of the present disclosure is to provide a manufacturing method of a touch panel, in which charging of a patterned electrode protective film can be prevented and discoloration of a lead wire can be suppressed.

An object of another aspect of the present disclosure is to provide a display device with a touch panel, which includes a laminate capable of preventing charging of a patterned electrode protective film.

Methods for achieving the objects described above include the following aspects.

<1> A photosensitive transfer film comprising:

a photosensitive layer having a thickness of 10 μm or less; and

an antistatic layer,

in which the photosensitive layer contains an alkali-soluble acrylic resin, a radically polymerizable compound having an ethylenically unsaturated group, and a photopolymerization initiator.

<2> The photosensitive transfer film according to <1>,

in which a transparent film 1, the photosensitive layer, the antistatic layer, and a transparent film 2 are provided in this order.

<3> The photosensitive transfer film according to <1> or <2>,

in which a surface electrical resistance value of the antistatic layer is 1.0×10¹²Ω/□ or less.

<4> The photosensitive transfer film according to any one of <1> to <3>,

in which an acid value of the alkali-soluble acrylic resin is 60 mgKOH/g or more.

<5> The photosensitive transfer film according to any one of <1> to <4>,

in which a thickness of the antistatic layer is 0.4 μm or less.

<6> The photosensitive transfer film according to any one of <1> to <5>,

in which the antistatic layer contains, as an antistatic agent, at least one compound selected from the group consisting of an ionic liquid, an ionic conductive polymer, an ionic conductive filler, and an electrically conductive polymer.

<7> The photosensitive transfer film according to any one of <1> to <6>,

in which an antistatic agent is not detected in a region from a surface of the photosensitive layer opposite to the antistatic layer to 40% of a total thickness of the photosensitive layer and the antistatic layer.

<8> A manufacturing method of an antistatic pattern comprising, in the following order:

a step of laminating the photosensitive layer and the antistatic layer of the photosensitive transfer film according to any one of <1> to <7> on a base material in this order;

a step of performing a pattern exposure of the photosensitive layer; and

a step of developing the photosensitive layer.

<9> A manufacturing method of the photosensitive transfer film according to <2>, comprising:

a step of applying a composition for the antistatic layer and a composition for the photosensitive layer on the transparent film 2 in this order.

<10> A laminate comprising, in the following order:

a base material;

a transparent electrode layer;

a cured composition layer of a photosensitive composition, which has a patterned shape; and

an antistatic layer having the same patterned shape as the patterned shape of the cured composition layer.

<11> The laminate according to <10>,

in which a surface electrical resistance value of the antistatic layer is 1.0×10¹²Ω/□ or less.

<12> The laminate according to <10> or <11>,

in which a thickness of the antistatic layer is 0.4 μm or less.

<13> The laminate according to any one of <10> to <12>,

in which the antistatic layer contains, as an antistatic agent, at least one compound selected from the group consisting of an ionic liquid, an ionic conductive polymer, an ionic conductive filler, and an electrically conductive polymer.

<14> The laminate according to any one of <10> to <13>,

in which a thickness of the cured composition layer is 10 μm or less.

<15> The laminate according to any one of <10> to <14>,

in which an antistatic agent is not detected in a region from a surface of the cured composition layer opposite to the antistatic layer to 40% of a total thickness of the cured composition layer and the antistatic layer.

<16> The laminate according to any one of <10> to <15>,

in which the transparent electrode layer is a layer containing a silver nanowire.

<17> A touch panel comprising:
the laminate according to any one of <10> to <16>.

<18> A manufacturing method of a touch panel, comprising in the following order:

a step of preparing a base material;

a step of forming a transparent electrode for a touch panel on the base material using a silver conductive material;

a step of forming a metal layer on the transparent electrode for a touch panel;

a step of treating the metal layer with a treatment liquid containing at least one azole compound selected from the group consisting of an imidazole compound, a triazole compound, a tetrazole compound, a thiazole compound, and a thiadiazole compound;

a step of forming a lead wire from the metal layer;

a step of laminating the photosensitive layer and the antistatic layer of the photosensitive transfer film according to any one of <1> to <7> on a surface of the base material on a side where the lead wire and the transparent electrode for a touch panel are arranged;

a step of performing a pattern exposure of the photosensitive layer and the antistatic layer; and

a step of developing the photosensitive layer and the antistatic layer to form a pattern.

<19> A manufacturing method of a touch panel, comprising in the following order:

a step of preparing a base material;

a step of forming a metal layer on the base material;

a step of treating the metal layer with a treatment liquid containing at least one azole compound selected from the group consisting of an imidazole compound, a triazole compound, a tetrazole compound, a thiazole compound, and a thiadiazole compound;

a step of forming a lead wire from the metal layer;

a step of forming a transparent electrode for a touch panel on the lead wire using a silver conductive material;

a step of laminating the photosensitive layer and the antistatic layer of the photosensitive transfer film according to any one of <1> to <7> on a surface of the base material on a side where the lead wire and the transparent electrode for a touch panel are arranged;

a step of performing a pattern exposure of the photosensitive layer and the antistatic layer; and

a step of developing the photosensitive layer and the antistatic layer to form a pattern.

<20> The manufacturing method of a touch panel according to <18> or <19>,

in which a pKa of a conjugate acid of the at least one azole compound selected from the group consisting of the imidazole compound, the triazole compound, the tetrazole compound, the thiazole compound, and the thiadiazole compound is 4.00 or less.

<21> A display device with a touch panel, comprising:

the touch panel according to <17>; and

a display device.

According to one aspect of the present disclosure, a photosensitive transfer film in which an antistatic layer can be patterned and a cured film having excellent transparency and bend resistance can be formed is provided.

According to another aspect of the present disclosure, a manufacturing method of an antistatic pattern having excellent transparency and bend resistance, in which patterning properties of an antistatic layer are excellent, is provided.

According to another aspect of the present disclosure, a manufacturing method of a photosensitive transfer film, in which an antistatic layer can be patterned and a cured film having excellent transparency and bend resistance can be formed, is provided.

According to another aspect of the present disclosure, a laminate capable of preventing charging of a patterned electrode protective film is provided.

According to another aspect of the present disclosure, a touch panel which includes a laminate capable of preventing charging of a patterned electrode protective film is provided.

According to another aspect of the present disclosure, a manufacturing method of a touch panel, in which charging of a patterned electrode protective film can be prevented and discoloration of a lead wire can be suppressed, is provided.

According to another aspect of the present disclosure, a display device with a touch panel, which includes a laminate capable of preventing charging of a patterned electrode protective film, is provided.

### BRIEF DESCRIPTION OF THE DRAWINGS

FIG. 1 is a schematic cross sectional view showing an example of a transfer film according to an embodiment of the present disclosure.

FIG. 2 is a schematic cross sectional view showing a first specific example of a touch panel according to an embodiment of the present disclosure.

FIG. 3 is a schematic cross sectional view showing a second specific example of a touch panel according to an embodiment of the present disclosure.

FIG. 4 is a schematic cross-sectional view showing an example of a state of a bending resistance evaluation sample in a bending resistance evaluation.

### DESCRIPTION OF THE PREFERRED EMBODIMENTS

Hereinafter, the content of the present disclosure will be described in detail. The configuration requirements will be described below based on the representative embodiments of the present disclosure, but the present disclosure is not limited to such embodiments.

In the present disclosure, the numerical ranges shown using “to” means ranges including the numerical values described before and after “to” as the minimum value and the maximum value.

In a numerical range described in a stepwise manner in the present disclosure, an upper limit value or a lower limit value described in a certain numerical range may be replaced with an upper limit value or a lower limit value in another numerical range described in a stepwise manner. In addition, in a numerical range described in the present disclosure, an upper limit value or a lower limit value described in a certain numerical range may be replaced with a value described in Examples.

In the present disclosure, a combination of two or more preferable aspects is the more preferable aspect.

Regarding a term, group (so-called atomic group) of the present disclosure, a term with no description of “substituted” and “unsubstituted” includes both a group not including a substituent and a group including a substituent. For example, an “alkyl group” not only includes an alkyl group not including a substituent (so-called unsubstituted alkyl group), but also an alkyl group including a substituent (so-called substituted alkyl group).

In the present disclosure, “(meth)acrylic acid” has a concept including both acrylic acid and a methacrylic acid, “(meth)acrylate” has a concept including both acrylate and methacrylate, “(meth)acryloyl group” has a concept including both acryloyl group and methacryloyl group, and “(meth)acryloxy group” has a concept including both acryloxy group and methacryloxy group.

In the present disclosure, a “total solid content” means a total mass of components obtained by removing a solvent from the whole composition of the composition. In addition, a “solid content” is a component obtained by removing a solvent as described above, and for example, the component may be solid or may be liquid at 25° C.

In the present disclosure, in a case where a plurality of substances corresponding to components are present in a composition, an amount of each component in the composition means a total amount of the plurality of substances present in the composition, unless otherwise noted.

In the present disclosure, a term “step” includes not only the independent step but also a step in which intended purposes are achieved even in a case where the step cannot be precisely distinguished from other steps.

In the present disclosure, the molecular weight, in a case where there is a molecular weight distribution, represents the weight-average molecular weight (Mw), unless otherwise noted.

A weight-average molecular weight (Mw) of the present disclosure, unless otherwise noted, is detected by a gel permeation chromatography (GPC) analysis apparatus using a column of TSKgel (registered trademark) GMHxL, TSKgel (registered trademark) G4000HxL, TSKgel (registered trademark) G2000HxL (all product names, manufactured by Tosoh Corporation), by using tetrahydrofuran (THF) as an eluent and a differential refractive index (RI) detector, and is a molecular weight obtained by conversion using polystyrene as a standard substance.

In the present disclosure, unless otherwise noted, a proportion of each constitutional unit in a polymer is a molar proportion.

In the present disclosure, “light” is a concept including active energy rays such as γ-rays, β-rays, electron beams, ultraviolet rays, visible rays, and infrared rays.

In the present disclosure, “transparent” means that the total light transmittance at a wavelength of 380 nm to 780 nm at a temperature of 23° C. is 85% or more (preferably 90% or more and more preferably 95% or more). The above-described total light transmittance is measured using a spectrophotometer [for example, a spectrophotometer “U-3310 (product name) manufactured by Hitachi, Ltd.].

The “refractive index” in the present disclosure means a value measured with visible light at a wavelength of 550 nm at a temperature of 23° C. by an ellipsometry method, unless otherwise noted.

In the present disclosure, a number added to the end of a term “transparent film” is a reference numeral for preventing confusion of components, and does not limit the number of components and the superiority or inferiority of the components.

<Photosensitive Transfer Film>

The photosensitive transfer film according to the embodiment of the present disclosure includes a photosensitive layer having a thickness of 10 μm or less and an antistatic layer, in which the photosensitive layer contains an alkali-soluble acrylic resin, a radically polymerizable compound having an ethylenically unsaturated group, and a photopolymerization initiator.

Since the photosensitive transfer film according to the embodiment of the present disclosure includes the above-described configuration, an antistatic layer can be patterned and a cured film having excellent transparency and bend resistance can be formed. The reason why the photosensitive transfer film according to the embodiment of the present disclosure exerts the above-described effects is not clear, but it is presumed as follows.

Since the photosensitive transfer film according to the embodiment of the present disclosure includes a photosensitive layer having a thickness of 10 μm or less and an antistatic layer, in which the photosensitive layer contains an alkali-soluble acrylic resin, a radically polymerizable compound having an ethylenically unsaturated group, and a photopolymerization initiator, it is considered that the antistatic layer can be patterned together with the photosensitive layer, and the transparency and bending resistance of the photosensitive layer cured by exposure can be improved. Therefore, in the photosensitive transfer film according to the embodiment of the present disclosure, the antistatic layer can be patterned and a cured film having excellent transparency and bend resistance can be formed.

In addition, with the photosensitive transfer film according to the embodiment of the present disclosure, since the antistatic layer can be patterned together with the photosensitive layer, in a case where the formed resist pattern is used as an electrode protective film, charging can be prevented even in the patterned electrode protective film.

[Photosensitive Layer]

The photosensitive transfer film according to the embodiment of the present disclosure includes a photosensitive layer having a thickness of 10 μm or less. In the photosensitive transfer film according to the embodiment of the present disclosure, the photosensitive layer contains an alkali-soluble acrylic resin, a radically polymerizable compound having an ethylenically unsaturated group, and a photopolymerization initiator. In the photosensitive transfer film according to the embodiment of the present disclosure, since the thickness of the photosensitive layer is 10 μm or less, and the photosensitive layer contains the alkali-soluble acrylic resin and the like, transparency and bend resistance of a cured film to be formed are improved.

(Alkali-Soluble Acrylic Resin)

The photosensitive layer contains an alkali-soluble acrylic resin. Since the photosensitive layer contains the alkali-soluble acrylic resin, transparency of a cured film to be formed is improved. In addition, since the photosensitive layer contains the alkali-soluble acrylic resin, solubility of the photosensitive layer (unexposed portion) in a developer can also be improved.

In the present disclosure, “alkali-soluble” means that the dissolution rate obtained by the following method is 0.01 μm/sec or more.

A propylene glycol monomethyl ether acetate solution having a concentration of a target compound (for example, a resin) of 25% by mass is applied to a glass substrate, and then heated in an oven at 100° C. for 3 minutes to obtain a coating film (thickness: 2.0 μm) of the compound. The above-described coating film is immersed in a 1% by mass aqueous solution of sodium carbonate (liquid temperature: 30° C.), thereby obtaining the dissolution rate (μm/sec) of the above-described coating film.

In a case where the target compound is not dissolved in propylene glycol monomethyl ether acetate, the target compound is dissolved in an organic solvent (for example, tetrahydrofuran, toluene, and ethanol) having a boiling point of lower than 200° C., other than propylene glycol monomethyl ether acetate.

The alkali-soluble acrylic resin is not limited as long as it is the alkali-soluble acrylic resin described above. Here, “acrylic resin” means a resin containing at least one of a constitutional unit derived from (meth)acrylic acid or a constitutional unit derived from (meth)acrylic acid ester.

The total proportion of the constitutional unit derived from (meth)acrylic acid and the constitutional unit derived from (meth)acrylic acid ester in the alkali-soluble acrylic resin is preferably 30 mol % or more and more preferably 50 mol % or more with respect to the total amount of the alkali-soluble acrylic resin. The upper limit of the total proportion of the constitutional unit derived from (meth)acrylic acid and the constitutional unit derived from (meth)acrylic acid ester in the alkali-soluble acrylic resin is not limited. The total proportion of the constitutional unit derived from (meth)acrylic acid and the constitutional unit derived from (meth)acrylic acid ester in the alkali-soluble acrylic resin is determined in a range of 100 mol % or less with respect to the total amount of the alkali-soluble acrylic resin.

In the present disclosure, in a case where the content of “constitutional unit” is specified by mole fraction (molar proportion), the above-described “constitutional unit” is synonymous with “monomer unit” unless otherwise specified. In addition, in the present disclosure, in a case where a resin or polymer has two or more specific constitutional units, the content of the specific constitutional units indicates the total content of the two or more specific constitutional units unless otherwise specified.

From the viewpoint of developability, the alkali-soluble acrylic resin preferably has a carboxy group. Examples of a method for introducing the carboxy group into the alkali-soluble acrylic resin include a method of synthesizing an alkali-soluble acrylic resin using a monomer having a carboxy group. By the above-described method, the monomer having a carboxy group is introduced into the alkali-soluble acrylic resin as a constitutional unit having a carboxy group. Examples of the monomer having a carboxy group include acrylic acid and methacrylic acid.

The alkali-soluble acrylic resin may have one carboxy group or two or more carboxy groups. In addition, the alkali-soluble acrylic resin may have one constitutional unit having a carboxy group alone, or two or more kinds thereof.

In a case where the alkali-soluble acrylic resin has a constitutional unit having a carboxy group, the content of the constitutional unit having a carboxy group is preferably 5 mol % to 50 mol %, more preferably 5 mol % to 40 mol %, and particularly preferably 10 mol % to 30 mol % with respect to the total amount of the alkali-soluble acrylic resin.

From the viewpoint of moisture permeability and hardness after curing, the alkali-soluble acrylic resin preferably has a constitutional unit having an aromatic ring. The constitutional unit having an aromatic ring is preferably a constitutional unit derived from a styrene compound.

Examples of a monomer forming the constitutional unit having an aromatic ring include a monomer forming a constitutional unit derived from a styrene compound and benzyl (meth)acrylate.

Examples of the above-described monomer forming a constitutional unit derived from a styrene compound include styrene, p-methylstyrene, α-methylstyrene, α,p-dimethylstyrene, p-ethylstyrene, p-t-butylstyrene, t-butoxystyrene, and 1,1-diphenylethylene, and styrene or α-methylstyrene is preferable and styrene is more preferable.

The alkali-soluble acrylic resin may have one constitutional unit having an aromatic ring alone, or two or more kinds thereof.

In a case where the alkali-soluble acrylic resin has a constitutional unit having an aromatic ring, the content of the constitutional unit having an aromatic ring is preferably 5 mol % to 90 mol %, more preferably 10 mol % to 90 mol %, and particularly preferably 15 mol % to 90 mol % with respect to the total amount of the alkali-soluble acrylic resin.

From the viewpoint of tackiness and hardness after curing, the alkali-soluble acrylic resin preferably includes a constitutional unit having an aliphatic cyclic skeleton.

Examples of an aliphatic ring in the aliphatic cyclic skeleton include a dicyclopentane ring, a cyclohexane ring, an isophorone ring, and a tricyclodecane ring. Among the above, a tricyclodecane ring is particularly preferable as the aliphatic ring in the aliphatic cyclic skeleton.

Examples of a monomer forming the constitutional unit having an aliphatic cyclic skeleton include dicyclopentanyl (meth)acrylate, cyclohexyl (meth)acrylate, and isobornyl (meth)acrylate.

The alkali-soluble acrylic resin may have one constitutional unit having an aliphatic cyclic skeleton alone, or two or more kinds thereof.

In a case where the alkali-soluble acrylic resin has a constitutional unit having an aliphatic cyclic skeleton, the content of the constitutional unit having an aliphatic cyclic skeleton is preferably 5 mol % to 90 mol %, more preferably 10 mol % to 80 mol %, and particularly preferably 10 mol % to 70 mol % with respect to the total amount of the alkali-soluble acrylic resin.

From the viewpoint of tackiness and hardness after curing, the alkali-soluble acrylic resin preferably has a reactive group.

As the reactive group, a radically polymerizable group is preferable, and an ethylenically unsaturated group is more preferable. In addition, in a case where the alkali-soluble acrylic resin has an ethylenically unsaturated group, the alkali-soluble acrylic resin preferably has a constitutional unit having an ethylenically unsaturated group in a side chain.

In the present disclosure, the “main chain” represents a relatively longest binding chain in a molecule of a polymer compound constituting a resin, and the “side chain” represents an atomic group branched from the main chain.

The ethylenically unsaturated group is preferably a (meth)acryloyl group or a (meth)acryloxy group and more preferably a (meth)acryloxy group.

The alkali-soluble acrylic resin may have one constitutional unit having an ethylenically unsaturated group alone, or two or more kinds thereof.

In a case where the alkali-soluble acrylic resin has a constitutional unit having an ethylenically unsaturated group, the content of the constitutional unit having an ethylenically unsaturated group is preferably 5 mol % to 70 mol %, more preferably 10 mol % to 50 mol %, and particularly preferably 15 mol % to 40 mol % with respect to the total amount of the alkali-soluble acrylic resin.

Examples of a method for introducing the reactive group into the alkali-soluble acrylic resin include a method of reacting an epoxy compound, a blocked isocyanate compound, an isocyanate compound, a vinyl sulfone compound, an aldehyde compound, a methylol compound, a carboxylic acid anhydride, or the like with a hydroxyl group, a carboxy group, a primary amino group, a secondary amino group, an acetoacetyl group, a sulfonic acid group, or the like.

Preferred examples of the method for introducing the reactive group into the alkali-soluble acrylic resin include a method in which an alkali-soluble acrylic resin having a carboxy group is synthesized by a polymerization reaction, and then a glycidyl (meth)acrylate is reacted with a part of the carboxy group of the alkali-soluble acrylic resin by a polymer reaction, thereby introducing a (meth)acryloxy group into the alkali-soluble acrylic resin. By the above-described method, an alkali-soluble acrylic resin having a (meth)acryloxy group in the side chain can be obtained.

The above-described polymerization reaction is preferably carried out under a temperature condition of 70° C. to 100° C., and more preferably carried out under a temperature condition of 80° C. to 90° C. As a polymerization initiator used in the above-described polymerization reaction, an azo-based initiator is preferable, and for example, V-601 (product name) or V-65 (product name) manufactured by FUJIFILM Wako Pure Chemical Corporation is more preferable. In addition, the above-described polymer reaction is preferably carried out under a temperature condition of 80° C. to 110° C. In the above-described polymer reaction, it is preferable to use a catalyst such as an ammonium salt.

The weight-average molecular weight (Mw) of the alkali-soluble acrylic resin is preferably 10,000 or more, more preferably 10,000 to 100,000, and particularly preferably 15,000 to 50,000.

From the viewpoint of developability, the acid value of the alkali-soluble acrylic resin is preferably 50 mgKOH/g or more, more preferably 60 mgKOH/g or more, still more preferably 70 mgKOH/g or more, and particularly preferably 80 mgKOH/g or more. In the present disclosure, the acid value of the alkali-soluble acrylic resin is a value measured according to the method described in JIS K0070: 1992.

From the viewpoint of preventing exposed photosensitive layer (exposed portion) from dissolving in a developer, the acid value of the alkali-soluble acrylic resin is preferably 200 mgKOH/g or less and more preferably 150 mgKOH/g or less.

Specific examples of the alkali-soluble acrylic resin are shown below. The content ratio (molar ratio) of each constitutional unit in the following alkali-soluble acrylic resins can be appropriately set according to the purpose.

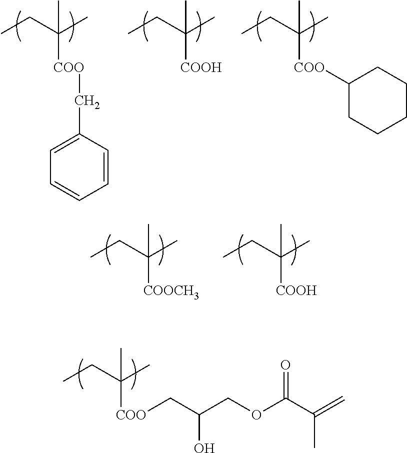

The photosensitive layer may contain only one kind of alkali-soluble acrylic resin, or may contain two or more kinds of alkali-soluble acrylic resins.

From the viewpoint of developability, the content of the alkali-soluble acrylic resin is preferably 10% by mass to 90% by mass, more preferably 20% by mass to 80% by mass, and particularly preferably 30% by mass to 70% by mass with respect to the total mass of the photosensitive layer.

From the viewpoint of patterning properties and reliability, the content of residual monomer of each constitutional unit of the alkali-soluble acrylic resin is preferably 1,000 ppm by mass or less, more preferably 500 ppm by mass or less, and particularly preferably 100 ppm by mass or less with respect to the total mass of the alkali-soluble acrylic resin. The content of the above-described residual monomer is preferably 0.1 ppm by mass or more and more preferably 1 ppm by mass or more with respect to the total mass of the alkali-soluble acrylic resin. It is preferable that the amount of residual monomer of the monomer in a case of synthesizing the alkali-soluble acrylic resin by the polymer reaction is also within the above-described range. For example, in a case where glycidyl acrylate is reacted with a carboxylic acid side chain to synthesize the alkali-soluble acrylic resin, the content of glycidyl acrylate is preferably within the above-described range. For example, the amount of the residual monomer can be measured by a known method such as gas chromatography.

(Radically Polymerizable Compound Having Ethylenically Unsaturated Group)

The photosensitive layer contains a radically polymerizable compound having an ethylenically unsaturated group (hereinafter, also simply referred to as an “ethylenically unsaturated compound”). The ethylenically unsaturated compound contributes to photosensitivity (that is, photocuring properties) and hardness of a cured film formed by curing the photosensitive layer.

As the ethylenically unsaturated group, a (meth)acryloyl group is preferable.

The ethylenically unsaturated compound preferably includes a bi- or higher functional ethylenically unsaturated compound. Here, the “bi- or higher functional ethylenically unsaturated compound” means a compound having two or more ethylenically unsaturated groups in one molecule.

As the ethylenically unsaturated compound, a (meth)acrylate compound is preferable.

From the viewpoint of film hardness after curing, for example, the ethylenically unsaturated compound preferably includes a bifunctional ethylenically unsaturated compound (preferably, a bifunctional (meth)acrylate compound) and a tri- or higher functional ethylenically unsaturated compound (preferably, a tri- or higher functional (meth)acrylate compound).

The bifunctional ethylenically unsaturated compound is not limited and can be appropriately selected from a known compound. Examples of the bifunctional ethylenically unsaturated compound include tricyclodecane dimethanol di(meth)acrylate, 1,9-nonanediol di(meth)acrylate, 1,10-decandiol di(meth)acrylate, and 1,6-hexanediol di(meth)acrylate.

Examples of a commercially available product of the bifunctional ethylenically unsaturated compound include tricyclodecane dimethanol diacrylate [product name: NK ESTER A-DCP, Shin-Nakamura Chemical Co., Ltd.], tricyclodecane dimethanol dimethacrylate [product name: NK ESTER DCP, Shin-Nakamura Chemical Co., Ltd.], 1,9-nonanediol diacrylate [product name: NK ESTER A-NOD-N, Shin-Nakamura Chemical Co., Ltd.], 1,10-decanediol diacrylate [product name: NK ESTER A-DOD-N, Shin-Nakamura Chemical Co., Ltd.], and 1,6-hexanediol diacrylate [product name: NK ESTER A-HD-N, Shin-Nakamura Chemical Co., Ltd.].

The tri- or higher functional ethylenically unsaturated compound is not limited and can be appropriately selected from a known compound. Examples of the tri- or higher functional ethylenically unsaturated compound include dipentaerythritol (tri/tetra/penta/hexa)(meth)acrylate, pentaerythritol (tri/tetra)(meth)acrylate, trimethylolpropane tri(meth)acrylate, ditrimethylolpropane tetra(meth)acrylate, isocyanuric acid (meth)acrylate, and glycerin tri(meth)acrylate.

Here, the “(tri/tetra/penta/hexa)(meth)acrylate” is a concept including tri(meth)acrylate, tetra(meth)acrylate, penta(meth)acrylate, and hexa(meth)acrylate. In addition, the “(tri/tetra)(meth)acrylate” is a concept including tri(meth)acrylate and tetra(meth)acrylate.

Examples of a commercially available product of the tri- or higher functional ethylenically unsaturated compound include dipentaerythritol hexaacrylate [product name: KAYARAD DPHA, Shin-Nakamura Chemical Co., Ltd.].

The ethylenically unsaturated compound more preferably includes 1,9-nonanediol di(meth)acrylate or 1,10-decanediol di(meth)acrylate, and dipentaerythritol (tri/tetra/penta/hexa)(meth)acrylate.

Examples of the ethylenically unsaturated compound also include a caprolactone-modified compound of a (meth)acrylate compound [KAYARAD (registered trademark) DPCA-20 of Nippon Kayaku Co., Ltd., A-9300-1CL of Shin-Nakamura Chemical Co., Ltd., or the like], an alkylene oxide-modified compound of a (meth)acrylate compound [KAYARAD (registered trademark) RP-1040 of Nippon Kayaku Co., Ltd., ATM-35E or A-9300 of Shin-Nakamura Chemical Co., Ltd., EBECRYL (registered trademark) 135 of Daicel-Allnex Ltd., or the like], and ethoxylated glycerin triacrylate [NK ESTER A-GLY-9E of Shin-Nakamura Chemical Co., Ltd., or the like].

Examples of the ethylenically unsaturated compound also include a urethane (meth)acrylate compound. As the urethane (meth)acrylate compound, a tri- or higher functional urethane (meth)acrylate compound is preferable. Examples of the tri- or higher functional urethane (meth)acrylate compound include 8UX-015A [Taisei Fine Chemical Co., Ltd.], NK ESTER UA-32P [Shin-Nakamura Chemical Co., Ltd.], and NK ESTER UA-1100H [Shin-Nakamura Chemical Co., Ltd.].

From the viewpoint of improving developability, for example, the ethylenically unsaturated compound preferably includes an ethylenically unsaturated compound having an acid group.

Examples of the acid group include a phosphoric acid group, a sulfonic acid group, and a carboxy group. Among the above, as the acid group, a carboxy group is preferable.

Examples of the ethylenically unsaturated compound having an acid group include a tri- or tetra-functional ethylenically unsaturated compound having an acid group [for example, compound obtained by introducing a carboxy group to pentaerythritol tri- and tetra-acrylate (PETA) skeleton (acid value: 80 mgKOH/g to 120 mgKOH/g)), and a penta- or hexa-functional ethylenically unsaturated compound having an acid group [for example, compound obtained by introducing a carboxy group to dipentaerythritol penta- and hexa-acrylate (DPHA) skeleton (acid value: 25 mgKOH/g to 70 mgKOH/g)]. The tri- or higher functional ethylenically unsaturated compound having an acid group may be used in combination with the bifunctional ethylenically unsaturated compound having an acid group, as necessary.

As the ethylenically unsaturated compound having an acid group, at least one compound selected from the group consisting of bi- or higher functional ethylenically unsaturated compound having a carboxy group and a carboxylic acid anhydride thereof is preferable. In a case where the ethylenically unsaturated compound having an acid group is at least one compound selected from the group consisting of bi- or higher functional ethylenically unsaturated compound having a carboxy group and a carboxylic acid anhydride thereof, developability and film hardness are further enhanced.

The bi- or higher functional ethylenically unsaturated compound having a carboxy group is not limited and can be appropriately selected from a known compound. Preferred examples of the bi- or higher functional ethylenically unsaturated compound having a carboxy group include ARONIX (registered trademark) TO-2349 [Toagosei Co., Ltd.], ARONIX (registered trademark) M-520 [Toagosei Co., Ltd.], and ARONIX (registered trademark) M-510 [Toagosei Co., Ltd.].

As the ethylenically unsaturated compound having an acid group, polymerizable compounds having an acid group, which are described in paragraphs “0025” to “0030” of JP2004-239942A, can be preferably used, and the contents described in this publication are incorporated in the present disclosure by reference.

The molecular weight of the ethylenically unsaturated compound is preferably 200 to 3,000, more preferably 250 to 2,600, still more preferably 280 to 2,200, and particularly preferably 300 to 2,200.

Among ethylenically unsaturated compounds in the photosensitive layer, the content of ethylenically unsaturated compound having a molecular weight of 300 or less is preferably 30% by mass or less, more preferably 25% by mass or less, and particularly preferably 20% by mass or less with respect to the content of all the ethylenically unsaturated compounds contained in the photosensitive layer. The content of ethylenically unsaturated compound having a molecular weight of 300 or less may be 0% by mass or may exceed 0% by mass with respect to the content of all the ethylenically unsaturated compounds contained in the photosensitive layer.

The photosensitive layer may contain only one kind of ethylenically unsaturated compound, or may contain two or more kinds of ethylenically unsaturated compounds.

The content of the ethylenically unsaturated compound is preferably 1% by mass to 70% by mass, more preferably 10% by mass to 70% by mass, still more preferably 20% by mass to 60% by mass, and particularly preferably 20% by mass to 50% by mass with respect to the total mass of the photosensitive layer.

In a case where the photosensitive layer contains a bi- or higher functional ethylenically unsaturated compound, the photosensitive layer may further contain a monofunctional ethylenically unsaturated compound.

In a case where the photosensitive layer contains a bi- or higher functional ethylenically unsaturated compound, it is preferable that the bi- or higher functional ethylenically unsaturated compound is a main component of ethylenically unsaturated compounds contained in the photosensitive layer.

In a case where the photosensitive layer contains a bi- or higher functional ethylenically unsaturated compound, the content of the bi- or higher functional ethylenically unsaturated compound is preferably 60% by mass to 100% by mass, more preferably 80% by mass to 100% by mass, and particularly preferably 90% by mass to 100% by mass with respect to the content of all the ethylenically unsaturated compounds contained in the photosensitive layer.

In a case where the photosensitive layer contains the ethylenically unsaturated compound having an acid group (preferably, bi- or higher functional ethylenically unsaturated compound having a carboxy group or a carboxylic acid anhydride thereof), the content of the ethylenically unsaturated compound having an acid group is preferably 1% by mass to 50% by mass, more preferably 1% by mass to 20% by mass, and still more preferably 1% by mass to 10% by mass with respect to the total mass of the photosensitive layer.

(Photopolymerization Initiator)

The photosensitive layer contains a photopolymerization initiator.

The photopolymerization initiator is not limited and a known photopolymerization initiator can be adopted. Examples of the photopolymerization initiator include a photopolymerization initiator having an oxime ester structure (hereinafter, also referred to as an “oxime-based photopolymerization initiator”), a photopolymerization initiator having an α-aminoalkylphenone structure (hereinafter, also referred to as an “α-aminoalkylphenone-based photopolymerization initiator”), a photopolymerization initiator having an α-hydroxyalkylphenone structure (hereinafter also referred to as an “α-hydroxyalkylphenone-based photopolymerization initiator”), a photopolymerization initiator having an acylphosphine oxide structure, (hereinafter, also referred to as an “acylphosphine oxide-based photopolymerization initiator”), and a photopolymerization initiator having an N-phenylglycine structure (hereinafter, also referred to as an N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based photopolymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators disclosed in paragraphs “0031” to “0042” of JP2011-95716A and paragraphs “0064” to “0081” of JP2015-014783A may be used.

Examples of a commercially available product of the photopolymerization initiator include 1-[4-(phenylthio)]phenyl-1,2-octanedione-2-(O-benzoyloxime) [product name: IRGACURE (registered trademark) OXE-01, manufactured by BASF SE], 1-[9-ethyl-6-(2-methylbenzoyl)-9H-carbazol-3-yl]ethanone-1-(O-acetyloxime) [product name: IRGACURE (registered trademark) OXE-02, manufactured by BASF SE], [8-[5-(2,4,6-trimethylphenyl)-11-(2-ethylhexyl)-11H-benzo[a]carbazoyl][2-(2,2,3,3-tetrafluoro propoxy)phenyl]methanone-(O-acetyloxime) [product name: IRGACURE (registered trademark) OXE-03, manufactured by BASF SE], 1-[4-[4-(2-benzofuranylcarbonyl)phenyl]thio]phenyl]-4-methyl-1-pentanone-1-(O-acetyloxime) [product name: IRGACURE (registered trademark) OXE-04, manufactured by BASF SE], 2-(dimethylamino)-2-[(4-methylphenyl)methyl]-1-[4-(4-morpholinyl)phenyl]-1-butanone [product name: IRGACURE (registered trademark) 379EG manufactured by BASF SE], 2-methyl-1-(4-methylthiophenyl)-2-morpholinopropan-1-one [product name: IRGACURE (registered trademark) 907, manufactured by BASF SE], 2-hydroxy-1-{4-[4-(2-hydroxy-2-methyl-propionyl)benzyl]phenyl}-2-methylpropan-1-one [product name: IRGACURE (registered trademark) 127, manufactured by BASF SE], 2-benzyl-2-dimethylamino-1-(4-morpholinophenyl)-butanone-1 [product name: IRGACURE (registered trademark) 369, manufactured by BASF SE], 2-hydroxy-2-methyl-1-phenyl-propan-1-one [product name: IRGACURE (registered trademark) 1173, manufactured by BASF SE], 1-hydroxy cyclohexyl phenyl ketone [product name: IRGACURE (registered trademark) 184, manufactured by BASF SE], 2,2-dimethoxy-1,2-diphenylethan-1-one (product name: IRGACURE 651, manufactured by BASF SE], and an oxime ester-based compound [product name: Lunar (registered trademark) 6, manufactured by DKSH Management Ltd.].

The photosensitive layer may contain only one kind of photopolymerization initiator, or may contain two or more kinds of photopolymerization initiators.

The content of the photopolymerization initiator is preferably 0.1% by mass or more, more preferably 0.5% by mass or more, and particularly preferably 1.0% by mass or more with respect to the total mass of the photosensitive layer. In addition, the content of the photopolymerization initiator is preferably 10% by mass or less and more preferably 5% by mass or less with respect to the total mass of the photosensitive layer.

(Polymer Including Constitutional Unit Having Carboxylic Acid Anhydride Structure)

It is preferable that the photosensitive layer may further contain, as a binder, a polymer (hereinafter, also referred to as a “polymer B”) including a constitutional unit having a carboxylic acid anhydride structure. In a case where the photosensitive layer contains the specific polymer B, developability and hardness after curing can be improved.

The carboxylic acid anhydride structure may be either a chain carboxylic acid anhydride structure or a cyclic carboxylic acid anhydride structure, and a cyclic carboxylic acid anhydride structure is preferable.

The ring of the cyclic carboxylic acid anhydride structure is preferably a 5-membered ring to 7-membered ring, more preferably a 5-membered ring or a 6-membered ring, and particularly preferably a 5-membered ring.

The constitutional unit having a carboxylic acid anhydride structure is preferably a constitutional unit containing a divalent group obtained by removing two hydrogen atoms from a compound represented by Formula P-1 in a main chain, or a constitutional unit in which a monovalent group obtained by removing one hydrogen atom from a compound represented by Formula P-1 is bonded to the main chain directly or through a divalent linking group.

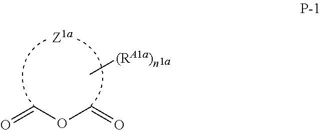

In Formula P-1, R^{A1a} represents a substituent, n^{1a} pieces of R^{A1a}'s may be the same or different, Z^{1a} represents a divalent group forming a ring including —C(═O)—O—C(═O)—, and n^{1a} represents an integer of 0 or more.

Examples of the substituent represented by R^{A1a} include an alkyl group.

Z^{1a} is preferably an alkylene group having 2 to 4 carbon atoms, more preferably an alkylene group having 2 or 3 carbon atoms, and particularly preferably an alkylene group having 2 carbon atoms.

n^{1a} represents an integer of 0 or more. In a case where Z^{1a} represents an alkylene group having 2 to 4 carbon atoms, n^{1a} is preferably an integer of 0 to 4, more preferably an integer of 0 to 2, and particularly preferably 0.

In a case where n^{1a} represents an integer of 2 or more, a plurality of R^{A1a}'s existing may be the same or different. In addition, the plurality of R^{A1a}'s existing may be bonded to each other to form a ring, but it is preferable that they are not bonded to each other to form a ring.

The constitutional unit having a carboxylic acid anhydride structure is preferably a constitutional unit derived from an unsaturated carboxylic acid anhydride, more preferably a constitutional unit derived from an unsaturated cyclic carboxylic acid anhydride, still more preferably a constitutional unit derived from an unsaturated aliphatic carboxylic acid anhydride, particularly preferably a constitutional unit derived from maleic acid anhydride or itaconic acid anhydride, and most preferably a constitutional unit derived from maleic acid anhydride.

The polymer B may have one constitutional unit having a carboxylic acid anhydride structure alone, or two or more kinds thereof.

The total content of the constitutional unit having a carboxylic acid anhydride structure is preferably more than 0 mol % and 60 mol % or less, more preferably 5 mol % to 40 mol %, and particularly preferably 10 mol % to 35 mol % with respect to the total amount of the polymer B.

The photosensitive layer may contain only one kind of polymer B, or may contain two or more kinds of polymers B.

In a case where the photosensitive layer contains the polymer B, from the viewpoint of developability and hardness after curing, the content of the polymer B is preferably 0.1% by mass to 30% by mass, more preferably 0.2% by mass to 20% by mass, still more preferably 0.5% by mass to 20% by mass, and particularly preferably 1% by mass to 20% by mass with respect to the total mass of the photosensitive layer.

(Heterocyclic Compound)

It is preferable that the photosensitive layer contains a heterocyclic compound. The heterocyclic compound contributes to the improvement of adhesiveness to a base material (particularly, a copper substrate) and corrosion inhibitory property of the metal (particularly, copper).

A heterocyclic ring included in the heterocyclic compound may be either a monocyclic or polycyclic heterocyclic ring.

Examples of a heteroatom included in the heterocyclic compound include an oxygen atom, a nitrogen atom, and a sulfur atom. The heterocyclic compound preferably has at least one atom selected from the group consisting of a nitrogen atom, an oxygen atom, and a sulfur atom, and more preferably has a nitrogen atom.

Preferred examples of the heterocyclic compound include a triazole compound, a benzotriazole compound, a tetrazole compound, a thiadiazole compound, a triazine compound, a rhodanine compound, a thiazole compound, a benzothiazole compound, a benzimidazole compound, a benzoxazole compound, and a pyrimidine compound. Among the above, the heterocyclic compound is preferably at least one compound selected from the group consisting of a triazole compound, a benzotriazole compound, a tetrazole compound, a thiadiazole compound, a triazine compound, a rhodanine compound, a thiazole compound, a benzimidazole compounds, and a benzoxazole compound, and more preferably at least one compound selected from the group consisting of a triazole compound, a benzotriazole compound, a tetrazole compound, a thiadiazole compound, a thiazole compound, a benzothiazole compound, a benzimidazole compound, and a benzoxazole compound.

Preferred specific examples of the heterocyclic compound are shown below. Examples of the triazole compound and the benzotriazole compound include the following compounds.

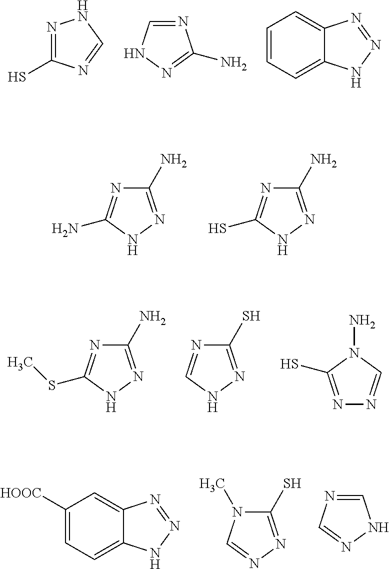

Examples of the tetrazole compound include the following compounds.

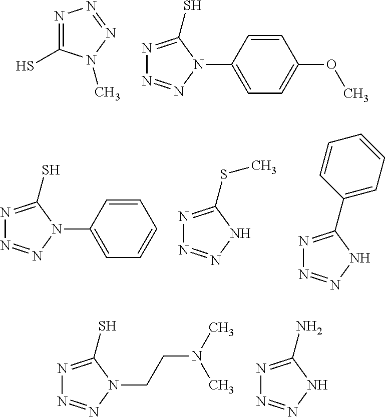

Examples of the thiadiazole compound include the following compounds.

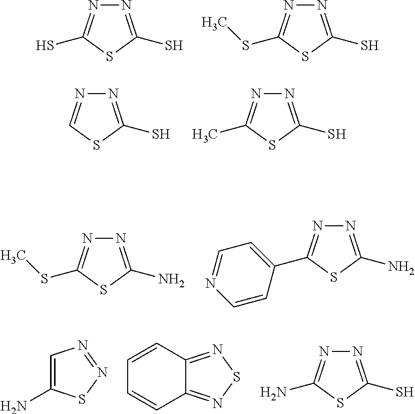

Examples of the triazine compound include the following compounds.

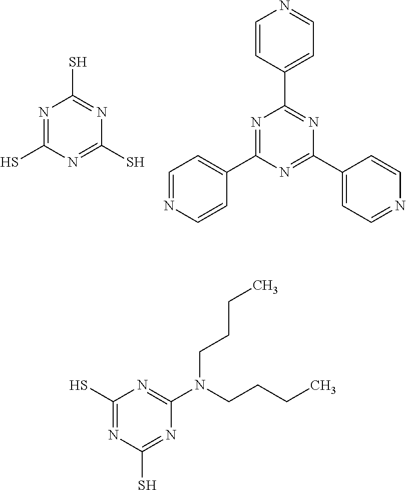

Examples of the rhodanine compound include the following compounds.

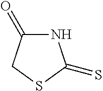

Examples of the thiazole compound include the following compounds.

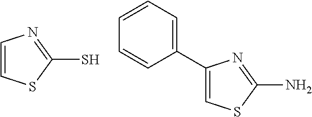

Examples of the benzothiazole compound include the following compounds.

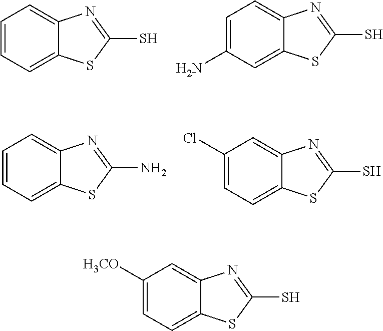 [SMILES: Sc1nc2ccccc2s1 ; Nc1ccc2nc(S)sc2c1 ; Nc1nc2ccccc2s1 ; Sc1nc2cc(Cl)ccc2s1 ; COc1ccc2sc(S)nc2c1]

Examples of the benzimidazole compound include the following compounds.

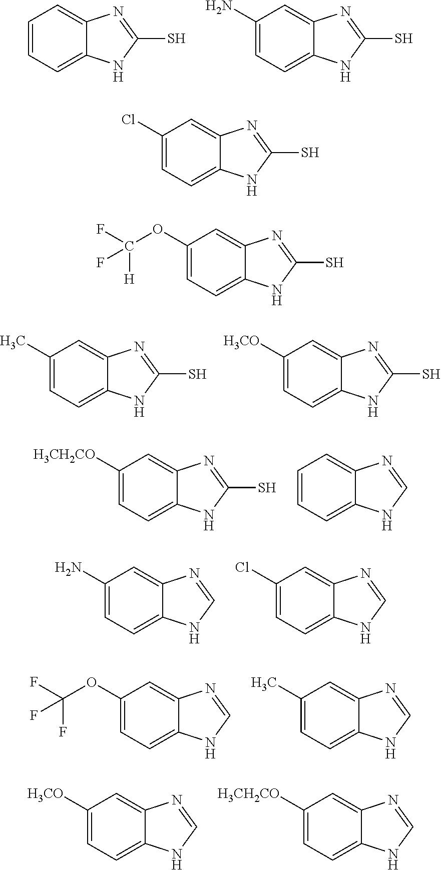

Examples of the benzoxazole compound include the following compounds.

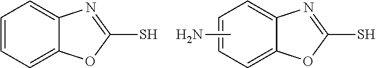

The photosensitive layer may contain only one kind of heterocyclic compound, or may contain two or more kinds of heterocyclic compounds.

In a case where the photosensitive layer contains the heterocyclic compound, the content of the heterocyclic compound is preferably 0.01% by mass to 20% by mass, more preferably 0.1% by mass to 10% by mass, still more preferably 0.3% by mass to 8% by mass, and particularly preferably 0.5% by mass to 5% by mass with respect to the total mass of the photosensitive layer. In a case where the content of the heterocyclic compound is within the above-described range, the adhesiveness to the base material (particularly, a copper substrate) and the corrosion inhibitory property of the metal (particularly, copper) can be improved.

(Aliphatic Thiol Compound)

It is preferable that the photosensitive layer contains an aliphatic thiol compound.

In a case where the photosensitive layer contains an aliphatic thiol compound, the ene-thiol reaction of the aliphatic thiol compound suppresses a curing contraction of the formed film and relieves stress. Therefore, adhesiveness of the formed cured film to the base material (particularly, adhesiveness after exposure) tends to be improved. In general, in a case where the photosensitive layer includes an aliphatic thiol compound, the metal (particularly, copper) is more easily corroded. On the other hand, the photosensitive layer in the present disclosure has an advantage that a cured film having excellent corrosion inhibitory property of the metal (particularly, copper) can be formed even in a case where the photosensitive layer in the present disclosure includes an aliphatic thiol compound.

As the aliphatic thiol compound, a monofunctional aliphatic thiol compound or a polyfunctional aliphatic thiol compound (that is, bi- or higher functional aliphatic thiol compound) is suitably used.

Among the above, for example, from the viewpoint of adhesiveness of the formed cured film to the substrate (particularly, adhesiveness after exposure), the aliphatic thiol compound preferably includes a polyfunctional aliphatic thiol compound, and is more preferably a polyfunctional aliphatic thiol compound.

In the present disclosure, the “polyfunctional aliphatic thiol compound” refers to an aliphatic compound having two or more thiol groups (also referred to as “mercapto groups”) in a molecule.

The polyfunctional aliphatic thiol compound is preferably a low-molecular-weight compound having a molecular weight of 100 or more. Specifically, the molecular weight of the polyfunctional aliphatic thiol compound is more preferably 100 to 1,500 and particularly preferably 150 to 1,000.

From the viewpoint of adhesiveness of the formed cured film to the substrate, for example, the number of functional groups of the polyfunctional aliphatic thiol compound (that is, the number of thiol groups) is preferably 2 to 10, more preferably 2 to 8, and particularly preferably 2 to 6.

Examples of the polyfunctional aliphatic thiol compound include trimethylolpropane tris(3-mercaptobutyrate), 1,4-bis(3-mercaptobutyryloxy)butane, pentaerythritol tetrakis(3-mercaptobutyrate), 1,3,5-tris(3-mercaptobutyryloxyethyl)-1,3,5-triazine-2,4,6(1H,3H,5H)-trione, trimethylolethane tris(3-mercaptobutyrate), tris[(3-mercaptopropionyloxy)ethyl]isocyanurate, trimethylolpropane tris(3-mercaptopropionate), pentaerythritol tetrakis(3-mercaptopropionate), tetraethylene glycol bis(3-mercaptopropionate), dipentaerythritol hexakis(3-mercaptopropionate), ethylene glycol bisthiopropionate, 1,2-ethanedithiol, 1,3-propanedithiol, 1,6-hexamethylenedithiol, 2,2′-(ethylenedithio)diethanethiol, meso-2,3-dimercaptosuccinic acid, and di(mercaptoethyl) ether.

Among the above, the polyfunctional aliphatic thiol compound is preferably at least one compound selected from the group consisting of trimethylolpropane tris(3-mercaptobutyrate), 1,4-bis(3-mercaptobutyryloxy)butane, and 1,3,5-tris(3-mercaptobutyryloxyethyl)-1,3,5-triazine-2,4,6(1H,3H,5H)-trione.

Examples of the monofunctional aliphatic thiol compound include 1-octanethiol, 1-dodecanethiol, β-mercaptopropionic acid, methyl-3-mercaptopropionate, 2-ethylhexyl-3-mercaptopropionate, n-octyl-3-mercaptopropionate, methoxybutyl-3-mercaptopropionate, and stearyl-3-mercaptopropionate.

The photosensitive layer may contain only one kind of aliphatic thiol compound, or may contain two or more kinds of aliphatic thiol compounds.

In a case where the photosensitive layer contains the aliphatic thiol compound, the content of the aliphatic thiol compound is preferably 5% by mass or more, more preferably 5% by mass to 50% by mass, still more preferably 5% by mass to 30% by mass, and particularly preferably 8% by mass to 20% by mass with respect to the total mass of the photosensitive layer. In a case where the content of the aliphatic thiol compound is 5% by mass or more, a cured film having more excellent adhesiveness (particularly, adhesiveness after exposure) to the substrate (particularly, a copper substrate) tends to be formed.

(Blocked Isocyanate Compound)

It is preferable that the photosensitive layer contains a blocked isocyanate compound. The blocked isocyanate compound contributes to improvement of hardness of the cured film.

Since the blocked isocyanate compound reacts with a hydroxyl group and a carboxy group, for example, in a case where at least one of the alkali-soluble acrylic resin or the radically polymerizable compound having an ethylenically unsaturated group has at least one of a hydroxyl group or a carboxy group, hydrophilicity of the formed film tends to decrease, and the function as a protective film tends to be strengthened. The blocked isocyanate compound refers to a “compound having a structure in which the isocyanate group of isocyanate is protected (so-called masked) with a blocking agent”.

The dissociation temperature of the blocked isocyanate compound is preferably 100° C. to 160° C. and more preferably 110° C. to 150° C.

In the present disclosure, the “dissociation temperature of the blocked isocyanate compound” means a temperature at an endothermic peak accompanied with a deprotection reaction of the blocked isocyanate compound, in a case where the measurement is performed by differential scanning calorimetry (DSC) analysis using a differential scanning calorimeter. As the differential scanning calorimeter, for example, a differential scanning calorimeter (model: DSC6200) manufactured by Seiko Instruments Inc. can be suitably used. However, the differential scanning calorimeter is not limited to the differential scanning calorimeter described above.

Examples of the blocking agent having a dissociation temperature of 100° C. to 160° C. include an active methylene compound [for example, diester malonates (such as dimethyl malonate, diethyl malonate, di-n-butyl malonate, and di-2-ethylhexyl malonate)], and an oxime compound (for example, compound having a structure represented by —C(═N—OH)— in a molecule, such as formaldoxime, acetoaldoxime, acetoxime, methyl ethyl ketoxime, and cyclohexanoneoxime). Among the above, from the viewpoint of storage stability, the blocking agent blocking agent having a dissociation temperature of 100° C. to 160° C. is preferably, for example, at least one selected from oxime compounds.

From the viewpoint of improving brittleness of the film and improving the adhesion to a transferred material, for example, the blocked isocyanate compound preferably has an isocyanurate structure. The blocked isocyanate compound having an isocyanurate structure can be obtained, for example, by isocyanurate-forming and protecting hexamethylene diisocyanate.

Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

The blocked isocyanate compound preferably has a polymerizable group and more preferably has a radically polymerizable group, from the viewpoint of hardness of the cured film.

The polymerizable group is not particularly limited, and a known polymerizable group can be used. Examples of the polymerizable group include an ethylenically unsaturated group (for example, a (meth)acryloxy group, a (meth)acrylamide group, and a styryl group), and a group having an epoxy group (for example, a glycidyl group). Among the above, as the polymerizable group, from the viewpoint of surface shape of the surface of a cured film to be obtained, a development speed, and reactivity, an ethylenically unsaturated group is preferable, and a (meth)acryloxy group is more preferable.

As the blocked isocyanate compound, a commercially available product can be used. Examples of the commercially available product of the blocked isocyanate compound include Karenz (registered trademark) AOI-BM, Karenz (registered trademark) MOI-BM, Karenz (registered trademark) AOI-BP, Karenz (registered trademark) MOI-BP, and the like [all manufactured by SHOWA DENKO K.K.], and block-type DURANATE series [for example, DURANATE (registered trademark) TPA-B80E, manufactured by Asahi Kasei Corporation].

The photosensitive layer may contain only one kind of blocked isocyanate compound, or may contain two or more kinds of blocked isocyanate compounds.

In a case where the photosensitive layer contains the blocked isocyanate compound, the content of the blocked isocyanate compound is preferably 1% by mass to 50% by mass and more preferably 5% by mass to 30% by mass with respect to the total mass of the photosensitive layer.

(Surfactant)

It is preferable that the photosensitive layer contains a surfactant.

The surfactant is not limited, and a known surfactant can be adopted. Examples of the surfactant include surfactants described in paragraph “0017” of JP4502784B and paragraphs “0060” to “0071” of JP2009-237362A.

As the surfactant, a fluorine-based surfactant or a silicon-based surfactant is preferable. Examples of a commercially available product of the fluorine-based surfactant include MEGAFACE (registered trademark) F551A (manufactured by DIC Corporation). Examples of a commercially available product of the silicon-based surfactant include DOWSIL (registered trademark) 8032 Additive.

The photosensitive layer may contain only one kind of surfactant, or may contain two or more kinds of surfactants.

In a case where the photosensitive layer contains the surfactant, the content of the surfactant is preferably 0.01% by mass to 3% by mass, more preferably 0.05% by mass to 1% by mass, and particularly preferably 0.1% by mass to 0.8% by mass with respect to the total mass of the photosensitive layer.

(Hydrogen Donating Compound)

It is preferable that the photosensitive layer contains a hydrogen donating compound. The hydrogen donating compound has a function of further improving sensitivity of the photopolymerization initiator to actinic ray, or suppressing inhibition of polymerization of the polymerizable compound by oxygen.

Examples of such a hydrogen donating compound include amines, for example, compounds described in M. R. Sander et al., “Journal of Polymer Society,” Vol. 10, page 3173 (1972), JP1969-20189B (JP-S44-20189B), JP1976-82102A (JP-S51-82102A), JP1977-134692A (JP-552-134692A), JP1984-138205A (JP-559-138205A), JP1985-84305A (JP-S60-84305A), JP1987-18537A (JP-S62-18537A), JP1989-33104A (JP-S64-33104A), and Research Disclosure 33825.

Specific examples of the hydrogen donating compound include triethanolamine, p-dimethylaminobenzoic acid ethyl ester, p-formyldimethylaniline, and p-methylthiodimethylaniline.

In addition, examples of the hydrogen donating compound also include an amino acid compound (N-phenylglycine and the like), an organic metal compound described in JP1973-42965B (JP-548-42965B) (tributyl tin acetate and the like), a hydrogen donor described in JP1980-34414B (JP-555-34414B), and a sulfur compound described in JP1994-308727A (JP-H06-308727A) (trithiane and the like).

The photosensitive layer may contain only one kind of hydrogen donating compound, or may contain two or more kinds of hydrogen donating compounds.

In a case where the photosensitive layer contains the hydrogen donating compound, from the viewpoint of improving a curing rate by balancing the polymerization growth rate and chain transfer, for example, the content of the hydrogen donating compound is preferably 0.01% by mass to 10% by mass, more preferably 0.03% by mass to 5% by mass, and particularly preferably 0.05% by mass to 3% by mass with respect to the total mass of the photosensitive layer.

(Other Components)

The photosensitive layer may contain a component other than the above-described components (hereinafter, also referred to as “other components”). Examples of the other components include particles (for example, metal oxide particles) and a colorant. In addition, examples of the other components include a thermal polymerization inhibitor described in paragraph “0018” of JP4502784B and other additives described in paragraphs “0058” to “0071” of JP2000-310706A.

—Particles—

The photosensitive layer may contain particles for the purpose of adjusting refractive index, light-transmitting property, and the like. Examples of the particles include metal oxide particles.

The metal of the metal oxide particles also includes semimetal such as B, Si, Ge, As, Sb, or Te.

From the viewpoint of transparency of the cured film, for example, the average primary particle diameter of the particles is preferably 1 nm to 200 nm and more preferably 3 nm to 80 nm. The average primary particle diameter of the particles is calculated by measuring particle diameters of 200 random particles using an electron microscope and arithmetically averaging the measurement result. In a case where the shape of the particle is not a spherical shape, the length of the major axis is set as the particle diameter.

The photosensitive layer may contain only one kind of particles, or may contain two or more kinds of particles. In addition, in a case where the photosensitive layer contains particles, the photosensitive layer may contain only one kind of particles having different metal species, sizes, or the like, or may contain two or more kinds thereof.

It is preferable that the photosensitive layer does not contain particles, or the content of the particles is more than 0% by mass to 35% by mass or less with respect to the total mass of the photosensitive layer; it is more preferable that the photosensitive layer does not contain particles, or the content of the particles is more than 0% by mass to 10% by mass or less with respect to the total mass of the photosensitive layer; it is still more preferable that the photosensitive layer does not contain particles, or the content of the particles is more than 0% by mass to 5% by mass or less with respect to the total mass of the photosensitive layer; it is particularly preferable that the photosensitive layer does not contain particles, or the content of the particles is more than 0% by mass to 1% by mass or less with respect to the total mass of the photosensitive layer; and it is most preferable that the photosensitive layer does not contain particles.

—Colorant—

The photosensitive layer may contain a trace amount of a colorant (for example, a pigment and a dye). However, for example, from the viewpoint of transparency, it is preferable that the photosensitive layer does not substantially contain a colorant.

The content of the colorant is preferably less than 1% by mass and more preferably less than 0.1% by mass with respect to the total mass of the photosensitive layer. The lower limit of the content of the colorant may be appropriately set in a range of 0% by mass or more with respect to the total mass of the photosensitive layer. The content of the colorant may be 0% by mass, or may exceed 0% by mass with respect to the total mass of the photosensitive layer.

—Compound A—

The photosensitive layer may contain a compound A having at least one group selected from the group consisting of a metal reducing group and a metal coordinating group.

From the viewpoint of moisture-heat resistance of metal, the above-described compound A is preferably a compound having a metal reducing group. Since the above-described compound A has a metal reducing group, it is presumed that ionization of metals can be suppressed and moisture-heat resistance of metals, particularly metal electrodes, can be improved.

From the viewpoint of moisture-heat resistance of metal, the above-described compound A is preferably a compound having a metal coordinating group. Since the above-described compound A has a metal coordinating group, it is presumed that it is possible to suppress approach of harmful substances such as halogens to metals and oxidation and ionization of metals, and to improve moisture-heat resistance of metal electrodes.

In addition, from the viewpoint of moisture-heat resistance of metal, the above-described compound A is preferably a compound having a metal reducing group and a metal coordinating group. Since the compound A has both the metal reducing group and the metal coordinating group, in addition to the above-described effects, reducing property of the metal reducing group can be exhibited in the vicinity of the metal due to coordination of the metal coordinating group to the metal. Therefore, the moisture-heat resistance of the metal can be improved more effectively.

It is sufficient that the above-described metal reducing group is a group capable of reducing at least one target metal. Examples of the above-described metal reducing group include an aldehyde group, an amino group, a group having a triple bond (for example, an acetylene group and a propargyl group), and a mercapto group. In addition, examples of the above-described metal reducing group include a residue in which one hydrogen atom is removed from at least one compound selected from the group consisting of hydroxylamines, hydroxamic acids, hydroxyureas, hydroxyurethanes, hydroxysemicarbazides, reductones (including reductone derivatives), anilines, phenols (including polyphenols such as chroman-6-ols, 2,3-dihydrobenzofuran-5-ols, aminophenol s, sulfonamidephenols, hydroquinones, catechols, resorcinols, benzenetriols, and bisphenols), acylhydrazines, carbamoylhydrazines, and 3-pyrazolidones.

Among the above, as the above-described metal reducing group, from the viewpoint of metal reducing ability and moisture-heat resistance of metal, an aldehyde group or a primary to tertiary amino group is preferable, an aldehyde group or a primary amino group is more preferable, and an aldehyde group is particularly preferable.

It is sufficient that the above-described metal coordinating group is a group which directly coordinates with at least one target metal or a group which promotes coordination with the metal. Specific examples of the above-described metal coordinating group include a mercapto group (or a salt thereof), a thione group (—C(═S)—), a heterocyclic group including at least one atom selected from the group consisting of a nitrogen atom, a sulfur atom, a selenium atom, and a tellurium atom, a thioether group, a disulfide group, a cationic group, and an ethynyl group.

The mercapto group (or a salt thereof) in the above-described metal coordinating group is preferably a mercapto group (or a salt thereof) which is substituted with a heterocyclic group, an aryl group, or an alkyl group, more preferably a mercapto group (or a salt thereof) which is substituted with a heterocyclic group or an aryl group, and particularly preferably a mercapto group (or a salt thereof) which is substituted with an aromatic heterocyclic group or an aryl group.

The heterocyclic group is an aromatic or non-aromatic heterocyclic group, which is monocyclic or fused and has at least 5- to 7-membered ring, and examples thereof include an imidazole ring group, a thiazole ring group, an oxazole ring group, a benzoimidazole ring group, a benzothiazole ring group, a benzoxazole ring group, a triazole ring group, a thiadiazole ring group, an oxadiazole ring group, a tetrazole ring group, a purine ring group, a pyridine ring group, a quinoline ring group, an isoquinoline ring group, a pyrimidine ring group, and a triazine ring group. In addition, the heterocyclic group may be a heterocyclic group including a quaternized nitrogen atom, and in this case, the substituted mercapto group may be dissociated to be mesoionic.

In a case where the mercapto group forms a salt, examples of a counter ion include cations of alkali metals, alkaline earth metals, and heavy metals (for example, Li⁺, Na⁺, K⁺, Mg²⁺, Ag⁺, and Zn⁺), an ammonium ion, a heterocyclic group including a quaternized nitrogen atom, and a phosphonium ion.

The mercapto group in the above-described metal coordinating group may be tautomerized to be a thione group.

The thione group in the above-described metal coordinating group also includes a linear or cyclic thioamide group, a thioureide group, a thiourethane group, or a dithiocarbamic acid ester group.

The heterocyclic group including at least one atom selected from the group consisting of a nitrogen atom, a sulfur atom, a selenium atom, and a tellurium atom in the above-described metal coordinating group is a nitrogen-containing heterocyclic group having a —NH— group as a partial structure of the hetero ring, which can form an iminoated metal, or a heterocyclic group having a “—S—” group, a “—Se—” group, a “—Te—” group, or a “═N—” group as a partial structure of the hetero ring, which can be coordinated to a metal ion by a coordinate bond. Examples of the former include a benzotriazole group, a triazole group, an indazole group, a pyrazole group, a tetrazole group, a benzimidazole group, an imidazole group, and a purine group. Examples of the latter include a thiophene group, a thiazole group, an oxazole group, a benzothiophene group, a benzothiazole group, a benzoxazole group, a thiadiazole group, an oxadiazole group, a triazine group, a selenoazole group, a benzoselenoazole group, a tellurazole group, and a benzotelluazole group.

Examples of the thioether group (sulfide group) or disulfide group in the above-described metal coordinating group include all groups having a partial structure of —S— or —S—S—. Examples of the thioether group or disulfide group include an alkylthio group, an arylthio group, an alkyldisulfide group, and an aryldisulfide group.

The cationic group in the above-described metal coordinating group is preferably a group having a cation on the nitrogen atom. Specific examples thereof include a primary to quaternary ammonio group and a group which includes a nitrogen-containing heterocyclic group including a quaternized nitrogen atom. Examples of the nitrogen-containing heterocyclic group including a quaternized nitrogen atom include a pyridinio group, a quinolinio group, an isoquinolinio group, and an imidazolio group.

The ethynyl group in the above-described metal coordinating group means a —C≡CH group, and the hydrogen atom in the —C≡CH group may be replaced.

The above-described metal coordinating group may have any substituent.

Specific examples of the above-described metal coordinating group include those described in pages 4 to 7 of JP1999-95355A (JP-H11-95355A).

As the above-described metal coordinating group, from the viewpoint of coordination ability to metal and moisture-heat resistance of metal, the thioether group, the mercapto group, or the heterocyclic group including at least one atom selected from the group consisting of a nitrogen atom, a sulfur atom, a selenium atom, and a tellurium atom is preferable, the thioether group, the mercapto group, or the heterocyclic group including at least one atom selected from the group consisting of a nitrogen atom and a sulfur atom is more preferable, the thioether group or the mercapto group is still more preferable, and the thioether group is particularly preferable.

The molecular weight of the above-described compound A is preferably 100 to 10,000, more preferably 120 to 1,000, and still more preferably 120 to 500. By setting the molecular weight of the above-described compound A within the above-described range, volatilization of the compound A in the manufacturing process and durability test can be suppressed, diffusivity in the photosensitive layer and the transferred and contacted layer is also excellent, and the moisture-heat resistance of the metal is more excellent.

From the viewpoint of moisture-heat resistance of metal, the number of metal reducing groups in the above-described compound A is preferably 1 or more, more preferably 1 to 6, still more preferably 1 to 3, and particularly preferably 1. In a case where the number of metal reducing groups is 2 or more, the metal reducing groups may be the same or different groups.

From the viewpoint of moisture-heat resistance of metal, the number of metal coordinating groups in the above-described compound A is preferably 1 or more, more preferably 1 to 6, still more preferably 1 to 3, and particularly preferably 1. In a case where the number of metal coordinating groups is 2 or more, the metal coordinating groups may be the same or different groups.

From the viewpoint of moisture-heat resistance of metal, as the above-described compound A, a compound represented by Formula (D1) is preferable, and a group represented by Formula (D2) is more preferable.

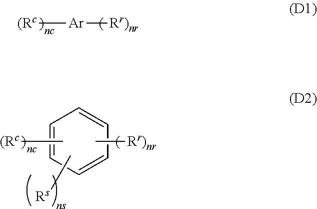

In Formulae D1 and D2, Ar represents a group obtained by removing (nr+nc) hydrogen atoms on an aromatic ring or an aromatic hetero ring from an aromatic ring compound or an aromatic heterocyclic compound, It's each independently represent a metal reducing group, R^{c}'s each independently represent a metal coordinating group, R^{s}'s each independently represent a substituent, nr represents an integer of 0 to 3, nc represents an integer of 0 to 3, ns represents an integer of 0 or more, a value of nr+nc is an integer of 1 to 6, and in Formula D2, a value of nr+nc+ns is an integer of 1 to 6.

Ar is preferably a group obtained by removing (nr+nc) hydrogen atoms on an aromatic ring or a hetero ring from benzene, thiadiazole, thiazole, or benzotriazole, which may have a substituent, and more preferably a group obtained by removing (nr+nc) hydrogen atoms on an aromatic ring from benzene, which may have a substituent. The substituent in Ar is not particularly limited, and preferred examples thereof include substituents in R^{s}, which will be described later.

Preferred examples of the metal reducing group in R^{r} include the above-described metal reducing groups.

Preferred examples of the metal coordinating group in R^{c} include the above-described metal coordinating groups.

The substituent in R^{s} is not particularly limited as long as it is a group other than the above-described metal reducing group and the above-described metal coordinating group, and preferred specific examples thereof include an alkyl group, an aryl group, a halogen atom, an acyl group, an alkoxycarbonyl group, an aryloxycarbonyl group, a heteroaryloxycarbonyl group, an amide group, a cyano group, and a nitro group.

nr is preferably an integer of 1 to 3, more preferably 1 or 2, and particularly preferably 1.

nc is preferably an integer of 1 to 3, more preferably 1 or 2, and particularly preferably 1.

ns is preferably an integer of 0 to 4 and more preferably an integer of 0 to 2.

The photosensitive layer may contain only one kind of compound A, or may contain two or more kinds of compounds A.

The content of the compound A in the photosensitive layer is preferably 0% by mass or more than 0% to 10% by mass, more preferably 1% by mass to 10% by mass, still more preferably 1% by mass to 6% by mass, and particularly preferably 2% by mass to 4% by mass with respect to the total mass of the above-described photosensitive layer. By setting the content of the compound A within the above-described range, moisture-heat resistance of metal can be improved.

The compound A used in the present disclosure will be exemplified below, the present disclosure is not limited thereto.

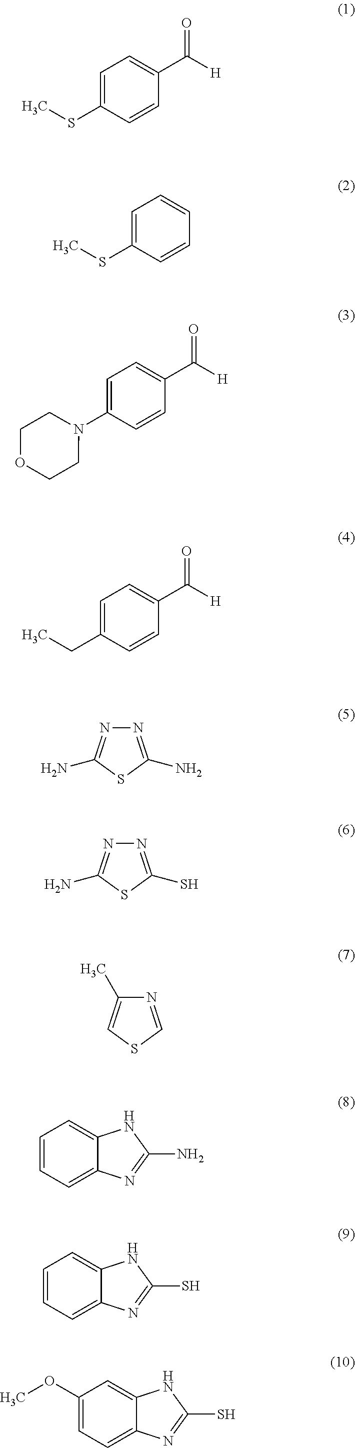

Further, preferred examples of the compound A in the present disclosure also include specific compounds 1 to 30 and 1″-1 to 1″-77 described in pages 73 to 87 of EP1308776B.

The photosensitive layer may contain a metal additive. The metal additive is an additive including a metal. The metal additive is not particularly limited, but from the viewpoint of transparency of the photosensitive transfer film, metal particles, metal oxide particles, or metal complex compounds are preferable.

Examples of the metal oxide particles include aluminum oxide particles, titanium oxide particles, and zirconium oxide particles. The metal oxide is not particularly limited, but from the viewpoint of transparency of the photosensitive transfer film, it is preferable to have a primary particle diameter of 100 nm or less.

From the viewpoint of solubility in a photosensitive resin, the metal additive is preferably a metal complex compound. By containing a metal complex in the photosensitive layer, deterioration of metal, particularly the metal electrode, due to visible light can be suppressed.

The metal complex compound is not particularly limited, but it is preferable to include iron, nickel, cobalt, aluminum, titanium, or zirconium, and it is more preferable to include iron.

Examples of a metal complex compound including iron include tris(2,4-pentanedionato)iron(III) (also referred to as “acetylacetone iron complex”) and analogous substance thereof, ferrocene and analogous substance thereof, and tris(dibenzoylmethanato)iron(III). Among these, from the viewpoint of solubility in an organic solvent, oxidation resistance, and the like, ferrocene is preferable.

The content of the metal additive in the photosensitive layer is preferably 0% by mass or more than 0% to 10% by mass, more preferably 0.001% by mass to 5% by mass, still more preferably 0.01% by mass to 3% by mass, and particularly preferably 0.1% by mass to 3% by mass with respect to the total mass of the above-described photosensitive layer. By setting the content of the metal additive within the above-described range, deterioration of metal due to visible light can be suppressed.

(Thickness of Photosensitive Layer)

The thickness of the photosensitive layer is 10 μm or less, and is preferably 8 μm or less, more preferably 5 μm or less, and particularly preferably 4 μm or less. Since the thickness of the photosensitive layer is 10 μm or less, bend resistance can be improved.

The lower limit of the thickness of the photosensitive layer is not limited. As the thickness of the photosensitive layer is smaller, bend resistance can be improved. From the viewpoint of manufacturing suitability, the thickness of the photosensitive layer is preferably 0.05 μm or more and more preferably 0.5 μm or more.

The thickness of the photosensitive layer is obtained as an average value of 5 random points measured by cross-sectional observation with a scanning electron microscope (SEM).

(Impurities and the Like)

In the photosensitive transfer film according to the embodiment of the present disclosure, from the viewpoint of improving reliability and patterning properties, it is preferable that the photosensitive layer contains a predetermined content of impurities. Examples of the impurities include sodium, potassium, magnesium, calcium, iron, manganese, copper, aluminum, titanium, chromium, cobalt, nickel, zinc, tin, halogen, and ions of these. Among these, halide ion, sodium ion, and potassium ion are easily mixed as impurities, so that the following content is particularly preferable.

The content of impurities in the photosensitive layer is preferably 80 ppm or less, more preferably 10 ppm or less, and particularly preferably 2 ppm or less on a mass basis. The content of impurities in the photosensitive layer may be 1 ppb or more or 0.1 ppm or more on a mass basis.

Examples of a method for keeping the content of impurities in the above-described range include selecting a raw material having a low content of impurities as a raw material for the photosensitive layer, preventing the impurities from being mixed in a case of forming the photosensitive layer, and washing and removing the impurities. By such a method, the amount of impurities can be kept within the above-described range.

The impurities can be quantified by a known method such as inductively coupled plasma (ICP) emission spectroscopy, atomic absorption spectroscopy, and ion chromatography.

In addition, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low in the photosensitive layer. The content of these compounds in the photosensitive layer is preferably 100 ppm or less, more preferably 20 ppm or less, and particularly preferably 4 ppm or less on a mass basis. The lower limit thereof may be 10 ppb or more or 100 ppb or more on a mass basis. The content of these compounds can be suppressed in the same manner as in the above-described metal as impurities. In addition, the compounds can be quantified by a known measurement method.

From the viewpoint of reliability and laminating property, the content of water in the photosensitive layer is preferably 0.01% to 1.0% by mass and more preferably 0.05% by mass to 0.5% by mass.

From the viewpoint of laminating property, the content of the organic solvent in the photosensitive layer is preferably 0.001% to 3.0% by mass and more preferably 0.05% by mass to 1.0% by mass.

(Refractive Index of Photosensitive Layer)

The refractive index of the photosensitive layer is preferably 1.47 to 1.56 and more preferably 1.49 to 1.54.

(Color of Photosensitive Layer)

The photosensitive layer is preferably achromatic. Specifically, in CIE1976 (L*, a*, b*) color space of total reflection (incidence angle: 8°, light source: D-65 (visual field: 2°)), the L* value is preferably 10 to 90, the a* value is preferably −1.0 to 1.0, and the b* value is preferably −1.0 to 1.0.

(Method for Forming Photosensitive Layer)

A method for forming the photosensitive layer is not limited, and a known method can be adopted. Examples of the method for forming the photosensitive layer include a method using a composition for a photosensitive layer. For example, the composition for a photosensitive layer is applied on an object to be coated (for example, a transparent film 1 described later), and the composition is dried as necessary to form a photosensitive layer.

Examples of a method for producing the composition for a photosensitive layer include a method of mixing the above-described components and a solvent. The mixing method is not limited, and a known method can be adopted.

The solvent is not limited, and a known solvent can be adopted. The solvent is preferably an organic solvent. Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol. As the solvent, a mixed solvent of methyl ethyl ketone and propylene glycol monomethyl ether acetate or a mixed solvent of diethylene glycol ethyl methyl ether and propylene glycol monomethyl ether acetate is preferably used.

As the solvent, a solvent described in paragraphs “0054” and “0055” of US2005/282073A can also be used, and the contents of this specification are incorporated in the present disclosure by reference.

In addition, as the solvent, an organic solvent (high-boiling-point solvent) having a boiling point of 180° C. to 250° C. can also be used, as necessary.

The composition for a photosensitive layer may contain only one kind of solvent, or may contain two or more kinds of solvents.

In a case where the composition for a photosensitive layer contains the solvent, the total solid content of the composition for a photosensitive layer is preferably 5% by mass to 80% by mass, more preferably 5% by mass to 40% by mass, and particularly preferably 5% by mass to 30% by mass with respect to the total mass of the composition for a photosensitive layer.

In a case where the composition for a photosensitive layer contains the solvent, for example, from the viewpoint of coatability, the viscosity of the composition for a photosensitive layer at 25° C. is preferably 1 mPa·s to 50 mPa·s, more preferably 2 mPa·s to 40 mPa·s, and particularly preferably 3 mPa·s to 30 mPa·s. The viscosity is measured using a viscometer. As the viscometer, for example, a viscometer (product name: VISCOMETER TV-22) manufactured by Toki Sangyo Co. Ltd. can be suitably used. However, the viscometer is not limited to the above-described viscometer.

In a case where the composition for a photosensitive layer contains the solvent, for example, from the viewpoint of coatability, the surface tension of the composition for a photosensitive layer at 25° C. is preferably 5 mN/m to 100 mN/m, more preferably 10 mN/m to 80 mN/m, and particularly preferably 15 mN/m to 40 mN/m. The surface tension is measured using a tensiometer. As the tensiometer, for example, a tensiometer (product name: Automatic Surface Tensiometer CBVP-Z) manufactured by Kyowa Interface Science Co., Ltd. can be suitably used. However, the tensiometer is not limited to the above-described tensiometer.

The coating method is not limited, and a known method can be adopted. Examples of the coating method include a printing method, a spray coating method, a roll coating method, a bar coating method, a curtain coating method, a spin coating method, and a die coating method (that is, a slit coating method). Among the above, a die coating method is preferable as the coating method.

The drying method is not limited, and a known method can be adopted. Examples of the drying method include natural drying, heating drying, and drying under reduced pressure. The above-described methods can be adopted alone or in combination of two or more thereof.

In the present disclosure, “drying” is not limited to removing all solvents contained in the composition, but includes removing at least a part of the solvents contained in the composition.

[Antistatic Layer]

The photosensitive transfer film according to the embodiment of the present disclosure has an antistatic layer. Since the photosensitive transfer film according to the embodiment of the present disclosure has an antistatic layer in addition to the above-described photosensitive layer, the antistatic layer can be patterned. Further, since the photosensitive transfer film according to the embodiment of the present disclosure has an antistatic layer, it is possible to suppress generation of static electricity in a case of peeling off the film or the like disposed on the antistatic layer, and also to suppress generation of static electricity due to rubbing against equipment, other films, or the like. Therefore, for example, it is possible to suppress occurrence of defect in an electronic device.

In the photosensitive transfer film according to the embodiment of the present disclosure, it is preferable that the photosensitive layer and the antistatic layer are arranged in contact with each other. By arranging the photosensitive layer and the antistatic layer in contact with each other, patterning properties of the antistatic layer can be improved.

The antistatic layer is a layer having antistatic properties, and contains at least an antistatic agent. The antistatic agent is not limited, and a known antistatic agent can be adopted.

The antistatic layer preferably contains, as the antistatic agent, at least one compound selected from the group consisting of an ionic liquid, an ionic conductive polymer, an ionic conductive filler, and an electrically conductive polymer.

(Ionic Liquid)

As the ionic liquid, a known ionic liquid can be adopted as long as the effect of the antistatic layer is not impaired. Here, the “ionic liquid” means a molten salt (that is, an ionic compound) which is liquid at 25° C.

The ionic liquid is preferably an ionic liquid composed of a fluoroorganic anion and an onium cation. In a case where the ionic liquid is an ionic liquid composed of a fluoroorganic anion and an onium cation, peeling charging which may generate in a case of peeling off the film or the like disposed on the antistatic layer can be suppressed, and charging which may generate due to rubbing against equipment, other films, or the like can be further suppressed.

Specific examples of the ionic liquid include 1-hexylpyridinium bis(fluorosulfonyl)imide, 1-ethyl-3-methylpyridinium trifluoromethane sulfonate, 1-ethyl-3-methylpyridinium pentafluoroethane sulfonate, 1-ethyl-3-methylpyridinium heptafluoropropane sulfonate, 1-ethyl-3-methylpyridinium nonafluorobutane sulfonate, 1-butyl-3-methylpyridinium trifluoromethane sulfonate, 1-butyl-3-methylpyridinium bis(trifluoromethanesulfonyl)imide, 1-octyl-4-methylpyridinium bis(fluorosulfonyl)imide, 1-methyl-1-propylpyrrolidinium bis(trifluoromethanesulfonyl)imide, 1-methyl-1-propylpyrrolidinium bis(fluorosulfonyl)imide, 1-methyl-1-propylpiperidinium bis(trifluoromethanesulfonyl)imide, 1-methyl-1-propylpiperidinium bis(fluorosulfonyl)imide, 1-ethyl-3-methylimidazolium trifluoromethane sulfonate, 1-ethyl-3-methylimidazolium heptafluoropropane sulfonate, 1-ethyl-3-methylimidazolium bis(trifluoromethanesulfonyl)imide, 1-ethyl-3-methylimidazolium bis(fluorosulfonyl)imide, 1-hexyl-3-methylimidazolium bis(fluorosulfonyl)imide, trimethylpropylammonium bis(trifluoromethanesulfonyl)imide, lithium bis(trifluoromethanesulfonyl)imide, and lithium bis(fluorosulfonyl)imide.

The ionic liquid is available, for example, as IL-AP3 (KOEI CHEMICAL CO., LTD.).

The antistatic layer may contain only one kind of ionic liquid, or may contain two or more kinds of ionic liquids.

(Ionic Conductive Polymer)

As the ionic conductive polymer, a known ionic conductive polymer can be adopted as long as the effect of the antistatic layer is not impaired.

Examples of the ionic conductive polymer include an ionic conductive polymer obtained by polymerizing or copolymerizing a monomer having a quaternary ammonium base.

The ionic conductive polymer is available, for example, as Acrit 1SX series (for example, product name 1SX-1055F, Taisei Fine Chemical Co., Ltd.).

The antistatic layer may contain only one kind of ionic conductive polymer, or may contain two or more kinds of ionic conductive polymers.

(Ionic Conductive Filler)

As the ionic conductive filler, a known ionic conductive filler can be adopted as long as the effect of the antistatic layer is not impaired.

Examples of the ionic conductive filler include tin oxide, antimony oxide, indium oxide, cadmium oxide, titanium oxide, zinc oxide, indium, tin, antimony, gold, silver, copper, aluminum, nickel, chromium, titanium, iron, cobalt, copper iodide, indium oxide/tin oxide (ITO), and antimony oxide/tin oxide (ATO).

The ionic conductive filler is available, for example, as FS series (for example, product name FS-10D, ISHIHARA SANGYO KAISHA, LTD.).

The antistatic layer may contain only one kind of ionic conductive filler, or may contain two or more kinds of ionic conductive fillers.

(Electrically Conductive Polymer)

As the electrically conductive polymer, a known electrically conductive polymer can be adopted as long as the effect of the antistatic layer is not impaired.

Examples of the electrically conductive polymer include polythiophene, polyaniline, polypyrrole, polyethyleneimine, and arylamine-based polymers. Specific examples of the electrically conductive polymer include (3,4-ethylenedioxythiophene)-poly(styrene sulfonic acid).

As the polythiophene, a polymer compound including poly(3,4-ethylenedioxythiophene) (PEDOT) is preferable, and a conductive polymer compound consisting of poly(3,4-ethylenedioxythiophene) and polystyrene sulfonic acid (hereinafter, abbreviated as PEDOT/PSS) is particularly preferable. Examples of a commercially available product of the polythiophene include Clevios series (Heraeus Holding), ORGACON series (AGFA Materials Japan LTD.), Denatron P-502RG, PT-432ME, and N8-2-1 (Nagase ChemteX Corporation), and SEPLEGYDA AS-X, AS-D, AS-H, AS-F, HC-R, HC-A, SAS-P, SAS-M, and SAS-F (Shin-Etsu Polymer Co., Ltd.).

Examples of the polyaniline include ORMECON series (Nissan Chemical Corporation).

Examples of the polypyrrole include product numbers 482552 and 735817 (Aldrich-Sigma, Co. LLC.).

In the present disclosure, as the electrically conductive polymer, the above-described commercially available products can be preferably used.

The antistatic layer may contain only one kind of electrically conductive polymer, or may contain two or more kinds of electrically conductive polymers.

The antistatic agent contained in the antistatic layer is preferably a solvent-dispersed antistatic agent. In a case where the antistatic agent is a solvent-dispersed antistatic agent, for example, in the manufacturing of the photosensitive transfer film, since elution of the antistatic agent in a case of applying the composition for a photosensitive layer to the antistatic layer can be suppressed, the region where the antistatic agent is not detected can be adjusted to the range described later.

The antistatic layer may contain only one kind of antistatic agent, or may contain two or more kinds of antistatic agents.

From the viewpoint of antistatic properties, the content of the antistatic agent is preferably 0.1% by mass to 100% by mass with respect to the total mass of the antistatic layer. In a case where the antistatic agent is a solvent-dispersed antistatic agent, the content of the antistatic agent is more preferably 1% by mass to 10% by mass and particularly preferably 3% by mass to 10% by mass with respect to the total mass of the antistatic layer. In a case where the antistatic agent is not a solvent-dispersed antistatic agent, the content of the antistatic agent is more preferably 60% by mass to 100% by mass and particularly preferably 70% by mass to 100% by mass with respect to the total mass of the antistatic layer.

It is preferable that an antistatic agent is not detected in a region from a surface of the photosensitive layer opposite to the antistatic layer to 40% of a total thickness of the photosensitive layer and the antistatic layer, it is more preferable to be not detected in a region up to 80%, and it is particularly preferable to be not detected in a region up to 90%. By setting the region where the antistatic agent is not detected to the above-described range, it is possible to prevent the antistatic agent from moving to other members through the photosensitive layer. For example, in a case where, using the photosensitive transfer film according to the embodiment of the present disclosure, the photosensitive layer and the antistatic layer are laminated in this order on a base material having an electrode layer (for example, a layer containing silver nanowires) on a surface, the movement of the antistatic agent to a conductive layer under heating or moist heating conditions can be suppressed, and as a result, deterioration of the electrode layer can be suppressed.

The region where the antistatic agent is not detected is determined by a method using a time of flight-secondary ion mass spectrometer (TOF-SIMS) and an ion gun, in which peak intensities of specific fragment ions due to molecules existing in a depth direction of the photosensitive layer and the antistatic layer are measured from a surface of the photosensitive layer opposite to the antistatic layer, and the length (depth) from the surface of the photosensitive layer opposite to the antistatic layer to the region where fragment ions due to the antistatic agent are not detected is divided by the total thickness of the photosensitive layer and the antistatic layer. The TOF-SIMS method is specifically described in “Surface Analysis Technology Selection Book Secondary Ion Mass Spectrometry” edited by Japan Surface Science Society, Maruzen (published in 1999).

(Other Components)

The antistatic layer may further contain a component other than the antistatic agent as necessary. The component other than the antistatic agent is not limited, and a known component can be adopted. Examples of the component other than the antistatic agent include a binder polymer, a curing component, and a surfactant. In addition, the antistatic agent may further contain a known additive other than the above-described components as necessary.

—Binder Polymer—

The binder polymer is not limited, and a known polymer can be adopted. However, the above-described antistatic agent is not included in the binder polymer. Examples of the binder polymer include polyvinylpyrrolidone, polyvinyl alcohol, and an acrylic resin.

The binder polymer may be an alkali-soluble binder polymer or an alkali-insoluble binder polymer. Here, “alkali-insoluble” refers to a property which does not correspond to the above-described “alkali-soluble”. In addition, as the binder polymer, the alkali-soluble acrylic resin described in the above section of “Photosensitive Layer” can also be adopted. In a case where the binder polymer is the alkali-soluble acrylic resin, a preferred embodiment of the alkali-soluble acrylic resin is the same as that of the alkali-soluble acrylic resin described in the above section of “Photosensitive Layer”.

In a case where the antistatic layer contains a binder polymer, from the viewpoint of patterning properties (suppression of dissolution of the developer in the exposed portion) of the antistatic layer, the acid value of the binder polymer is preferably 60 mgKOH/g or less.

The antistatic layer may contain only one kind of binder polymer, or may contain two or more kinds of binder polymers.

The content of the binder polymer other than the above-described antistatic agent is preferably 0% by mass to 70% by mass, more preferably 0% by mass to 60% by mass, and particularly preferably 0% by mass to 55% by mass with respect to the total mass of the antistatic layer.

—Curing Component—

Examples of the curing component include a polymerizable compound and a photopolymerization initiator.

The polymerizable compound is not limited, and a known polymerizable compound can be adopted. Examples of the polymerizable compound include the radically polymerizable compound having an ethylenically unsaturated group (that is, the ethylenically unsaturated compound), which is described in the above section of “Photosensitive Layer”. A preferred embodiment of the ethylenically unsaturated compound in the antistatic layer is the same as that of the ethylenically unsaturated compound described in the above section of “Photosensitive Layer”.

The photopolymerization initiator is not limited and a known photopolymerization initiator can be adopted. Examples of the photopolymerization initiator include the photopolymerization initiator described in the above section of “Photosensitive Layer”. A preferred embodiment of the photopolymerization initiator in the antistatic layer is the same as that of the photopolymerization initiator described in the above section of “Photosensitive Layer”.

In a case where the antistatic layer contains a binder polymer having an acid value of 60 mgKOH/g or more, it is preferable that the antistatic layer further contains the polymerizable compound and the photopolymerization initiator as the curing component.

The antistatic layer may contain only one kind of polymerizable compound, or may contain two or more kinds of polymerizable compounds.

In a case where the antistatic layer contains a polymerizable compound, the content of the polymerizable compound is preferably 5% by mass to 60% by mass, more preferably 5% by mass to 50% by mass, and particularly preferably 5% by mass to 45% by mass with respect to the total mass of the antistatic layer.

The antistatic layer may contain only one kind of photopolymerization initiator, or may contain two or more kinds of photopolymerization initiators.

In a case where the antistatic layer contains a polymerizable compound, the content of the photopolymerization initiator is preferably 0.1% by mass to 10% by mass, more preferably 0.1% by mass to 7.5% by mass, and particularly preferably 0.1% by mass to 5% by mass with respect to the total mass of the antistatic layer.

—Surfactant—

Examples of the surfactant include the surfactant described in the above section of “Photosensitive Layer”. A preferred embodiment of the surfactant in the antistatic layer is the same as that of the surfactant described in the above section of “Photosensitive Layer”.

The antistatic layer may contain only one kind of surfactant, or may contain two or more kinds of surfactants.

In a case where the antistatic layer contains a surfactant, the content of the surfactant is preferably more than 0% by mass and 1% by mass or less with respect to the total mass of the antistatic layer.

(Surface Electrical Resistance Value)

The surface electrical resistance value of the antistatic layer is preferably 1.0×10¹²Ω/□ or less, more preferably 1.0×10¹¹Ω/□ or less, and particularly preferably 5.0×10¹⁰Ω/□ or less. In a case where the surface electrical resistance of the antistatic layer is within the above-described range, the surface electrical resistance of the antistatic layer can be lowered, so that the generation of static electricity in a case of peeling off the film or the like disposed on the antistatic layer can be suppressed.

The lower limit of the surface electrical resistance value of the antistatic layer is not limited. The surface electrical resistance value of the antistatic layer is preferably 1.0×10⁶Ω/□ or more and more preferably 1.0×10⁷Ω/□ or more.

The surface electrical resistance value of the antistatic layer is measured using a resistivity meter (Hiresta-UX MCP-HT800 manufactured by Mitsubishi Chemical Analytech Co., Ltd.).

(Thickness of Antistatic Layer)

The thickness of the antistatic layer is preferably 1 μm or less, more preferably 0.6 μm or less, still more preferably 0.4 μm or less, and particularly preferably 0.2 μm or less. In a case where the thickness of the antistatic layer is 1 μm or less, haze can be reduced.

The lower limit of the thickness of the antistatic layer is not limited. As the thickness of the antistatic layer is smaller, haze can be reduced. From the viewpoint of manufacturing suitability, the thickness of the antistatic layer is preferably 0.01 μm or more.

The thickness of the antistatic layer is obtained as an average value of 5 random points measured by cross-sectional observation with a scanning electron microscope (SEM).

(Color of Antistatic Layer)

The antistatic layer is preferably achromatic. Specifically, in CIE1976 (L*, a*, b*) color space of total reflection (incidence angle: 8°, light source: D-65 (visual field: 2°)), the L* value is preferably 10 to 90, the a* value is preferably −1.0 to 1.0, and the b* value is preferably −1.0 to 1.0.

(Method for Forming Antistatic Layer)

A method for forming the antistatic layer is not limited, and a known method can be adopted. Examples of the method for forming the antistatic layer include a method using a composition for an antistatic layer. For example, the composition for an antistatic layer is applied on an object to be coated (for example, the photosensitive layer), and the composition is dried as necessary to form an antistatic layer.

Examples of a method for producing the composition for an antistatic layer include a method of mixing the above-described components and a solvent. The mixing method is not limited, and a known method can be adopted.

The solvent is not limited, and a known solvent can be adopted. Examples of the solvent include water, and organic solvents described in the above section of “Method for Forming Photosensitive Layer”.

The composition for an antistatic layer may contain only one kind of solvent, or may contain two or more kinds of solvents.

In a case where the composition for an antistatic layer contains the solvent, the total solid content of the composition for an antistatic layer is preferably 0.5% by mass to 10% by mass, more preferably 0.5% by mass to 7% by mass, and particularly preferably 0.5% by mass to 5% by mass with respect to the total mass of the composition for an antistatic layer.

The coating method is not limited, and a known method can be adopted. Examples of the coating method include a printing method, a spray coating method, a roll coating method, a bar coating method, a curtain coating method, a spin coating method, and a die coating method (that is, a slit coating method). Among the above, a die coating method is preferable as the coating method.

The drying method is not limited, and a known method can be adopted. Examples of the drying method include natural drying, heating drying, and drying under reduced pressure. The above-described methods can be adopted alone or in combination of two or more thereof.

[Transparent Film 1]

It is preferable that the photosensitive transfer film according to the embodiment of the present disclosure further has a transparent film 1 on a side of the photosensitive layer opposite to a side on which the antistatic layer is disposed. Specifically, the photosensitive transfer film according to the embodiment of the present disclosure preferably has the transparent film 1, the photosensitive layer, and the antistatic layer in this order. In a case where the photosensitive transfer film according to the embodiment of the present disclosure has the transparent film 1, at least the photosensitive layer and the antistatic layer can be supported, and the photosensitive layer can be protected.

In a case where the photosensitive transfer film according to the embodiment of the present disclosure has the transparent film 1, the transparent film 1 is preferably the outermost layer on the side opposite to the side on which the antistatic layer is disposed with respect to the photosensitive layer.

The transparent film 1 is not limited, and a known transparent film can be adopted. Examples of the transparent film 1 include a polyethylene terephthalate film, a polypropylene film, a polyethylene film, a polystyrene film, and a polycarbonate film. Among the above, from the viewpoint of optical characteristics, the transparent film 1 is preferably a polypropylene or a polyethylene terephthalate film.

The transparent film 1 is also available, for example, as ALPHAN (registered trademark) FG-201 manufactured by Oji F-Tex Co., Ltd., Cerapeel (registered trademark) 25WZ manufactured by TORAY ADVANCED FILM CO., LTD., or LUMIRROR (registered trademark) 16QS62 and LUMIRROR (registered trademark) 16FB40 manufactured by Toray Industries, Inc.

From the viewpoint of ease of handling and general-purpose properties, the thickness of the transparent film 1 is preferably 5 μm to 200 μm, more preferably 10 μm to 150 μm, and still more preferably 10 μm to 50 μm.

The thickness of the transparent film 1 is obtained as an average value of 5 random points measured by cross-sectional observation with a scanning electron microscope (SEM).

In order to make it easier to peel off the transparent film 1 from the photosensitive layer, it is preferable that the adhesive force between the transparent film 1 and the photosensitive layer is smaller than the adhesive force between a transparent film 2 and the antistatic layer.

In addition, the transparent film 1 preferably has 5 pieces/m² or less of the number of fisheyes with a diameter of 80 μm or more in the transparent film 1. The “fisheye” means that, for example, in a case where a material is hot-melted, kneaded, extruded, biaxially stretched, cast or the like to produce a film, foreign substances, undissolved substances, oxidatively deteriorated substances, and the like of the material are incorporated into the film.

The number of particles having a diameter of 3 μm or more included in the transparent film 1 is preferably 30 particles/mm² or less, more preferably 10 particles/mm² or less, and still more preferably 5 particles/mm² or less. As a result, it is possible to suppress defects caused by ruggedness due to the particles included in the transparent film 1 being transferred to the photosensitive layer.

From the viewpoint of imparting take-up property, the arithmetic average roughness Ra on a surface of the transparent film 1 opposite to a surface in contact with the photosensitive layer is preferably 0.01 μm or more, more preferably 0.02 μm or more, and still more preferably 0.03 μm or more. On the other hand, the above-described arithmetic average roughness Ra is preferably less than 0.50 more preferably 0.40 μm or less, and still more preferably 0.30 μm or less.

From the viewpoint of suppressing defects during transfer, the arithmetic average roughness Ra on the surface of the transparent film 1 in contact with the photosensitive layer is preferably 0.01 μm or more, more preferably 0.02 μm or more, and still more preferably 0.03 μm or more. On the other hand, the above-described arithmetic average roughness Ra is preferably less than 0.50 more preferably 0.40 μm or less, and still more preferably 0.30 μm or less.

[Transparent Film 2]

It is preferable that the photosensitive transfer film according to the embodiment of the present disclosure further has a transparent film 2 on a side of the antistatic layer opposite to a side on which the photosensitive layer is disposed. Specifically, the photosensitive transfer film according to the embodiment of the present disclosure preferably has the photosensitive layer, the antistatic layer, and the transparent film 2 in this order. In a case where the photosensitive transfer film according to the embodiment of the present disclosure has the transparent film 2, at least the photosensitive layer and the antistatic layer can be supported, and the antistatic layer can be protected. Further, in a case where the photosensitive transfer film according to the embodiment of the present disclosure has the transparent film 2, the photosensitive layer can be exposed through the transparent film 2, as described later.

In a case where the photosensitive transfer film according to the embodiment of the present disclosure has the transparent film 2, the transparent film 2 is preferably the outermost layer on the side opposite to the side on which the photosensitive layer is disposed with respect to the antistatic layer.

In addition, in a case where the photosensitive transfer film according to the embodiment of the present disclosure has the transparent film 1 and the transparent film 2, the photosensitive transfer film according to the embodiment of the present disclosure preferably has the transparent film 1, the photosensitive layer, the antistatic layer, and the transparent film 2 in this order.

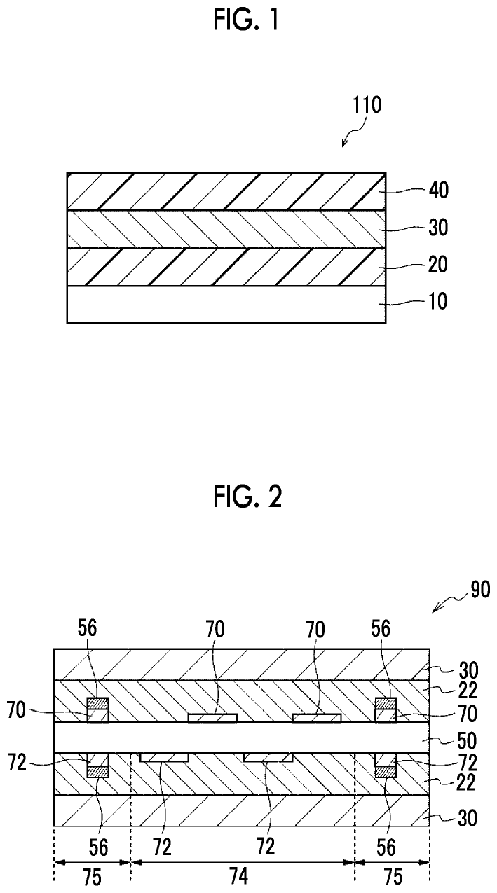

An embodiment of the photosensitive transfer film according to the embodiment of the present disclosure will be described with reference to the drawing. FIG. 1 is a schematic cross sectional view showing an example of the photosensitive transfer film according to the embodiment of the present disclosure. A photosensitive transfer film 110 shown in FIG. 1 has a transparent film 10, a photosensitive layer 20, an antistatic layer 30, and a transparent film 40 in this order. The transparent film 10 is an example of the transparent film 1. The transparent film 40 is an example of the transparent film 2.

The transparent film 2 is not limited, and a known transparent film can be adopted. Examples of the transparent film 2 include a polyethylene terephthalate film, a polypropylene film, a polystyrene film, and a polycarbonate film. Among the above, from the viewpoint of optical characteristics, the transparent film 2 is preferably a polyethylene terephthalate film.

The transparent film 2 is also available, for example, as COSMOSHINE (registered trademark) A4100, COSMOSHINE (registered trademark) A4300, and COSMOSHINE (registered trademark) A8300 (all manufactured by TOYOBO Co., Ltd.), LUMIRROR (registered trademark) 16FB40 manufactured by Toray Industries, Inc., and LUMIRROR (registered trademark) 16QS62 manufactured by Toray Industries, Inc.

From the viewpoint of ease of handling and general-purpose properties, the thickness of the transparent film 2 is preferably 5 μm to 200 μm, more preferably 10 μm to 150 μm, and still more preferably 10 μm to 50 μm.

The thickness of the transparent film 2 is obtained as an average value of 5 random points measured by cross-sectional observation with a scanning electron microscope (SEM).

From the viewpoint of improving exposure sensitivity, the haze of the transparent film 2 is preferably small, more preferably 2% or less, and particularly preferably 0.5% by mass. From the viewpoint of improving handleability, the haze of the transparent film 2 is preferably 0.1% or more.

From the viewpoint of improving exposure sensitivity and improving resolution, it is preferable that the number of fine particles, foreign substances, and defects (for example, pinholes) included in the transparent film 2 is small. The number of fine particles, foreign substances, and defects having a diameter of 1 μm or more included in the transparent film 2 is preferably 50 pieces/10 mm² or less and more preferably 10 pieces/10 mm² or less. From the viewpoint of improving handleability, the number of fine particles, foreign substances, and defects having a diameter of 1 μm or more included in the transparent film 2 is preferably 1 piece/10 mm² or more.

Preferred aspects of the transparent film 2 are described in, for example, paragraphs “0017” and “0018” of JP2014-85643A, paragraphs “0019” to “0026” of JP2016-27363A, paragraphs “0041” to “0057” of WO2012/081680A, and paragraphs “0029” to “0040” of WO2018/179370A, and the contents of these publications are incorporated in the present specification.

In addition, particularly preferred examples of the transparent film 2 include a biaxial stretching polyethylene terephthalate film having a thickness of 16 μm, a biaxial stretching polyethylene terephthalate film having a thickness of 12 μm, and a biaxial stretching polyethylene terephthalate film having a thickness of 10 μm.

[Refractive Index Adjusting Layer]

The photosensitive transfer film according to the embodiment of the present disclosure may further have a refractive index adjusting layer. In a case where the photosensitive transfer film according to the embodiment of the present disclosure has the refractive index adjusting layer, it is preferable that the photosensitive transfer film according to the embodiment of the present disclosure further has the refractive index adjusting layer on the side of the photosensitive layer opposite to the side on which the antistatic layer is disposed. In addition, in a case where the photosensitive transfer film according to the embodiment of the present disclosure has the transparent film 1, it is preferable that the refractive index adjusting layer is disposed between the transparent film 1 and the photosensitive layer.

The refractive index adjusting layer is not limited, and a known refractive index adjusting layer can be adopted. Examples of a material contained in the refractive index adjusting layer include a binder and particles.

The binder is not limited, and a known binder can be adopted. Examples of the binder include the alkali-soluble acrylic resin described in the above section of “Photosensitive Layer” and the binder polymer described in the above section of “Antistatic Layer”.

The particles are not limited, and known particles can be adopted. Examples of the particles include zirconium oxide particles (ZrO₂ particles), niobium oxide particles (Nb₂O₅ particles), titanium oxide particles (TiO₂ particles), and silicon dioxide particles (SiO₂ particles).

In addition, the refractive index adjusting layer preferably contains a metal oxidation inhibitor. In a case where the refractive index adjusting layer contains a metal oxidation inhibitor, oxidation of metal in contact with the refractive index adjusting layer can be suppressed.

Preferred examples of the metal oxidation inhibitor include a compound having an aromatic ring including a nitrogen atom in the molecule. Specific examples of the metal oxidation inhibitor include imidazole, benzimidazole, tetrazole, mercaptothiadiazole, and benzotriazole.

The refractive index of the refractive index adjusting layer is preferably 1.50 or more, more preferably 1.55 or more, and particularly preferably 1.60 or more.

The upper limit of the refractive index of the refractive index adjusting layer is not particularly limited. The refractive index of the refractive index adjusting layer is preferably 2.10 or less and more preferably 1.85 or less.

The thickness of the refractive index adjusting layer is preferably 500 nm or less, more preferably 110 nm or less, and particularly preferably 100 nm or less.

The thickness of the refractive index adjusting layer is preferably 20 nm or more and more preferably 50 nm or more.

The thickness of the refractive index adjusting layer is obtained as an average value of 5 random points measured by cross-sectional observation with a scanning electron microscope (SEM).

A method for forming the refractive index adjusting layer is not limited, and a known method can be adopted. Examples of the method for forming the refractive index adjusting layer include a method using a composition for a refractive index adjusting layer. For example, the composition for a refractive index adjusting layer is applied on an object to be coated, and the composition is dried as necessary to form a refractive index adjusting layer.

Examples of a method for producing the composition for a refractive index adjusting layer include a method of mixing the above-described components and a solvent. The mixing method is not limited, and a known method can be adopted.

The solvent is not limited, and a known solvent can be adopted. Examples of the solvent include water, and organic solvents described in the above section of “Method for Forming Photosensitive Layer”.

As the coating method and drying method, the coating method and drying method described in the above section of “Method for Forming Photosensitive Layer” can be adopted, respectively.

[Thermoplastic Resin Layer]

The photosensitive transfer film according to the embodiment of the present disclosure may further have a thermoplastic resin layer. In a case where the photosensitive transfer film according to the embodiment of the present disclosure has the thermoplastic resin layer, it is preferable that the photosensitive transfer film according to the embodiment of the present disclosure further has the thermoplastic resin layer on the side of the antistatic layer opposite to the side on which the photosensitive layer is disposed. In addition, in a case where the photosensitive transfer film according to the embodiment of the present disclosure has the transparent film 2, it is preferable that the thermoplastic resin layer is disposed between the antistatic layer and the transparent film 2.

The thermoplastic resin functions as a cushion material which absorbs ruggedness of a surface of the base material. Therefore, it is possible to suppress generation of air bubbles in a case where the photosensitive transfer film is attached to the base material.

The thermoplastic resin layer preferably has alkali solubility. In addition, the thermoplastic resin layer preferably has properties capable of being deformed in accordance with ruggedness.

In addition, the thermoplastic resin layer may be a layer which can be removed by a development treatment, or may be a layer which can be peeled off from the photosensitive layer at the same time as the transparent film 2 is peeled off.

The thermoplastic resin layer preferably includes an organic polymer substance described in JP1993-72724A (JP-H05-72724A), and more preferably includes an organic polymer substance having a softening point approximately 80° C. or lower by a Vicat method (specifically, polymer softening point measurement method using an American Society for Testing and Materials ASTM D1235).

The thickness of the thermoplastic resin layer is preferably 3 μm to 30 μm, more preferably 4 μm to 25 μm, and particularly preferably 5 μm to 20 μm.

In a case where the thickness of the thermoplastic resin layer is 3 μm or more, followability with respect to the ruggedness of the surface of the base material is improved, and the ruggedness of the surface of the base material can be effectively absorbed.

In a case where the thickness of the thermoplastic resin layer is 30 μm or less, since the manufacturing suitability is more improved, for example, burden of the drying (so-called drying for removing the solvent) in a case of applying and forming the thermoplastic resin layer is further reduced, and the development time of the thermoplastic resin layer after the transfer is further shortened.

The thermoplastic resin layer can be formed by applying and, as necessary, drying a composition for forming a thermoplastic resin layer including a solvent and a thermoplastic organic polymer on an object to be coated.

Specific examples of coating and drying methods in the forming method of the thermoplastic resin layer are the same as the specific examples of coating and drying in the forming method of the photosensitive layer, respectively.

The solvent is not particularly limited as long as the solvent dissolves the polymer component forming the thermoplastic resin layer.

Examples of the solvent include organic solvents (for example, methyl ethyl ketone, cyclohexanone, propylene glycol monomethyl ether acetate, n-propanol, and 2-propanol).

The viscosity of the thermoplastic resin layer measured at 100° C. is preferably 1,000 Pa·s to 10,000 Pa·s. In addition, the viscosity of the thermoplastic resin layer measured at 100° C. is preferably lower than the viscosity of the photosensitive layer measured at 100° C.

[Interlayer]

The photosensitive transfer film according to the embodiment of the present disclosure may further have an interlayer. In a case where the photosensitive transfer film according to the embodiment of the present disclosure has the interlayer, it is preferable that the photosensitive transfer film according to the embodiment of the present disclosure further has the interlayer on the side of the antistatic layer opposite to the side on which the photosensitive layer is disposed. In a case where the photosensitive transfer film according to the embodiment of the present disclosure has the transparent film 2, it is preferable that the interlayer is disposed between the antistatic layer and the transparent film 2. In a case where the photosensitive transfer film according to the embodiment of the present disclosure has the thermoplastic resin layer, it is preferable that the interlayer is disposed between the antistatic layer and the thermoplastic resin layer.

Examples of a component included in the interlayer include at least one polymer selected from the group consisting of polyvinyl alcohol, polyvinylpyrrolidone, and cellulose.

In addition, as the interlayer, a component described in JP1993-72724A (JP-H05-72724A) as a “separation layer” can also be used.

For example, the interlayer can be formed by applying and, as necessary, drying a composition for forming an interlayer, that includes a solvent which does not dissolve the thermoplastic resin layer and the above-described polymer as the component of the interlayer, to an object to be coated.

Specific examples of coating and drying methods in the forming method of the interlayer are the same as the specific examples of coating and drying in the forming method of the photosensitive layer, respectively.

[Layer Configuration of Photosensitive Transfer Film]

Examples of a layer configuration of the photosensitive transfer film according to the embodiment of the present disclosure are shown below. In the layer configuration shown below, “/” represents a boundary between layers.

(1) photosensitive layer/antistatic layer

(2) transparent film 1/photosensitive layer/antistatic layer

(3) photosensitive layer/antistatic layer/transparent film 2

(4) transparent film 1/photosensitive layer/antistatic layer/transparent film 2

(5) transparent film 1/refractive index adjusting layer/photosensitive layer/antistatic layer/transparent film 2

(6) transparent film 1/photosensitive layer/antistatic layer/thermoplastic resin layer/transparent film 2

(7) transparent film 1/photosensitive layer/antistatic layer/interlayer/thermoplastic resin layer/transparent film 2

[Manufacturing Method of Photosensitive Transfer Film]

A manufacturing method of the photosensitive transfer film according to the embodiment of the present disclosure is not limited, and a known method can be adopted. The photosensitive transfer film according to the embodiment of the present disclosure can be manufactured, for example, by using the above-described methods for forming each layer.

Hereinafter, an example of the manufacturing method of the photosensitive transfer film having the transparent film 1, the photosensitive layer, the antistatic layer, and the transparent film 2 in this order will be described. The above-described manufacturing method of the photosensitive transfer film includes, for example, a step of forming a photosensitive layer on the transparent film 1, a step of forming an antistatic layer on the photosensitive layer, and a step of laminating the transparent film 2 on the antistatic layer. As the step of forming a photosensitive layer, the method described in the above section of “Method for Forming Photosensitive Layer” can be adopted. In addition, as the step of forming an antistatic layer, the method described in the above section of “Method for Forming Antistatic Layer” can be adopted.

In the manufacturing method of the photosensitive transfer film having the transparent film 1, the photosensitive layer, the antistatic layer, and the transparent film 2 in this order, it is preferable to include a step of applying the composition for an antistatic layer and the composition for a photosensitive layer to the transparent film 2 in this order. By forming the antistatic layer and the photosensitive layer on the transparent film 2 in this order, the region where the antistatic agent is not detected can be easily adjusted to the above-described range.

<Manufacturing Method of Antistatic Pattern>

The manufacturing method of an antistatic pattern according to the embodiment of the present disclosure is not limited as long as it is a method using the photosensitive transfer film according to the embodiment of the present disclosure. It is preferable that the manufacturing method of an antistatic pattern according to the embodiment of the present disclosure includes, in the following order, a step (hereinafter, also referred to as a “lamination step”) of laminating the photosensitive layer and the antistatic layer of the above-described photosensitive transfer film on a base material in this order, a step (hereinafter, also referred to as an “exposure step”) of performing a pattern exposure of the photosensitive layer, and a step (hereinafter, also referred to as a “development step”) of developing the photosensitive layer. By including the above-described steps, the manufacturing method of an antistatic pattern according to the embodiment of the present disclosure can form an antistatic pattern having excellent transparency and bend resistance, in which patterning properties of the antistatic layer is excellent.

[Lamination Step]

In the lamination step, the photosensitive layer and the antistatic layer in the above-described photosensitive transfer film are laminated on a base material in this order.

As the photosensitive transfer film used in the lamination step, the photosensitive transfer film described in the above section of “Photosensitive Transfer Film” can be adopted, and the same applies to the preferred embodiment.

As the base material, a glass base material or a resin base material is preferable. In addition, the base material is preferably a transparent base material and more preferably a transparent resin base material.

As the glass base material, tempered glass such as GORILLA GLASS (registered trademark) manufactured by Corning Incorporated can be used.

As the resin base material, it is preferable to use at least one of an optically undistorted resin base material and a highly transparent resin base material. Examples of a resin constituting the resin base material include polyethylene terephthalate (PET), polyethylene naphthalate (PEN), polycarbonate (PC), triacetyl cellulose (TAC), polyimide (PI), polybenzoxazole (PBO), and cycloolefin polymer (COP).

As a material of the transparent base material, a material described in JP2010-86684A, JP2010-152809A, and JP2010-257492A is preferable.

The refractive index of the base material is preferably 1.50 to 1.52.

The thickness of the base material is not limited, and may be appropriately set within a range of 10 μm to 1 mm depending on the application, for example.

The thickness of the base material is obtained as an average value of 5 random points measured by cross-sectional observation with a scanning electron microscope (SEM) or an optical microscope.

The base material may have an electrode layer on at least one surface. Examples of the electrode layer include a layer including a metal or a metal oxide.

Examples of the metal include gold, silver, copper, molybdenum, aluminum, titanium, chromium, zinc, manganese, and alloy formed of two or more kinds of these metal elements.

Examples of the metal oxide include indium tin oxide (ITO) and indium zinc oxide (IZO).

The electrode layer is preferably a transparent electrode layer. Examples of the transparent electrode layer include an indium tin oxide (ITO) layer, an indium zinc oxide (IZO) layer, and a layer containing silver nanowires. Among the above, the transparent electrode layer is preferably an indium tin oxide (ITO) layer or a layer containing silver nanowires, and more preferably a layer containing silver nanowires.

Examples of a method of laminating the photosensitive layer and the antistatic layer in the photosensitive transfer film on the base material in this order include a method (hereinafter, also referred to as a “lamination”) of laminating the base material and the photosensitive transfer film. Specific examples thereof include a method of laminating the base material and the photosensitive transfer film such that the photosensitive layer in the photosensitive transfer film and the base material come into contact with each other. By laminating the base material and the photosensitive transfer film by the above-described method, a structure body having the base material, the photosensitive layer, and the antistatic layer in this order is formed.

In a case where the photosensitive transfer film has the above-described transparent film 1, the base material and the photosensitive transfer film are laminated after peeling off the transparent film 1 from the photosensitive transfer film. Specifically, first, the photosensitive layer is exposed by peeling off the transparent film 1 from the photosensitive transfer film, and then the base material and the photosensitive transfer film are laminated such that the exposed photosensitive layer and the base material come into contact with each other.

In a case where the photosensitive transfer film has the above-described transparent film 2, the base material and the photosensitive transfer film can be laminated without peeling off the transparent film 2 from the photosensitive transfer film. After laminating the base material and the photosensitive transfer film, the transparent film 2 may be peeled off from the obtained structure body (for example, a structure body having a laminated structure of base material/photosensitive layer/antistatic layer/transparent film 2). In addition, the exposure step described later may be performed without peeling off the transparent film 2 from the structure body, that is, while leaving the transparent film 2.

In a case where the photosensitive transfer film has a layer other than the photosensitive layer and the antistatic layer (examples thereof include a refractive index adjusting layer, a thermoplastic resin layer, and an interlayer; hereinafter, referred to as “other layers” in this paragraph), the other layers are laminated on the base material together with the photosensitive layer and the antistatic layer while maintaining the positional relationship between the photosensitive layer and the antistatic layer. For example, in a case where the photosensitive transfer film has the refractive index adjusting layer, the photosensitive layer, and the antistatic layer in this order, in the lamination step, the refractive index adjusting layer, the photosensitive layer, and the antistatic layer are laminated on the base material in this order.

The lamination can be performed using a known laminator. Examples of the laminator include a vacuum laminator and an auto-cut laminator.

The laminating conditions are not limited, and general conditions can be adopted.

The laminating temperature is preferably 80° C. to 150° C., more preferably 90° C. to 150° C., and particularly preferably 100° C. to 150° C. In a case of using a laminator including a rubber roller, the laminating temperature indicates a temperature of the rubber roller.

A temperature of the base material in a case of laminating is not particularly limited. The temperature of the base material in a case of laminating is, for example, 10° C. to 150° C., and is preferably 20° C. to 150° C. and more preferably 30° C. to 150° C.

In a case of using the resin base material as the base material, the temperature of the base material in a case of laminating is preferably 10° C. to 80° C., more preferably 20° C. to 60° C., and particularly preferably 30° C. to 50° C.

The linear pressure in a case of laminating is preferably 0.5 N/cm to 20 N/cm, more preferably 1 N/cm to 10 N/cm, and particularly preferably 1 N/cm to 5 N/cm.

The transportation speed (laminating speed) in a case of laminating is preferably 0.5 m/min to 5 m/min and more preferably 1.5 m/min to 3 m/min.

[Exposure Step]

In the exposure step, pattern exposure is performed to the above-described photosensitive layer. Here, the “pattern exposure” refers to exposure of the aspect of performing the exposure in a patterned shape, that is, the embodiment in which an exposed portion and an unexposed portion are present. By performing the pattern exposure to the photosensitive layer, the exposed portion of the photosensitive layer is cured. Meanwhile, the unexposed portion of the photosensitive layer is not cured, and is removed in the development step described later. In addition, in a case where the antistatic layer contains the curing component, the exposed portion of the antistatic layer is also cured.

The pattern exposure may be an exposure through a mask or may be a digital exposure using a laser or the like.

As a light source of the pattern exposure, a light source can be appropriately selected, as long as it can emit light at a wavelength region (for example, 365 nm or 405 nm) at which at least the photosensitive layer can be cured.

Examples of the light source include various lasers, a light emitting diode (LED), an ultra-high pressure mercury lamp, a high pressure mercury lamp, and a metal halide lamp.

The exposure amount is preferably 5 mJ/cm² to 200 mJ/cm² and more preferably 10 mJ/cm² to 200 mJ/cm².

The shape of the pattern is not limited, and may be appropriately set according to the application, for example.

In a case where the photosensitive transfer film having the transparent film 2 is used in the above-described lamination step, the pattern exposure may be performed after peeling off the transparent film 2, or the pattern exposure may be performed before peeling off the transparent film 2 and then the transparent film 2 may be peeled off.

In addition, in the exposure step, a heat treatment [so-called post exposure bake (PEB)] may be performed to the photosensitive layer after the pattern exposure and before the development step described later.

[Development Step]

In the development step, the above-described photosensitive layer is developed. By developing the photosensitive layer, the unexposed portion of the photosensitive layer is removed, and the antistatic layer disposed on the unexposed portion of the photosensitive layer is also removed. As a result, a patterned antistatic layer (that is, an antistatic pattern) is formed on the cured photosensitive layer pattern (that is, a resist pattern). Therefore, the antistatic pattern formed by the manufacturing method of an antistatic pattern according to the embodiment of the present disclosure can present the pattern of the cured photosensitive layer from being charged.

A developer used for the development is not limited, and a known developer can be adopted. Examples of the developer include developers described in JP1993-72724A (JP-H05-72724A).

In the development step, as the developer, an alkali aqueous solution is preferably used. Examples of an alkali compound which can be included in the alkali aqueous solution include sodium hydroxide, potassium hydroxide, sodium carbonate, potassium carbonate, sodium hydrogen carbonate, potassium hydrogencarbonate, tetramethyl ammonium hydroxide, tetraethyl ammonium hydroxide, tetrapropyl ammonium hydroxide, tetrabutylammonium hydroxide, and choline (2-hydroxyethyltrimethylammonium hydroxide).

The pH of the alkali aqueous solution at 25° C. is preferably 8 to 13, more preferably 9 to 12, and particularly preferably 10 to 12.

The content of the alkali compound in the alkali aqueous solution is preferably 0.1% by mass to 5% by mass and more preferably 0.1% by mass to 3% by mass with respect to the total mass of the alkali aqueous solution.

The developer may include an organic solvent having miscibility with water. Examples of the organic solvent include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, acetone, methyl ethyl ketone, cyclohexanone, ε-caprolactone, γ-butyrolactone, dimethylformamide, dimethylacetamide, hexamethylphosphoramide, ethyl lactate, methyl lactate, ε-caprolactam, and N-methylpyrrolidone.

The concentration of the organic solvent in the developer is preferably 0.1% by mass to 30% by mass.

The developer may include a known surfactant. The concentration of the surfactant in the developer is preferably 0.01% by mass to 10% by mass.

The liquid temperature of the developer is preferably 20° C. to 40° C.

Examples of the development method include methods such as puddle development, shower development, shower and spin development, and dip development.

In a case of the shower development, the unexposed portion of the photosensitive layer is removed by spraying the developer to the photosensitive layer after the pattern exposure as a shower.

In a case of using the photosensitive transfer film having at least one of the photosensitive layer, the thermoplastic resin layer, or the interlayer, after the lamination step and before the development of the photosensitive layer, an alkali solution having a low solubility of the photosensitive layer may be sprayed as a shower, and at least one of the thermoplastic resin layer or the interlayer (both layers, in a case where both layers are present) may be removed in advance.

In addition, after the development, the development residue is preferably removed by spraying a washing agent with a shower and rubbing with a brush or the like.

The development step may include a stage of performing the development, and a stage of performing the heat treatment (hereinafter, also referred to as “post baking”) with respect to the pattern obtained by the development. A resistance value of the transparent electrode layer can also be adjusted by the above-described post baking. In a case where the base material is the resin base material, a temperature of the post baking is preferably 100° C. to 160° C. and more preferably 130° C. to 160° C.

In a case where the photosensitive layer contains a (meth)acrylic resin having a carboxy group, at least a part of the (meth)acrylic resin can be changed to carboxylic acid anhydride by the post baking. In a case of being changed to carboxylic acid anhydride, developability and hardness of the cured film are excellent.

The development step may include a stage of performing the development, and a stage of exposing the pattern obtained by the development (hereinafter, also referred to as “post exposure”). In a case where the development step includes both a stage of performing the post exposure and a stage of performing the post baking, it is preferable to perform the post-baking after the post-exposure.

With regard to the pattern exposure and the development, for example, a description described in paragraphs “0035” to “0051” of JP2006-23696A can be referred to.

The manufacturing method of an antistatic pattern according to the embodiment of the present disclosure may include a step other than the above-described steps. The manufacturing method of an antistatic pattern according to the embodiment of the present disclosure may include, for example, a step (for example, a washing step) which may be provided in a normal photolithography step.

<Laminate>

The laminate according to the embodiment of the present disclosure includes, in the following order, a base material, a transparent electrode layer, a cured composition layer of a photosensitive composition, which has a patterned shape, and an antistatic layer having the same patterned shape as the patterned shape of the cured composition layer. Since the laminate according to the embodiment of the present disclosure has the above-described configuration, charging of the patterned electrode protective film (that is, the cured composition layer of the photosensitive composition) is prevented.

(Base Material)

The laminate according to the embodiment of the present disclosure has a base material.

The base material is not limited, and a known base material can be adopted. Examples of the base material include the base material described in the above section of “Manufacturing Method of Antistatic Pattern”. A preferred embodiment of the base material in the laminate according to the embodiment of the present disclosure is the same as that of the base material described in the above section of “Manufacturing Method of Antistatic Pattern”.

The thickness of the base material is not limited, and for example, may be appropriately set within a range of 10 μm to 1 mm.

The thickness of the base material is obtained as an average value of 5 random points measured by cross-sectional observation with a scanning electron microscope (SEM).

(Transparent Electrode Layer)

The laminate according to the embodiment of the present disclosure has a transparent electrode layer.

The transparent electrode layer is not limited, and a known transparent electrode layer can be adopted. Examples of the transparent electrode layer include an indium tin oxide (ITO) layer, an indium zinc oxide (IZO) layer, a copper layer, and a layer containing silver nanowires. Among the above, the transparent electrode layer is preferably an indium tin oxide (ITO) layer or a layer containing silver nanowires, and more preferably a layer containing silver nanowires.

From the viewpoint of conductivity and transparency, the thickness of the transparent electrode layer is preferably 0.01 μm to 1 μm and more preferably 0.03 μm to 0.5 μm.

The thickness of the transparent electrode layer is obtained as an average value of 5 random points measured by cross-sectional observation with a scanning electron microscope (SEM).

A method for forming the transparent electrode layer is not limited, and a known method can be adopted. Examples of the method for forming the transparent electrode layer include a sputtering method and a coating method.

(Cured Composition Layer of Photosensitive Composition)

The laminate according to the embodiment of the present disclosure has a cured composition layer (hereinafter, also simply referred to as a “cured composition layer”) of a photosensitive composition, which has a patterned shape. In the laminate according to the embodiment of the present disclosure, the cured composition layer can function as a layer protecting the transparent electrode layer, that is, as an electrode protective film.

In the present disclosure, the “cured composition layer of a photosensitive composition” means a layer formed by curing the photosensitive composition. In a case where the photosensitive composition contains a solvent, the “cured composition layer of a photosensitive composition” means a layer formed by curing solid content of the photosensitive composition.

The cured composition layer in which a photosensitive composition is a precursor contains components constituting the photosensitive composition described later. A curable component (for example, a polymerizable compound) contained in the photosensitive composition may be present in the cured composition layer as, for example, a polymerized cured product. In addition, the cured composition layer may contain a component which cures the photosensitive composition (for example, a polymerizable compound and a photopolymerization initiator) and a solvent, as long as the effects of the laminate according to the embodiment of the present disclosure are not impaired.

It is preferable that the cured composition layer contains an acrylic resin. In a case where the cured composition layer contains an acrylic resin, transparency can be improved.

The total proportion of a constitutional unit derived from (meth)acrylic acid and a constitutional unit derived from (meth)acrylic acid ester in the acrylic resin is preferably 30 mol % or more and more preferably 50 mol % or more.

The acrylic resin in the cured composition layer may be an alkali-soluble acrylic resin. In a case where the acrylic resin is an alkali-soluble acrylic resin, for example, as will be described later, it is possible to improve developability in a case of forming a cured composition layer having a patterned shape through pattern exposure and development.

A preferred embodiment of the alkali-soluble acrylic resin in the cured composition layer is the same as that of the alkali-soluble acrylic resin described in the above section of “Photosensitive Layer”.

The cured composition layer may contain only one kind of acrylic resin, or may contain two or more kinds of acrylic resins.

From the viewpoint of transparency, the content of the acrylic resin is preferably 10% by mass to 90% by mass, more preferably 20% by mass to 80% by mass, and particularly preferably 30% by mass to 70% by mass with respect to the total mass of the cured composition layer.

The patterned shape of the cured composition layer is not limited, and may be appropriately set according to the application, for example. Examples of the patterned shape include a linear shape, a curved shape, a diamond shape, and a lattice shape.

The thickness of the cured composition layer is preferably 10 μm or less, more preferably 8 μm or less, still more preferably 5 μm or less, and particularly preferably 4 μm or less. Since the thickness of the cured composition layer is 10 μm or less, bend resistance can be improved.

From the viewpoint of manufacturing suitability, the thickness of the cured composition layer is preferably 0.05 μm or more.

The thickness of the cured composition layer is obtained as an average value of 5 random points measured by cross-sectional observation with a scanning electron microscope (SEM).

A method for forming the cured composition layer is not limited as long as it is a method of curing the photosensitive composition. Examples of the method for forming the cured composition layer include a method of performing pattern exposure to a layer (hereinafter, also referred to as a “photosensitive composition layer”) formed by applying a photosensitive composition to a base material, and developing the photosensitive composition layer. In the above-described method, it is preferable to perform pattern exposure and develop the photosensitive composition layer together with the antistatic layer. In addition, in a case where the photosensitive composition contains a solvent, it is preferable to dry the photosensitive composition after applying the photosensitive composition and before the pattern exposure.

The photosensitive composition is not limited as long as it contains a curable component. The photosensitive composition preferably contains an acrylic resin, a polymerizable compound, and a photopolymerization initiator. The photosensitive composition containing the polymerizable compound and the photopolymerization initiator can be cured by irradiation with light.

The acrylic resin in the photosensitive composition is as described above as one component of the cured composition layer, and the same applies to the preferred embodiment.

The polymerizable compound is not limited, and a known polymerizable compound can be adopted. Examples of the polymerizable compound include the radically polymerizable compound having an ethylenically unsaturated group (that is, the ethylenically unsaturated compound), which is described in the above section of “Photosensitive Layer”. A preferred embodiment of the ethylenically unsaturated compound in the photosensitive composition is the same as that of the ethylenically unsaturated compound described in the above section of “Photosensitive Layer”.

The photopolymerization initiator is not limited and a known photopolymerization initiator can be adopted. Examples of the photopolymerization initiator include the photopolymerization initiator described in the above section of “Photosensitive Layer”. A preferred embodiment of the photopolymerization initiator in the photosensitive composition is the same as that of the photopolymerization initiator described in the above section of “Photosensitive Layer”.

The photosensitive composition may contain a solvent as necessary. As the solvent, for example, the solvent described in the above section of “Method for Forming Photosensitive Layer” can be adopted.

As necessary, the photosensitive composition may contain each component (for example, a surfactant) described in the above section of “Photosensitive Layer” as a component other than the above.

A method for producing the photosensitive composition is not limited, and a known method can be adopted. For example, the photosensitive composition can be produced by mixing each of the above-described components and, as necessary, a solvent.

As the coating method and drying method, the coating method and drying method described in the above section of “Method for Forming Photosensitive Layer” can be adopted, respectively.

As the pattern exposure method and developing method, the pattern exposure method and developing method described in the above section of “Manufacturing Method of Antistatic Pattern” can be adopted, respectively.

In addition, examples of the method for forming the cured composition layer also include a method using the photosensitive transfer film according to the embodiment of the present disclosure, as described later.

(Antistatic Layer)

The laminate according to the embodiment of the present disclosure has an antistatic layer which has the same patterned shape as the above-described patterned shape of the above-described cured composition layer. Since the laminate according to the embodiment of the present disclosure has an antistatic layer which has the same patterned shape as the patterned shape of the cured composition layer, charging of the patterned electrode protective film (that is, the cured composition layer of the photosensitive composition) is prevented.

In the present disclosure, the term “same patterned shape” is not limited to a case where the patterned shape is completely the same, and includes a case where the patterned shapes do not completely match within a range in which the effects of the laminate according to the embodiment of the present disclosure are exhibited, for example, due to a manufacturing error or the like.

As the antistatic layer in the laminate according to the embodiment of the present disclosure, for example, the antistatic layer described in the above section of “Photosensitive Transfer Film” can be adopted. A preferred embodiment of the antistatic layer in the laminate according to the embodiment of the present disclosure is the same as that of the antistatic layer described in the above section of “Photosensitive Transfer Film”. Hereinafter, a preferred embodiment of the antistatic layer will be described. However, the preferred embodiment of the antistatic layer is not limited to the following embodiment, and the preferred embodiment of the antistatic layer described in the above section of “Photosensitive Transfer Film” can be appropriately adopted.

The antistatic layer preferably contains, as the antistatic agent, at least one compound selected from the group consisting of an ionic liquid, an ionic conductive polymer, an ionic conductive filler, and an electrically conductive polymer. The ionic liquid, the ionic conductive polymer, the ionic conductive filler, and the electrically conductive polymer are synonymous with the ionic liquid, the ionic conductive polymer, the ionic conductive filler, and the electrically conductive polymer described in the above section of “Photosensitive Transfer Film”, respectively.

It is preferable that an antistatic agent is not detected in a region from a surface of the cured composition layer opposite to the antistatic layer to 40% of a total thickness of the cured composition layer and the antistatic layer, it is more preferable to be not detected in a region up to 80%, and it is particularly preferable to be not detected in a region up to 90%. The region where the antistatic agent is not detected is measured by a method according to the measuring method described in the above section of “Photosensitive Transfer Film” (that is, TOF-SIMS). In the laminate according to the embodiment of the present disclosure, in a case where the region where the antistatic agent is not detected is measured by TOF-SIMS, it is preferable that peak intensities of specific fragment ions due to molecules existing in a depth direction of the antistatic layer and the cured composition layer are measured from a surface of the antistatic layer toward the cured composition layer.

The surface electrical resistance value of the antistatic layer is preferably 1.0×10¹²Ω/□ or less, more preferably 1.0×10¹¹Ω/□ or less, and particularly preferably 5.0×10¹⁰Ω/□ or less. In a case where the surface electrical resistance of the antistatic layer is within the above-described range, the surface electrical resistance of the antistatic layer can be lowered, so that the generation of static electricity in a case of peeling off the film or the like disposed on the antistatic layer can be suppressed.

The lower limit of the surface electrical resistance value of the antistatic layer is not limited. The surface electrical resistance value of the antistatic layer is preferably 1.0×10⁶Ω/□ or more and more preferably 1.0×10⁷Ω/□ or more.

The surface electrical resistance value of the antistatic layer is measured using a resistivity meter (Hiresta-UX MCP-HT800 manufactured by Mitsubishi Chemical Analytech Co., Ltd.).

The thickness of the antistatic layer is preferably 1 μm or less, more preferably 0.6 μm or less, still more preferably 0.4 μm or less, and particularly preferably 0.2 μm or less. In a case where the thickness of the antistatic layer is 1 μm or less, haze can be reduced.

The lower limit of the thickness of the antistatic layer is not limited. As the thickness of the antistatic layer is smaller, haze can be reduced. From the viewpoint of manufacturing suitability, the thickness of the antistatic layer is preferably 0.01 μm or more.

The thickness of the antistatic layer is obtained as an average value of 5 random points measured by cross-sectional observation with a scanning electron microscope (SEM).

A method for forming the antistatic layer is not limited, and a known method can be adopted. Examples of the method for forming the antistatic layer include a method using a composition for an antistatic layer. For example, an antistatic layer having a patterned shape can be formed by applying a composition for an antistatic layer to the photosensitive composition layer, drying the composition for an antistatic layer as necessary, and then performing pattern exposure and development.

The composition for an antistatic layer is as described in the above-described “Method for Forming Antistatic Layer”.

As the coating method and drying method, the coating method and drying method described in the above section of “Method for Forming Antistatic Layer” can be adopted, respectively.

As the pattern exposure method and developing method, the pattern exposure method and developing method described in the above section of “Manufacturing Method of Antistatic Pattern” can be adopted, respectively.

In addition, examples of the method for forming the cured composition layer also include a method using the photosensitive transfer film according to the embodiment of the present disclosure, as described later.

(Other Layers)

The laminate according to the embodiment of the present disclosure may further have a layer (hereinafter, referred to as “other layers” in this paragraph) other than the above-described layers. Examples of the other layers include a refractive index adjusting layer. The refractive index adjusting layer is preferably disposed between the transparent electrode layer and the cured composition layer. The refractive index adjusting layer is as described in the above section of “Refractive Index Adjusting Layer”.

(Color of Laminate)

The laminate according to the embodiment of the present disclosure is preferably achromatic. Specifically, in CIE1976 (L*, a*, b*) color space of total reflection (incidence angle: 8°, light source: D-65 (visual field: 2°)), the L* value is preferably 10 to 90, the a* value is preferably −1.0 to 1.0, and the b* value is preferably −1.0 to 1.0.

(Manufacturing Method of Laminate)

A manufacturing method of the laminate according to the embodiment of the present disclosure is not limited, and a known method can be adopted. The laminate according to the embodiment of the present disclosure can be manufactured, for example, by using the above-described methods for forming each layer.

As the manufacturing method of the laminate according to the embodiment of the present disclosure, a method using the photosensitive transfer film according to the embodiment of the present disclosure is preferable. Examples of the method for manufacturing the laminate using the photosensitive transfer film include a method of performing the lamination step, the exposure step, and the development step described in the above section of “Manufacturing Method of Antistatic Pattern”. In the lamination step, for example, by laminating the transparent electrode layer formed on the base material and the photosensitive transfer film, a structure body having the base material, the transparent electrode layer, the photosensitive layer, and the antistatic layer in this order is formed. A laminate can be obtained by subjecting the obtained structure body to pattern exposure and then development.

<Touch Panel>

The touch panel according to the embodiment of the present disclosure includes the laminate according to the embodiment of the present disclosure. Since the touch panel according to the embodiment of the present disclosure includes the laminate according to the embodiment of the present disclosure, charging of the patterned electrode protective film is prevented.

The laminate in the touch panel according to the embodiment of the present disclosure is synonymous with the laminate described in the above section of “Laminate”, and the preferred embodiment is also the same.

In the touch panel according to the embodiment of the present disclosure, the transparent electrode layer may form a lead wire (so-called lead-out wire) disposed on the frame portion of the touch panel, or may form an electrode disposed in a visible portion of the touch panel. The transparent electrode layer in the laminate preferably forms an electrode disposed in the visible portion of the touch panel.

The touch panel according to the embodiment of the present disclosure may have the lead wire on a surface opposite to the surface on which the base material of the transparent electrode layer is disposed. In addition, the touch panel according to the embodiment of the present disclosure may have the lead wire between the base material and the transparent electrode layer.

As a material of the lead wire, metal is preferable. Examples of the metal include gold, silver, copper, molybdenum, aluminum, titanium, chromium, zinc, manganese, and alloy formed of two or more kinds of these metal elements. Among the above, as the metal, copper, molybdenum, aluminum, or titanium is preferable, and from the viewpoint of low electric resistance, copper is more preferable. On the other hand, since copper is easily oxidized and discolored, it is preferable to perform treatment with a treatment liquid described later.

Examples of a detection method of the touch panel according to the embodiment of the present disclosure include a resistive film method, a electrostatic capacitance method, an ultrasonic method, an electromagnetic induction method, and an optical method. Among the above, the detection method is preferably a electrostatic capacitance method.

Examples of the touch panel type include a so-called in-cell type (for example, those shown in FIGS. 5, 6, 7, and 8 of JP2012-517051B), a so-called on-cell type (for example, one described in FIG. 19 of JP2013-168125A and those described in FIGS. 1 and 5 of JP2012-89102A), an one glass solution (OGS) type, a touch-on-lens (TOL) type (for example, one described in FIG. 2 of JP2013-54727A), other configurations (for example, those described in FIG. 6 of JP2013-164871A), and various out-cell types (so-called GG, G1·G2, GFF, GF2, GF1, G1F, and the like).

Here, a first specific example of the touch panel according to the embodiment of the present disclosure will be described with reference to FIG. 2. FIG. 2 is a schematic cross sectional view showing the first specific example of the touch panel according to the embodiment of the present disclosure.

As shown in FIG. 2, a touch panel 90 has an image display region 74 and an image non-display region 75 (that is, frame portion).

The touch panel 90 has transparent electrodes for a touch panel on both sides of a substrate 50. Specifically, the touch panel 90 has a first transparent electrode 70 for a touch panel on one surface of the substrate 50 and a second transparent electrode 72 for a touch panel on the other surface of the substrate 50.

In the image non-display region 75 of the touch panel 90, a lead wire 56 is connected to the first transparent electrode 70 for a touch panel and the second transparent electrode 72 for a touch panel, respectively. Examples of the lead wire 56 include a copper wire and a silver wire.

In the touch panel 90, a cured composition layer 22 is disposed on one surface of the substrate 50 to cover the first transparent electrode 70 for a touch panel and the lead wire 56, and a cured composition layer 22 is disposed on the other surface of the substrate 50 to cover the second transparent electrode 72 for a touch panel and the lead wire 56.

In the touch panel 90, an antistatic layer 30 is disposed on a surface of the cured composition layer 22 opposite to a surface on which the substrate 50 is disposed.

In the touch panel 90, a refractive index adjusting layer may be disposed on one surface of the substrate 50.

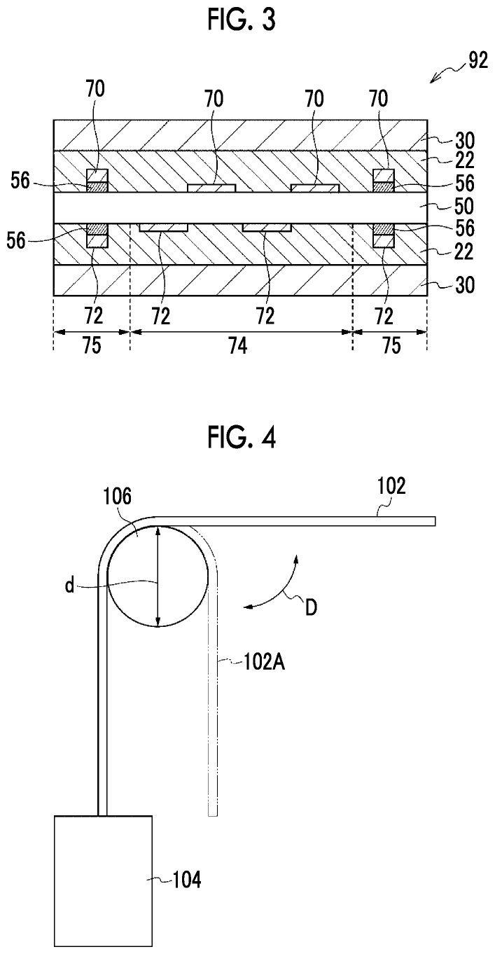

Next, a second specific example of the touch panel according to the embodiment of the present disclosure will be described with reference to FIG. 3. FIG. 3 is a schematic cross sectional view showing the second specific example of the touch panel according to the embodiment of the present disclosure.

As shown in FIG. 3, a touch panel 92 has an image display region 74 and an image non-display region 75 (that is, frame portion).

In the image display region 74 of the touch panel 92, a first transparent electrode 70 for a touch panel is disposed on one surface of a substrate 50, and a second transparent electrode 72 for a touch panel is disposed on the other surface of the substrate 50.

In the image non-display region 75 of the touch panel 92, lead wires 56 are arranged on both sides of the substrate 50, respectively. Examples of the lead wire 56 include a copper wire and a silver wire. The lead wires 56 are arranged to be surrounded by a cured composition layer 22, the first transparent electrode 70 for a touch panel, or the second transparent electrode 72 for a touch panel.

In the image non-display region 75 of the touch panel 92, the first transparent electrode 70 for a touch panel is connected to the lead wire 56 disposed on one surface of the substrate 50, and the second transparent electrode 72 for a touch panel is connected to the lead wire 56 disposed on the other surface of the substrate 50.

In the touch panel 92, a cured composition layer 22 is disposed on one surface of the substrate 50 to cover the first transparent electrode 70 for a touch panel, and a cured composition layer 22 is disposed on the other surface of the substrate 50 to cover the second transparent electrode 72 for a touch panel. The cured composition layer 22 functions as a protective film for the electrodes.

In the touch panel 92, an antistatic layer 30 is disposed on a surface of the cured composition layer 22 opposite to a surface on which the substrate 50 is disposed.

In the touch panel 92, a refractive index adjusting layer may be disposed on one surface of the substrate 50.

[Manufacturing Method of Touch Panel]

The manufacturing method of a touch panel according to the embodiment of the present disclosure is not limited, and a known method can be adopted. In the manufacturing method of the touch panel according to the embodiment of the present disclosure, for example, the manufacturing method of an antistatic pattern according to the embodiment of the present disclosure can be adopted. For example, the touch panel according to the embodiment of the present disclosure can be manufactured by laminating the photosensitive transfer film according to the embodiment of the present disclosure to a base material having a transparent electrode layer on at least one surface, and then performing pattern exposure and development.

Hereinafter, a preferred manufacturing method of a touch panel according to the embodiment of the present disclosure will be described.

A first embodiment of the manufacturing method of a touch panel according to the present disclosure includes, in the following order, a step of preparing a base material, a step of forming a transparent electrode for a touch panel on the base material using a silver conductive material, a step of forming a metal layer on the transparent electrode for a touch panel, a step of treating the metal layer with a treatment liquid containing at least one azole compound (hereinafter, may be referred to as a “specific azole compound”) selected from the group consisting of an imidazole compound, a triazole compound, a tetrazole compound, a thiazole compound, and a thiadiazole compound, a step of forming a lead wire from the metal layer, a step of laminating the photosensitive layer and the antistatic layer of the photosensitive transfer film according to the embodiment of the present disclosure on a surface of the base material on a side where the lead wire and the transparent electrode for a touch panel are arranged, a step of performing a pattern exposure of the photosensitive layer and the antistatic layer, and a step of developing the photosensitive layer and the antistatic layer to form a pattern. Since the first embodiment of the manufacturing method of the touch panel according to the embodiment of the present disclosure includes the above-described steps, it is possible to manufacture a touch panel capable of preventing charging of the patterned electrode protective film. In addition, according to the first embodiment of the manufacturing method of the touch panel according to the embodiment of the present disclosure, by treating the metal layer with the treatment liquid containing the specific azole compound, discoloration of the lead wire (particularly, a lead wire including copper) can be suppressed.

As the base material, the base material described in the above section of “Manufacturing Method of Antistatic Pattern” can be adopted.

The silver conductive material is not limited as long as it is a conductive material containing silver. The silver conductive material preferably contains silver nanowires.

Examples of the method for forming the transparent electrode for a touch panel using the silver conductive material include photolithography. For example, the transparent electrode for a touch panel can be formed by processing the silver conductive material disposed on the base material by photolithography.

The method for forming the metal layer is not limited, and a known method can be adopted. Examples of the method for forming the metal layer include a sputtering method and a coating method.

Examples of the metal included in the metal layer include gold, silver, copper, molybdenum, aluminum, titanium, chromium, zinc, manganese, and alloy formed of two or more kinds of these metal elements. Among the above, as the metal included in the metal layer, copper, molybdenum, aluminum, or titanium is preferable, and from the viewpoint of low electric resistance, copper is more preferable.

The specific azole compound is not particularly limited. From the viewpoint of further suppressing the discoloration of the metal layer (particularly, the metal layer including copper), the pKa of a conjugate acid of the specific azole compound is preferably 4.00 or less and more preferably 2.00 or less. The lower limit of the pKa of the conjugate acid of the specific azole compound is not particularly limited. In the present specification, the pKa of the conjugate acid is a calculated value obtained by ACD/ChemSketch (ACD/Labs 8.00, Release Product Version: 8.08).

The molecular weight of the specific azole compound is not particularly limited, but for example, is preferably 1,000 or less.

As a specific example of the specific azole compound, the heterocyclic compound described in the above section of “Photosensitive Layer” is preferably adopted. Among these, as the specific azole compound, from the viewpoint of further suppressing the discoloration of the metal layer (particularly, the metal layer including copper), at least one azole compound selected from the group consisting of a triazole compound and a tetrazole compound is preferable, at least one azole compound selected from the group consisting of 1,2,3-triazole, 1,2,4-triazole, 1,2,3-benzotriazole, and 5-amino-1H-tetrazole is more preferable, and at least one azole compound selected from the group consisting of 1,2,4-triazole and 5-amino-1H-tetrazole is still more preferable.

The treatment liquid may contain only one kind of the specific azole compound, or may contain two or more kinds thereof.

The content of the specific azole compound in the treatment liquid is preferably 0.005% by mass or more, more preferably 0.008% by mass or more, and still more preferably 0.01% by mass or more with respect to the total mass of the treatment liquid. The upper limit of the content of the specific azole compound in the treatment liquid is not particularly limited. Because of solubility of the specific azole compound, the content of the specific azole compound in the treatment liquid is preferably 5% by mass or less with respect to the total mass of the treatment liquid.

The treatment liquid preferably contains water. The water is not particularly limited, but preferably does not contain impurities. Examples of the water include distilled water, ion exchange water, and pure water. The content of the water in the treatment liquid is not particularly limited, but for example, is preferably 70% by mass to 99.9% by mass, more preferably 90.0% by mass to 99.9% by mass, still more preferably 95.0% by mass to 99.9% by mass, and particularly preferably 98.0% by mass to 99.9% by mass with respect to the total mass of the treatment liquid.

The treatment liquid may contain an organic solvent having miscibility with water. Examples of the organic solvent include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, acetone, methyl ethyl ketone, cyclohexanone, ε-caprolactone, γ-butyrolactone, dimethylformamide, dimethylacetamide, hexamethylphosphoramide, ethyl lactate, methyl lactate, ε-caprolactam, and N-methylpyrrolidone. In a case where the treatment liquid contains the organic solvent, the content of the organic solvent in the treatment liquid is preferably 0.1% by mass to 30% by mass with respect to the total mass of the treatment liquid.

The treatment liquid may contain a known surfactant. In a case where the treatment liquid contains the surfactant, the content of the surfactant in the treatment liquid is preferably 0.01% by mass to 10% by mass with respect to the total mass of the treatment liquid.

Examples of the treatment method using the treatment liquid include methods such as paddle treatment, shower treatment, spin treatment, and dip treatment.

The temperature of the treatment liquid is preferably 20° C. to 40° C.

Examples of the method for forming the lead wire from the metal layer include photolithography. For example, the lead wire can be formed by processing the metal layer by photolithography.

As the method and conditions of the step of laminating the photosensitive layer and the antistatic layer of the photosensitive transfer film on a surface of the base material on a side where the lead wire and the transparent electrode for a touch panel are arranged, the method and conditions described in the above section of “Lamination Step” can be adopted. By laminating the photosensitive layer and the antistatic layer of the photosensitive transfer film on a surface of the base material on a side where the lead wire and the transparent electrode for a touch panel are arranged, the photosensitive layer and the antistatic layer are laminated on the base material to cover the lead wire and the transparent electrode for a touch panel.

As the method and conditions of the step of performing a pattern exposure of the photosensitive layer and the antistatic layer, the method and conditions described in the above section of “Exposure Step” can be adopted.

As the method and conditions of the step of developing the photosensitive layer and the antistatic layer to form a pattern, the method and conditions described in the above section of “Development Step” can be adopted.

A second embodiment of the manufacturing method of a touch panel according to the present disclosure includes, in the following order, a step of preparing a base material, a step of forming a metal layer on the base material, a step of treating the metal layer with a treatment liquid containing at least one azole compound selected from the group consisting of an imidazole compound, a triazole compound, a tetrazole compound, a thiazole compound, and a thiadiazole compound, a step of forming a lead wire from the metal layer, a step of forming a transparent electrode for a touch panel on the lead wire using a silver conductive material, a step of laminating the photosensitive layer and the antistatic layer of the photosensitive transfer film according to the embodiment of the present disclosure on a surface of the base material on a side where the lead wire and the transparent electrode for a touch panel are arranged, a step of performing a pattern exposure of the photosensitive layer and the antistatic layer, and a step of developing the photosensitive layer and the antistatic layer to form a pattern. Since the second embodiment of the manufacturing method of the touch panel according to the embodiment of the present disclosure includes the above-described steps, it is possible to manufacture a touch panel capable of preventing charging of the patterned electrode protective film. In addition, according to the second embodiment of the manufacturing method of the touch panel according to the embodiment of the present disclosure, by treating the metal layer with the treatment liquid containing the specific azole compound, discoloration of the lead wire (particularly, a lead wire including copper) can be suppressed.

The second embodiment of the manufacturing method of the touch panel according to the embodiment of the present disclosure is the same as the first embodiment of the manufacturing method of the touch panel according to the embodiment of the present disclosure, except that the order of forming the transparent electrode for a touch panel and the order of forming the lead wire are changed. That is, in the second embodiment of the manufacturing method of the touch panel according to the embodiment of the present disclosure, the lead wire and the transparent electrode for a touch panel are formed on the base material in this order, whereas in the first embodiment of the manufacturing method of the touch panel according to the embodiment of the present disclosure, the transparent electrode for a touch panel and the lead wire are formed on the base material in this order. As the methods and conditions of each step of the second embodiment of the manufacturing method of the touch panel according to the embodiment of the present disclosure, the methods and conditions of the first embodiment of the manufacturing method of the touch panel according to the embodiment of the present disclosure can be adopted.

<Display Device with Touch Panel>

The display device with a touch panel according to the embodiment of the present disclosure includes the touch panel according to the embodiment of the present disclosure and a display device. Since the display device with a touch panel according to the embodiment of the present disclosure includes the touch panel according to the embodiment of the present disclosure and a display device, it is possible to prevent the patterned electrode protective film from being charged.

In addition, in the display device with a touch panel according to the embodiment of the present disclosure, an image is displayed through the touch panel, and it is possible to perform operation on the touch panel.

The laminate in the display device with a touch panel according to the embodiment of the present disclosure is synonymous with the laminate described in the above section of “Laminate”, and the preferred embodiment is also the same.

The touch panel in the display device with a touch panel according to the embodiment of the present disclosure is as described in the above section of “Touch Panel”.

The display device in the display device with a touch panel according to the embodiment of the present disclosure is not limited, and a known display device can be adopted. Examples of the display device include a liquid crystal display device and an organic electro luminescence (EL) display device.

The manufacturing method of the display device with a touch panel according to the embodiment of the present disclosure is not limited, and a known method can be adopted.

### EXAMPLES

Hereinafter, the present disclosure will be more specifically described with reference to Examples. The material, the amount used, the proportion, the process contents, the process procedure, and the like shown in the following examples can be appropriately changed, within a range not departing from a gist of the present disclosure. Accordingly, the range of the present disclosure is not limited to specific examples shown below. “parts” and “%” are on a mass basis unless otherwise specified. In the following examples, a weight-average molecular weight of a resin is a weight-average molecular weight obtained by performing polystyrene conversion of a value measured by gel permeation chromatography (GPC). In addition, a theoretical acid value is used for the acid value.

<Synthesis of Polymers P-1 to P-6>

The following polymers P-1 to P-6 were synthesized, respectively. The ratio of each constitutional unit in the following polymers P-1 to P-6 is a molar ratio.
Polymer P-1: polymer having the structure shown below (weight-average molecular weight: 30,000, alkali-soluble acrylic resin)

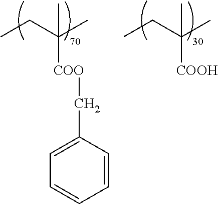

Polymer P-2: polymer having the structure shown below (weight-average molecular weight: 30,000, alkali-soluble acrylic resin)

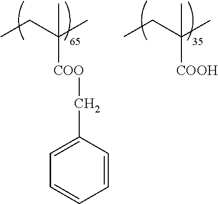

Polymer P-3: polymer having the structure shown below (weight-average molecular weight: 29,000, alkali-soluble acrylic resin)

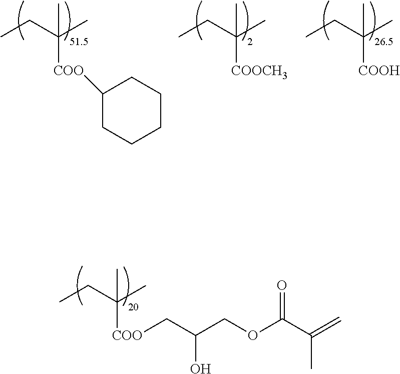

Polymer P-4: polymer having the structure shown below (weight-average molecular weight: 29,000, alkali-soluble acrylic resin)

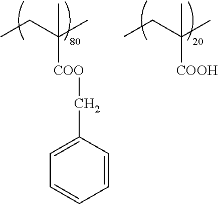

Polymer P-5: polymer having the structure shown below (weight-average molecular weight: 30,000, alkali-soluble acrylic resin)

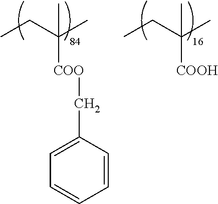

Polymer P-6: polymer having the structure shown below (weight-average molecular weight: 30,000)

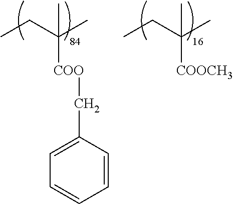

<Synthesis of Polymer P-7>

In a reactor (with a stirrer, a reflux condenser, and a nitrogen introduction pipe), 173.2 g (0.593 mol) of 1,3-bis(3-aminophenoxy)benzene was dissolved in 700 g of N,N-dimethylacetamide and 350 g of diethylene glycol dimethyl ether under a nitrogen atmosphere, and while stirring the obtained solution, 126.8 g (0.582 mol, molar ratio: 0.981) of dry solid pyromellitic dianhydride was added thereto little by little. By keeping the temperature of the reaction solution at 25° C. to 30° C. during the addition of the pyromellitic dianhydride and continuing stirring under a nitrogen atmosphere for 20 hours after the addition, a polymer P-7 solution, which is a polyamic acid and has a solid content of 22.2% by mass, was obtained.

<Synthesis of Polymer P-8>

In a reactor (with a stirrer, a reflux condenser, a dropping funnel, and a nitrogen introduction pipe), under a nitrogen atmosphere, 15.3 g of pyromellitic dianhydride (manufactured by Daicel Corporation) and 75 g of N,N-dimethylacetamide (manufactured by Daicel Corporation) were stirred, and the internal temperature was raised to 50° C. After adjusting the temperature of the mixture of the above-described components to 50° C., 6.36 g of polypropylene glycol diamine (JEFFAMINE D400, manufactured by Sun Techno Chemicals, Inc.) was added dropwise thereto little by little from the dropping funnel over 2 hours. After the dropwise addition, stirring was continued at 50° C. for 1 hour. Thereafter, the temperature of the reaction solution was lowered to 30° C. or lower, 16.4 g of 1,3-bis(3-aminophenoxy)benzene (manufactured by Mitsui Chemicals, Inc.) was added thereto, and the mixture was stirred under a nitrogen atmosphere for 20 hours, thereby obtaining a polymer P-8 solution which is a polyamic acid and has a solid content of 33.7% by mass.

<Synthesis of Polymer P-9>

82.4 g of propylene glycol monomethyl ether was charged into a flask and heated to 90° C. under a nitrogen stream. To this liquid, a solution in which 38.4 g of styrene, 30.1 g of dicyclopentanyl methacrylate, and 34.0 g of methacrylic acid had been dissolved in 20 g of propylene glycol monomethyl ether and a solution in which 5.4 g of a polymerization initiator V-601 (manufactured by FUJIFILM Wako Pure Chemical Corporation) had been dissolved in 43.6 g of propylene glycol monomethyl ether acetate was simultaneously added dropwise over 3 hours. After the dropwise addition, 0.75 g of V-601 was added three times every hour. Thereafter, the reaction was continued for another 3 hours. Thereafter, the reaction solution was diluted with 58.4 g of propylene glycol monomethyl ether acetate and 11.7 g of propylene glycol monomethyl ether. The reaction solution was heated to 100° C. under an air stream, and 0.80 g of tetraethylammonium acetate and 0.26 g of p-methoxyphenol were added thereto. 25.5 g of glycidyl methacrylate (Blemmer GH manufactured by NOF Corporation.) was added dropwise thereto over 20 minutes. The reaction was continued at 100° C. for 7 hours to obtain a solution of an alkali-soluble acrylic polymer P-9. The concentration of solid contents of the obtained solution was 36.2%. The obtained solution of polymer P-9 was dried, the solvent was evaporated, and the resultant was redissolved with propylene glycol monomethyl ether acetate to obtain a polymer P-9 solution having a concentration of solid contents of 27.0% by mass. The weight-average molecular weight in terms of standard polystyrene in GPC was 17,000, the dispersity was 2.4, and the acid value of the polymer was 94 mgKOH/g. The amount of residual monomer measured by gas chromatography was less than 0.1% by mass with respect to the solid content of the polymer in any of the monomers.

<Preparation of Composition for Photosensitive Layer>

Compositions A-1 to A-31 for a photosensitive layer having compositions shown in Tables 1 to 3 below were prepared, respectively. The unit of the numerical value shown in the column of each component in Tables 1 to 3 is part by mass.

TABLE 1

| Composition for forming antistatic layer | | A-1 | A-2 | A-3 | A-4 | A-5 |
|---|---|---|---|---|---|---|
| Radically | 1,10-Decanediol diaciylate | 3.16 | 3.16 | 3.16 | 3.16 | 3.16 |
| polymerizable | (A-DOD-N, manufactured by Shin-Nakamura | | | | | |
| compound | Chemical Co., Ltd.) | | | | | |
| | 75% by mass PGMEA solufion of dipentaerythritol | 4.16 | 4.16 | 4.16 | 4.16 | 4.16 |
| | hexaacrylate | | | | | |
| | (KAYARAD DPHA, manufactured by | | | | | |
| | Shin-Nakamura Chemical Co., Ltd.) | | | | | |
| | Ethoxylated bisphenol A dimethacrylate | — | — | — | — | — |
| | (BPE-500, manufactured by Shin-Nakamura | | | | | |
| | Chemical Co., Ltd.) | | | | | |
| | 75% by mass PGMEA solufion of pentaelythritol | — | — | — | — | — |
| | tri- and tetra-acrylate | | | | | |
| | (M-305, manufactured by Toagosei Co., Ltd.) | | | | | |
| | 1,9-Nonanediol diacrylate | — | — | — | — | — |
| | (A-NOD-N, manufactured by Shin-Nakamura | | | | | |
| | Chemical Co., Ltd.) | | | | | |
| | Trimethylolpropane triaciylate | — | — | — | — | — |
| | (A-TMPT, manufactured by Shin-Nakamura | | | | | |
| | Chemical Co., Ltd.) | | | | | |
| | Ditrimethylolpropane tetraacrylate | — | — | — | — | — |
| | (AD-TMP, manufactured by Shin-Nakamura | | | | | |
| | Chemical Co., Ltd.) | | | | | |
| Polymer | 27% by mass PGMEA solution of P-1 | 29.29 | — | — | — | — |
| | (acid value: 113) | | | | | |
| | 27% by mass PGMEA solution of P-2 | — | 29.29 | — | — | — |
| | (acid value: 136) | | | | | |
| | 27% by mass PGMEA solution of P-3 | — | — | 29.29 | — | — |
| | (acid value: 95) | | | | | |
| | 27% by mass PGMEA solution of P-4 | — | — | — | 29.29 | — |
| | (acid value: 71) | | | | | |
| | 27% by mass PGMEA solution of P-5 | — | — | — | — | 29.29 |
| | (acid value: 55) | | | | | |
| | 27% by mass PGMEA solution of P-6 | — | — | — | — | — |
| | (acid value: 0) | | | | | |
| | P-7 | — | — | — | — | — |
| | P-8 | — | — | — | — | — |
| | 27% by mass PGMEA solution of P-9 | — | — | — | — | — |
| | (acid value: 94) | | | | | |
| Photopolymerization | 1-[9-Ethyl-6-(2-methylbenzoyl)-9H-carbazol-3- | 0.07 | 0.07 | 0.07 | 0.07 | 0.07 |
| initiator | yl]ethanone-1-(O-acetyloxime) | | | | | |
| | (Irgacure OXE-02, manufactured by BASF SE) | | | | | |
| | 2-Methyl-1-(4-methylthiophenyl)-2-morpholinopro- | 0.15 | 0.15 | 0.15 | 0.15 | 0.15 |
| | pan-1-one | | | | | |
| | (Irgacure 907, manufactured by BASF SE) | | | | | |
| | 2,4-Diethyl thioxanthone | — | — | — | — | — |
| | (KAYACURE DETX-S, manufactured by Nippon | | | | | |
| | Kayaku Co., Ltd.) | | | | | |
| | [8-[5-(2,4,6-Trimethylphenyl)-11-(2-ethylhexyl)- | — | — | — | — | — |
| | 11H-benzo[a]carbazoyl][2-(2,2,3,3-tetrafluoropro- | | | | | |
| | poxy)phenyl]methanone-(O-acetyloxime) | | | | | |
| | (IRGACURE OXE-03, manufactured by BASF SE) | | | | | |
| | 2-(Dimethylamino)-2-[(4-methylphenyl)methyl]-1- | — | — | — | — | — |
| | [4-(4-morpholinyl)phenyl]-1-butanone | | | | | |
| | (Irgacure 379EG, manufactured by BASF SE) | | | | | |
| | 2-Hydroxy-4′-(2-hydroxyethoxy)-2-methylpro- | — | — | — | — | — |
| | piophenone | | | | | |
| | (Irgacure 2959, manufactured by BASF SE) | | | | | |
| Hydrogen donating | N-Phenylglycine | — | — | — | — | — |
| compound | (manufactured by Tokyo Chemical | | | | | |
| | Industry Co., Ltd.) | | | | | |
| Compound A | 4-Methylthiobenzaldehyde | — | — | — | — | — |
| | (manufactured by Tokyo Chemical | | | | | |
| | Industry Co., Ltd.) | | | | | |
| | 4-Methylthioacetophenone | — | — | — | — | — |
| | (manufactured by Tokyo Chemical | | | | | |
| | Industry Co., Ltd.) | | | | | |
| | 4-Methythiobenzoic acid | — | — | — | — | — |
| | (manufactured by Tokyo Chemical | | | | | |
| | Industry Co., Ltd.) | | | | | |
| Metal additive | Iron (III) acetylacetonate | — | — | — | — | — |
| | (manufactured by Tokyo Chemical | | | | | |
| | Industry Co., Ltd.) | | | | | |
| | Ferrocene | — | — | — | — | — |
| | (manufactured by Tokyo Chemical | | | | | |
| | Industry Co., Ltd.) | | | | | |
| Surfactant | MEGAFACE F551A (manufactured by DIC | 0.16 | 0.16 | 0.16 | 0.16 | 0.16 |
| | Corporation) | | | | | |
| | (30% by mass PGMEA solution) | | | | | |
| Solvent | Propylene glycol monomethyl ether acetate | 37.36 | 37.36 | 37.36 | 37.36 | 37.36 |
| | (PGMEA) | | | | | |
| | Methyl ethyl ketone | 25.65 | 25.65 | 25.65 | 25.65 | 25.65 |
| | (MEK) | | | | | |
| Composition for forming antistatic layer | | A-6 | A-7 | A-8 | A-9 | A-10 |
| Radically | 1,10-Decanediol diaciylate | 3.16 | — | — | — | — |
| polymerizable | (A-DOD-N, manufactured by Shin-Nakamura | | | | | |
| compound | Chemical Co., Ltd.) | | | | | |
| | 75% by mass PGMEA solution of dipentaerythritol | 4.16 | — | 8.43 | — | — |
| | hexaacrylate | | | | | |
| | (KAYARAD DPHA, manufactured by | | | | | |
| | Shin-Nakamura Chemical Co., Ltd.) | | | | | |
| | Ethoxylated bisphenol A dimethacrylate | — | 10.38 | — | — | — |
| | (BPE-500, manufactured by Shin-Nakamura | | | | | |
| | Chemical Co., Ltd.) | | | | | |
| | 75% by mass PGMEA solution of pentaelythritol | — | 10.38 | — | — | — |
| | tri- and tetra-acrylate | | | | | |
| | (M-305, manufactured by Toagosei Co., Ltd.) | | | | | |
| | 1,9-Nonanediol diacrylate | — | — | — | 6.33 | — |
| | (A-NOD-N, manufactured by Shin-Nakamura | | | | | |
| | Chemical Co., Ltd.) | | | | | |
| | Trimethylolpropane triacrylate | — | — | — | — | 6.33 |
| | (A-TMPT, manufactured by Shin-Nakamura | | | | | |
| | Chemical Co., Ltd.) | | | | | |
| | Ditrimethylolpropane tetraacrylate | — | — | — | — | — |
| | (AD-TMP, manufactured by Shin-Nakamura | | | | | |
| | Chemical Co., Ltd.) | | | | | |
| Polymer | 27% by mass PGMEA solution of P-1 | — | — | 29.28 | 29.28 | 29.28 |
| | (acid value:113) | | | | | |
| | 27% by mass PGMEA solution of P-2 | — | — | — | — | — |
| | (acid value: 136) | | | | | |
| | 27% by mass PGMEA solution of P-3 | — | — | — | — | — |
| | (acid value: 95) | | | | | |
| | 27% by mass PGMEA solution of P-4 | — | — | — | — | — |
| | (acid value: 71) | | | | | |
| | 27% by mass PGMEA solution of P-5 | — | — | — | — | — |
| | (acid value: 55) | | | | | |
| | 27% by mass PGMEA solution of P-6 | 29.29 | — | — | — | — |
| | (acid value: 0) | | | | | |
| | P-7 | — | 46.76 | — | — | — |
| | P-8 | — | 30.81 | — | — | — |
| | 27% by mass PGMEA solution of P-9 | — | — | — | — | — |
| | (acid value: 94) | | | | | |
| Photopolymerization | 1-[9-Ethyl-6-(2 -methylbenzoyl)-9H-carbazol-3- | 0.07 | — | 0.07 | 0.07 | 0.07 |
| initiator | yl]ethanone-1-(O-acetyloxime) | | | | | |
| | (Irgacure OXE-02, manufactured by BASF SE) | | | | | |
| | 2-Methyl-1-(4-methylthiophenyl)-2-morpholinopro- | 0.15 | 1.04 | 0.15 | 0.15 | 0.15 |
| | pan-1-one | | | | | |
| | (Irgacure 907, manufactured by BASF SE) | | | | | |
| | 2,4-Diethyl thioxanthone | — | 0.62 | — | — | — |
| | (KAYACURE DETX-S manufactured by Nippon | | | | | |
| | Kayaku Co., Ltd.) | | | | | |
| | [8-[5-(2,4,6-Trimethylphenyl)-11-(2-ethylhexyl)- | — | — | — | — | — |
| | 11H--benzo[a]carbazoyl][2-(2,2,3,3-tetrafluoropro- | | | | | |
| | poxy)phenyl]methanone-(O-acetyloxime) | | | | | |
| | (IRGACURE OXE-03, manufactured by BASF SE) | | | | | |
| | 2-(Dimethylamino)-2-[(4-methylphenyl)methyl]-1- | — | — | — | — | — |
| | [4-(4-morpholinyl)phenyl]-1-butanone | | | | | |
| | (Irgacure 379EG, manufactured by BASF SE) | | | | | |
| | 2-Hydroxy-4′-(2-hydroxyethoxy)-2-methylpro- | — | — | — | — | — |
| | piophenone | | | | | |
| | (Irgacure 2959, manufactured by BASF SE) | | | | | |
| Hydrogen donting | N-Phenylglycine | — | — | — | — | — |
| compound | (manufactured by Tokyo Chemical | | | | | |
| | Industry Co., Ltd.) | | | | | |
| Compound A | 4-Methylthiobenzaldehyde | — | — | — | — | — |
| | (manufactured by Tokyo Chemical | | | | | |
| | Industry Co., Ltd.) | | | | | |
| | 4-Methylthioacetophenone | — | — | — | — | — |
| | (manufactured by Tokyo Chemical | | | | | |
| | Industry Co., Ltd.) | | | | | |
| | 4-Methylthiobenzoic acid | — | — | — | — | — |
| | (manufactured by Tokyo Chemical | | | | | |
| | Industry Co., Ltd.) | | | | | |
| Metal additive | Iron (III) acetylacetonate | — | — | — | — | — |
| | (manufactured by Tokyo Chemical | | | | | |
| | Industry Co., Ltd.) | | | | | |
| | Ferrocene | — | — | — | — | — |
| | (manufactured by Tokyo Chemical | | | | | |
| | Industry Co., Ltd.) | | | | | |
| Surfactant | MEGAFACE F551A (manufactured by DIC | 0.16 | — | 0.16 | 0.16 | 0.16 |
| | (30% by mass PGMEA solution) | | | | | |
| Solvent | Propylene glycol monomethyl ether acetate | 37.36 | — | 38.36 | 38.36 | 38.36 |
| | (PGMEA) | | | | | |
| | Methyl ethyl ketone | 26.65 | — | 25.65 | 25.65 | 25.65 |
| | (MEK) | | | | | |

TABLE 2

| Composition for forming antistatic layer | | A-11 | A-12 | A-13 | A-14 | A-15 |
|---|---|---|---|---|---|---|
| Radically | 1,10-Decanediol diaciylate | — | — | — | — | — |
| polymerizable | (A-DOD-N, manufactured by Shin-Nakamura | | | | | |
| compound | Chemical Co., Ltd.) | | | | | |
| | 75% by mass PGMEA solufion of dipentaerythritol | — | 1.69 | 1.69 | 4.16 | 4.16 |
| | hexaacrylate | | | | | |
| | (KAYARAD DPHA, manufactured by | | | | | |
| | Shin-Nakamura Chemical Co., Ltd.) | | | | | |
| | Ethoxylated bisphenol A dimethacrylate | — | — | — | — | — |
| | (BPE-500, manufactured by Shin-Nakamura | | | | | |
| | Chemical Co., Ltd.) | | | | | |
| | 75% by mass PGMEA solufion of pentaelythritol | — | — | — | — | — |
| | tri- and tetra-acrylate | | | | | |
| | (M-305, manufactured by Toagosei Co., Ltd.) | | | | | |
| | 1,9-Nonanediol diacrylate | — | 2.53 | 2.53 | 3.16 | 3.16 |
| | (A-NOD-N, manufactured by Shin-Nakamura | | | | | |
| | Chemical Co., Ltd.) | | | | | |
| | Trimethylolpropane triaciylate | — | 2.53 | — | — | — |
| | (A-TMPT, manufactured by Shin-Nakamura | | | | | |
| | Chemical Co., Ltd.) | | | | | |
| | Ditrimethylolpropane tetraacrylate | 6.33 | — | 2.53 | — | — |
| | (AD-TMP, manufactured by Shin-Nakamura | | | | | |
| | Chemical Co., Ltd.) | | | | | |
| Polymer | 27% by mass PGMEA solution of P-1 | 29.28 | 29.28 | 29.28 | 29.29 | 29.29 |
| | (acid value: 113) | | | | | |
| | 27% by mass PGMEA solution of P-2 | — | — | — | — | — |
| | (acid value: 136) | | | | | |
| | 27% by mass PGMEA solution of P-3 | — | — | — | — | — |
| | (acid value: 95) | | | | | |
| | 27% by mass PGMEA solution of P-4 | — | — | — | — | — |
| | (acid value: 71) | | | | | |
| | 27% by mass PGMEA solution of P-5 | — | — | — | — | — |
| | (acid value: 55) | | | | | |
| | 27% by mass PGMEA solution of P-6 | — | — | — | — | — |
| | (acid value: 0) | | | | | |
| | P-7 | — | — | — | — | — |
| | P-8 | — | — | — | — | — |
| | 27% by mass PGMEA solution of P-9 | — | — | — | — | — |
| | (acid value: 94) | | | | | |
| Photopolymerization | 1-[9-Ethyl-6-(2-methylbenzoyl)-9H-carbazol-3- | 0.07 | 0.07 | 0.07 | 0.07 | — |
| initiator | yl]ethanone-1-(O-acetyloxime) | | | | | |
| | (Irgacure OXE-02, manufactured by BASF SE) | | | | | |
| | 2-Methyl-1-(4-methylthiophenyl)-2-morpholinopro- | 0.15 | 0.15 | 0.15 | 0.15 | — |
| | pan-1-one | | | | | |
| | (Irgacure 907, manufactured by BASF SE) | | | | | |
| | 2,4-Diethyl thioxanthone | — | — | — | — | — |
| | (KAYACURE DETX-S, manufactured by Nippon | | | | | |
| | Kayaku Co., Ltd.) | | | | | |
| | [8-[5-(2,4,6-Trimethylphenyl)-11-(2-ethylhexyl)- | — | — | — | — | 0.22 |
| | 11H-benzo[a]carbazoyl][2-(2,2,3,3-tetrafluoropro- | | | | | |
| | poxy)phenyl]methanone-(O-acetyloxime) | | | | | |
| | (IRGACURE OXE-03, manufactured by BASF SE) | | | | | |
| | 2-(Dimethylamino)-2-[(4-methylphenyl)methyl]-1- | — | — | — | — | — |
| | [4-(4-morpholinyl)phenyl]-1-butanone | | | | | |
| | (Irgacure 379EG, manufactured by BASF SE) | | | | | |
| | 2-Hydroxy-4′-(2-hydroxyethoxy)-2-methylpro- | — | — | — | — | — |
| | piophenone | | | | | |
| | (Irgacure 2959, manufactured by BASF SE) | | | | | |
| Hydrogen donating | N-Phenylglycine | — | — | — | — | — |
| compound | (manufactured by Tokyo Chemical | | | | | |
| | Industry Co., Ltd.) | | | | | |
| Compound A | 4-Methylthiobenzaldehyde | — | — | — | — | — |
| | (manufactured by Tokyo Chemical | | | | | |
| | Industry Co., Ltd.) | | | | | |
| | 4-Methylthioacetophenone | — | — | — | — | — |
| | (manufactured by Tokyo Chemical | | | | | |
| | Industry Co., Ltd.) | | | | | |
| | 4-Methythiobenzoic acid | — | — | — | — | — |
| | (manufactured by Tokyo Chemical | | | | | |
| | Industry Co., Ltd.) | | | | | |
| Metal additive | Iron (III) acetylacetonate | — | — | — | — | — |
| | (manufactured by Tokyo Chemical | | | | | |
| | Industry Co., Ltd.) | | | | | |
| | Ferrocene | — | — | — | — | — |
| | (manufactured by Tokyo Chemical | | | | | |
| | Industry Co., Ltd.) | | | | | |
| Surfactant | MEGAFACE F551A (manufactured by DIC | 0.16 | 0.16 | 0.16 | 0.16 | 0.16 |
| | Corporation) | | | | | |
| | (30% by mass PGMEA solution) | | | | | |
| Solvent | Propylene glycol monomethyl ether acetate | 37.94 | 37.94 | 37.94 | 37.36 | 37.36 |
| | (PGMEA) | | | | | |
| | Methyl ethyl ketone | 25.65 | 25.65 | 25.65 | 25.65 | 25.65 |
| | (MEK) | | | | | |
| Composition for forming antistatic layer | | A-16 | A-17 | A-18 | A-19 | A-20 |
| Radically | 1,10-Decanediol diaciylate | — | — | — | — | — |
| polymerizable | (A-DOD-N, manufactured by Shin-Nakamura | | | | | |
| compound | Chemical Co., Ltd.) | | | | | |
| | 75% by mass PGMEA solution of dipentaerythritol | 4.16 | 4.16 | 4.73 | 2.21 | 8.43 |
| | hexaacrylate | | | | | |
| | (KAYARAD DPHA, manufactured by | | | | | |
| | Shin-Nakamura Chemical Co., Ltd.) | | | | | |
| | Ethoxylated bisphenol A dimethacrylate | — | — | — | — | — |
| | (BPE-500, manufactured by Shin-Nakamura | | | | | |
| | Chemical Co., Ltd.) | | | | | |
| | 75% by mass PGMEA solution of pentaelythritol | — | — | — | — | — |
| | tri- and tetra-acrylate | | | | | |
| | (M-305, manufactured by Toagosei Co., Ltd.) | | | | | |
| | 1,9-Nonanediol diacrylate | 3.16 | 3.16 | 3.55 | 1.65 | 6.33 |
| | (A-NOD-N, manufactured by Shin-Nakamura | | | | | |
| | Chemical Co., Ltd.) | | | | | |
| | Trimethylolpropane triacrylate | — | — | — | — | — |
| | (A-TMPT, manufactured by Shin-Nakamura | | | | | |
| | Chemical Co., Ltd.) | | | | | |
| | Ditrimethylolpropane tetraacrylate | — | — | — | — | — |
| | (AD-TMP, manufactured by Shin-Nakamura | | | | | |
| | Chemical Co., Ltd.) | | | | | |
| Polymer | 27% by mass PGMEA solution of P-1 | 29.28 | 29.28 | 26.30 | 40.85 | 58.57 |
| | (acid value:113) | | | | | |
| | 27% by mass PGMEA solution of P-2 | — | — | — | — | — |
| | (acid value: 136) | | | | | |
| | 27% by mass PGMEA solution of P-3 | — | — | — | — | — |
| | (acid value: 95) | | | | | |
| | 27% by mass PGMEA solution of P-4 | — | — | — | — | — |
| | (acid value: 71) | | | | | |
| | 27% by mass PGMEA solution of P-5 | — | — | — | — | — |
| | (acid value: 55) | | | | | |
| | 27% by mass PGMEA solution of P-6 | — | — | — | — | — |
| | (acid value: 0) | | | | | |
| | P-7 | — | — | — | — | — |
| | P-8 | — | — | — | — | — |
| | 27% by mass PGMEA solution of P-9 | — | — | — | — | — |
| | (acid value: 94) | | | | | |
| Photopolymerization | 1-[9-Ethyl-6-(2 -methylbenzoyl)-9H-carbazol-3- | — | — | — | — | — |
| initiator | yl]ethanone-1-(O-acetyloxime) | | | | | |
| | (Irgacure OXE-02, manufactured by BASF SE) | | | | | |
| | 2-Methyl-1-(4-methylthiophenyl)-2-morpholinopro- | — | — | — | — | — |
| | pan-1-one | | | | | |
| | (Irgacure 907, manufactured by BASF SE) | | | | | |
| | 2,4-Diethyl thioxanthone | — | — | — | — | — |
| | (KAYACURE DETX-S manufactured by Nippon | | | | | |
| | Kayaku Co., Ltd.) | | | | | |
| | [8-[5-(2,4,6-Trimethylphenyl)-11-(2-ethylhexyl)- | — | — | — | — | — |
| | 11H--benzo[a]carbazoyl][2-(2,2,3,3-tetrafluoropro- | | | | | |
| | poxy)phenyl]methanone-(O-acetyloxime) | | | | | |
| | (IRGACURE OXE-03, manufactured by BASF SE) | | | | | |
| | 2-(Dimethylamino)-2-[(4-methylphenyl)methyl]-1- | 0.22 | — | — | — | — |
| | [4-(4-morpholinyl)phenyl]-1-butanone | | | | | |
| | (Irgacure 379EG, manufactured by BASF SE) | | | | | |
| | 2-Hydroxy-4′-(2-hydroxyethoxy)-2-methylpro- | — | 0.22 | 0.25 | 0.12 | 0.44 |
| | piophenone | | | | | |
| | (Irgacure 2959, manufactured by BASF SE) | | | | | |
| Hydrogen donting | N-Phenylglycine | — | — | — | — | — |
| compound | (manufactured by Tokyo Chemical | | | | | |
| | Industry Co., Ltd.) | | | | | |
| Compound A | 4-Methylthiobenzaldehyde | — | — | — | — | — |
| | (manufactured by Tokyo Chemical | | | | | |
| | Industry Co., Ltd.) | | | | | |
| | 4-Methylthioacetophenone | — | — | — | — | — |
| | (manufactured by Tokyo Chemical | | | | | |
| | Industry Co., Ltd.) | | | | | |
| | 4-Methylthiobenzoic acid | — | — | — | — | — |
| | (manufactured by Tokyo Chemical | | | | | |
| | Industry Co., Ltd.) | | | | | |
| Metal additive | Iron (III) acetylacetonate | — | — | — | — | — |
| | (manufactured by Tokyo Chemical | | | | | |
| | Industry Co., Ltd.) | | | | | |
| | Ferrocene | — | — | — | — | — |
| | (manufactured by Tokyo Chemical | | | | | |
| | Industry Co., Ltd.) | | | | | |
| Surfactant | MEGAFACE F551A (manufactured by DIC | 0.16 | 0.16 | 0.16 | 0.16 | 0.31 |
| | (30% by mass PGMEA solution) | | | | | |
| Solvent | Propylene glycol monomethyl ether acetate | 37.36 | 37.36 | 39.35 | 29.37 | 4.62 |
| | (PGMEA) | | | | | |
| | Methyl ethyl ketone | 25.65 | 25.65 | 25.65 | 25.65 | 21.30 |
| | (MEK) | | | | | |

TABLE 3

| Composition for forming antistatic layer | | A-21 | A-22 | A-23 | A-24 | A-25 | A-26 |
|---|---|---|---|---|---|---|---|
| Radically | 1,10-Decanediol diaciylate | — | — | — | — | — | — |
| polymerizable | (A-DOD-N, manufactured by Shin-Nakamura | | | | | | |
| compound | Chemical Co., Ltd.) | | | | | | |
| | 75% by mass PGMEA solufion of dipentaerythritol | 4.21 | 4.17 | 4.09 | 4.01 | 4.17 | 4.17 |
| | hexaacrylate | | | | | | |
| | (KAYARAD DPHA, manufactured by | | | | | | |
| | Shin-Nakamura Chemical Co., Ltd.) | | | | | | |
| | Ethoxylated bisphenol A dimethacrylate | — | — | — | — | — | — |
| | (BPE-500, manufactured by Shin-Nakamura | | | | | | |
| | Chemical Co., Ltd.) | | | | | | |
| | 75% by mass PGMEA solufion of pentaelythritol | — | — | — | — | — | — |
| | tri- and tetra-acrylate | | | | | | |
| | (M-305, manufactured by Toagosei Co., Ltd.) | | | | | | |
| | 1,9-Nonanediol diacrylate | 3.16 | 3.13 | 3.07 | 3.00 | 3.13 | 3.13 |
| | (A-NOD-N, manufactured by Shin-Nakamura | | | | | | |
| | Chemical Co., Ltd.) | | | | | | |
| | Trimethylolpropane triaciylate | — | — | — | — | — | — |
| | (A-TMPT, manufactured by Shin-Nakamura | | | | | | |
| | Chemical Co., Ltd.) | | | | | | |
| | Ditrimethylolpropane tetraacrylate | — | — | — | — | — | — |
| | (AD-TMP, manufactured by Shin-Nakamura | | | | | | |
| | Chemical Co., Ltd.) | | | | | | |
| Polymer | 27% by mass PGMEA solution of P-1 | 29.25 | 28.99 | 28.40 | 27.81 | 28.99 | 28.99 |
| | (acid value: 113) | | | | | | |
| | 27% by mass PGMEA solution of P-2 | — | — | — | — | — | — |
| | (acid value: 136) | | | | | | |
| | 27% by mass PGMEA solution of P-3 | — | — | — | — | — | — |
| | (acid value: 95) | | | | | | |
| | 27% by mass PGMEA solution of P-4 | — | — | — | — | — | — |
| | (acid value: 71) | | | | | | |
| | 27% by mass PGMEA solution of P-5 | — | — | — | — | — | — |
| | (acid value: 55) | | | | | | |
| | 27% by mass PGMEA solution of P-6 | — | — | — | — | — | — |
| | (acid value: 0) | | | | | | |
| | P-7 | — | — | — | — | — | — |
| | P-8 | — | — | — | — | — | — |
| | 27% by mass PGMEA solution of P-9 | — | — | — | — | — | — |
| | (acid value: 94) | | | | | | |
| Photopoly- | 1-[9-Ethyl-6-(2-methylbenzoyl)-9H-carbazol-3- | — | — | — | — | — | — |
| merization | yl]ethanone-1-(O-acetyloxime) | | | | | | |
| initiator | (Irgacure OXE-02, manufactured by BASF SE) | | | | | | |
| | 2-Methyl-1-(4-methylthiophenyl)-2-morpholinopro- | — | — | — | — | — | — |
| | pan-1-one | | | | | | |
| | (Irgacure 907, manufactured by BASF SE) | | | | | | |
| | 2,4-Diethyl thioxanthone | — | — | — | — | — | — |
| | (KAYACURE DETX-S, manufactured by Nippon | | | | | | |
| | Kayaku Co., Ltd.) | | | | | | |
| | [8-[5-(2,4,6-Trimethylphenyl)-11-(2-ethylhexyl)- | — | — | — | — | — | — |
| | 11H-benzo[a]carbazoyl][2-(2,2,3,3-tetrafluoropro- | | | | | | |
| | poxy)phenyl]methanone-(O-acetyloxime) | | | | | | |
| | (IRGACURE OXE-03, manufactured by BASF SE) | | | | | | |
| | 2-(Dimethylamino)-2-[(4-methylphenyl)methyl]-1- | — | — | — | — | — | — |
| | [4-(4-morpholinyl)phenyl]-1-butanone | | | | | | |
| | (Irgacure 379EG, manufactured by BASF SE) | | | | | | |
| | 2-Hydroxy-4′-(2-hydroxyethoxy)-2-methylpro- | 0.22 | 0.22 | 0.21 | 0.21 | 0.22 | 0.22 |
| | piophenone | | | | | | |
| | (Irgacure 2959, manufactured by BASF SE) | | | | | | |
| Hydrogen | N-Phenylglycine | — | — | — | — | — | — |
| donating | (manufactured by Tokyo Chemical | | | | | | |
| compound | Industry Co., Ltd.) | | | | | | |
| Compound A | 4-Methylthiobenzaldehyde | 0.015 | 0.15 | 0.44 | 0.73 | — | — |
| | (manufactured by Tokyo Chemical | | | | | | |
| | Industry Co., Ltd.) | | | | | | |
| | 4-Methylthioacetophenone | — | — | — | — | 0.15 | — |
| | (manufactured by Tokyo Chemical | | | | | | |
| | Industry Co., Ltd.) | | | | | | |
| | 4-Methythiobenzoic acid | — | — | — | — | — | 0.15 |
| | (manufactured by Tokyo Chemical | | | | | | |
| | Industry Co., Ltd.) | | | | | | |
| Metal additive | Iron (III) acetylacetonate | — | — | — | — | — | — |
| | (manufactured by Tokyo Chemical | | | | | | |
| | Industry Co., Ltd.) | | | | | | |
| | Ferrocene | — | — | — | — | — | — |
| | (manufactured by Tokyo Chemical | | | | | | |
| | Industry Co., Ltd.) | | | | | | |
| Surfactant | MEGAFACE F551A (manufactured by DIC | 0.16 | 0.16 | 0.16 | 0.16 | 0.16 | 0.16 |
| | Corporation) | | | | | | |
| | (30% by mass PGMEA solution) | | | | | | |
| Solvent | Propylene glycol monomethyl ether acetate | 37.33 | 37.53 | 37.98 | 38.44 | 37.53 | 37.53 |
| | (PGMEA) | | | | | | |
| | Methyl ethyl ketone | 25.65 | 25.65 | 25.65 | 25.65 | 25.65 | 25.65 |
| | (MEK) | | | | | | |

| Composition for forming antistatic layer | | A-27 | A-28 | A-29 | A-30 | A-31 |
|---|---|---|---|---|---|---|
| Radically | 1,10-Decanediol diaciylate | — | — | — | — | — |
| polymerizable | (A-DOD-N, manufactured by Shin-Nakamura | | | | | |
| compound | Chemical Co., Ltd.) | | | | | |
| | 75% by mass PGMEA solution of dipentaerythritol | 4.17 | 4.13 | 4.05 | 3.96 | 4.13 |
| | hexaacrylate | | | | | |
| | (KAYARAD DPHA, manufactured by | | | | | |
| | Shin-Nakamura Chemical Co., Ltd.) | | | | | |
| | Ethoxylated bisphenol A dimethacrylate | — | — | — | — | — |
| | (BPE-500, manufactured by Shin-Nakamura | | | | | |
| | Chemical Co., Ltd.) | | | | | |
| | 75% by mass PGMEA solution of pentaelythritol | — | — | — | — | — |
| | tri- and tetra-acrylate | | | | | |
| | (M-305, manufactured by Toagosei Co., Ltd.) | | | | | |
| | 1,9-Nonanediol diacrylate | 3.13 | 3.10 | 3.04 | 2.97 | 3.10 |
| | (A-NOD-N, manufactured by Shin-Nakamura | | | | | |
| | Chemical Co., Ltd.) | | | | | |
| | Trimethylolpropane triacrylate | — | — | — | — | — |
| | (A-TMPT, manufactured by Shin-Nakamura | | | | | |
| | Chemical Co., Ltd.) | | | | | |
| | Ditrimethylolpropane tetraacrylate | — | — | — | — | — |
| | (AD-TMP, manufactured by Shin-Nakamura | | | | | |
| | Chemical Co., Ltd.) | | | | | |
| Polymer | 27% by mass PGMEA solution of P-1 | 28.96 | 28.70 | 28.11 | 27.52 | — |
| | (acid value:113) | | | | | |
| | 27% by mass PGMEA solution of P-2 | — | — | — | — | — |
| | (acid value: 136) | | | | | |
| | 27% by mass PGMEA solution of P-3 | — | — | — | — | — |
| | (acid value: 95) | | | | | |
| | 27% by mass PGMEA solution of P-4 | — | — | — | — | — |
| | (acid value: 71) | | | | | |
| | 27% by mass PGMEA solution of P-5 | — | — | — | — | — |
| | (acid value: 55) | | | | | |
| | 27% by mass PGMEA solution of P-6 | — | — | — | — | — |
| | (acid value: 0) | | | | | |
| | P-7 | — | — | — | — | — |
| | P-8 | — | — | — | — | — |
| | 27% by mass PGMEA solution of P-9 | — | — | — | — | 28.70 |
| | (acid value: 94) | | | | | |
| Photopoly- | 1-[9-Ethyl-6-(2 -methylbenzoyl)-9H-carbazol-3- | — | — | — | — | — |
| merization | yl]ethanone-1-(O-acetyloxime) | | | | | |
| initiator | (Irgacure OXE-02, manufactured by BASF SE) | | | | | |
| | 2-Methyl-1-(4-methylthiophenyl)-2-morpholinopro- | — | — | — | — | — |
| | pan-1-one | | | | | |
| | (Irgacure 907, manufactured by BASF SE) | | | | | |
| | 2,4-Diethyl thioxanthone | — | — | — | — | — |
| | (KAYACURE DETX-S manufactured by Nippon | | | | | |
| | Kayaku Co., Ltd.) | | | | | |
| | [8-[5-(2,4,6-Trimethylphenyl)-11-(2-ethylhexyl)- | — | — | — | — | — |
| | 11H--benzo[a]carbazoyl][2-(2,2,3,3-tetrafluoropro- | | | | | |
| | poxy)phenyl]methanone-(O-acetyloxime) | | | | | |
| | (IRGACURE OXE-03, manufactured by BASF SE) | | | | | |
| | 2-(Dimethylamino)-2-[(4-methylphenyl)methyl]-1- | — | — | — | — | — |
| | [4-(4-morpholinyl)phenyl]-1-butanone | | | | | |
| | (Irgacure 379EG, manufactured by BASF SE) | | | | | |
| | 2-Hydroxy-4′-(2-hydroxyethoxy)-2-methylpro- | 0.22 | 0.22 | 0.21 | 0.21 | 0.22 |
| | piophenone | | | | | |
| | (Irgacure 2959, manufactured by BASF SE) | | | | | |
| Hydrogen | N-Phenylglycine | 0.015 | 0.15 | 0.44 | 0.73 | 0.15 |
| donting | (manufactured by Tokyo Chemical | | | | | |
| compound | Industry Co., Ltd.) | | | | | |
| Compound A | 4-Methylthiobenzaldehyde | 0.15 | 0.15 | 0.15 | 0.15 | 0.15 |
| | (manufactured by Tokyo Chemical | | | | | |
| | Industry Co., Ltd.) | | | | | |
| | 4-Methylthioacetophenone | — | — | — | — | — |
| | (manufactured by Tokyo Chemical | | | | | |
| | Industry Co., Ltd.) | | | | | |
| | 4-Methylthiobenzoic acid | — | — | — | — | — |
| | (manufactured by Tokyo Chemical | | | | | |
| | Industry Co., Ltd.) | | | | | |
| Metal additive | Iron (III) acetylacetonate | — | — | — | — | — |
| | (manufactured by Tokyo Chemical | | | | | |
| | Industry Co., Ltd.) | | | | | |
| | Ferrocene | — | — | — | — | — |
| | (manufactured by Tokyo Chemical | | | | | |
| | Industry Co., Ltd.) | | | | | |
| Surfactant | MEGAFACE F551A (manufactured by DIC | 0.16 | 0.16 | 0.16 | 0.16 | 0.16 |
| | (30% by mass PGMEA solution) | | | | | |
| Solvent | Propylene glycol monomethyl ether acetate | 37.56 | 37.76 | 38.21 | 38.66 | 37.76 |
| | (PGMEA) | | | | | |
| | Methyl ethyl ketone | 25.65 | 25.65 | 25.65 | 25.65 | 25.65 |
| | (MEK) | | | | | |

<Preparation of Composition for Antistatic Layer>

Compositions B-1 to B-7 for an antistatic layer having compositions shown in Table 4 below were prepared, respectively. The unit of the numerical value shown in the column of each component in Table 4 is part by mass.

TABLE 4

| Composition for antistatic layer | | | B-1 | B-2 | B-3 | B-4 | B-5 | B-6 | B-7 |
|---|---|---|---|---|---|---|---|---|---|
| Radically | Ethoxylated bisphenol A dimethacrylate | | — | — | — | — | — | — | 17.20 |
| polymerizable | (BPE-500, manufactured by Shin-Nakamura | | | | | | | | |
| compound | Chemical Co., Ltd.) | | | | | | | | |
| Polymer | Polyvinylpyrrolidone | | 0.09 | 0.19 | 0.28 | — | — | 0.28 | — |
| | (K-30, manufactured by I. S.P.Japan Co., Ltd.) | | | | | | | | |
| | Polyvinyl alcohol | | 0.21 | 0.41 | 0.62 | — | — | 0.62 | — |
| | (manufactured by KURARAY CO., LTD.) | | | | | | | | |
| | P-4 | | — | — | — | — | — | — | 77.46 |
| Photopolymerization | 2-Methyl-1-(4-methylthiophenyl)-2-morpholino- | | — | — | — | — | — | — | 0.96 |
| initiator | propan-1 -one | | | | | | | | |
| | (Irgacure 907, manufactured by BASF SE) | | | | | | | | |
| | 2,4-Diethyl thioxanthone | | — | — | — | — | — | — | 0.57 |
| | (KAYACURE DETX-S, manufactured by Nippon | | | | | | | | |
| | Kayaku Co., Ltd.) | | | | | | | | |
| Antistatic agent | Ionic | FS-10D | 13.04 | 11.59 | 9.13 | — | — | — | — |
| | conductive | (manufactured by ISH1HARA | | | | | | | |
| | filler | SANGYO KAISHA, LTD., 20% by | | | | | | | |
| | | mass ultrafine tin oxide aqueous | | | | | | | |
| | | dispersion liquid) | | | | | | | |
| | Ionic | Acrit 1SX-1055F | — | — | — | 11.39 | — | — | — |
| | conductive | (manufactured by Taisei Fine | | | | | | | |
| | polymer | Chemical Co., Ltd., 43.9% by mass | | | | | | | |
| | | aqueous solution of quaternary | | | | | | | |
| | | ammonium salt-type antistatic | | | | | | | |
| | | polymer) | | | | | | | |
| | Electrically | N8-2-1 | — | — | — | — | 100.00 | — | — |
| | conductive | (manufactured by Nagase ChemteX | | | | | | | |
| | polymer | Co., Ltd 1.5% by mass aqueous | | | | | | | |
| | | dispersion liquid of | | | | | | | |
| | | polythiophene-based electrically | | | | | | | |
| | | conductive polymer) | | | | | | | |
| | Ionic liquid | IL-AP3 | — | — | — | — | — | 0.05 | — |
| | | (manufactured by KOEI | | | | | | | |
| | | CHEMICAL CO., LTD.) | | | | | | | |
| | Electrically | Orgacon ICP1010 | — | — | — | — | — | — | 3.82 |
| | conductive | (manufactured by Nippon Agfa | | | | | | | |
| | polymer | Materials Co., Ltd., 1.2% by mass | | | | | | | |
| | | aqueous dispersion liquid) | | | | | | | |
| Solvent | | Water | 86.66 | 87.81 | 89.97 | 88.61 | — | 99.05 | — |

### Examples 1 to 15 and Comparative Examples 2 and 3

To a surface on which a release layer of a transparent film 1 (Cerapeel 25WZ, thickness: 25 μm, manufactured by TORAY ADVANCED FILM CO., LTD., polyethylene terephthalate film with a release layer) was formed, the compositions (A-1 to A-6) for a photosensitive layer were applied according to the description in Tables 6 and 7 using a slit-shaped nozzle, and then the solvent was volatilized in a drying zone at 120° C. to form a photosensitive layer. The coating amount of the composition for a photosensitive layer was adjusted to be the thickness of the photosensitive layer shown in Tables 6 and 7. To the above-described photosensitive layer, the compositions (B-1 to B-6) for an antistatic layer were applied according to the description in Tables 6 and 7 using a slit-shaped nozzle, and dried to form an antistatic layer. The coating amount of the composition for an antistatic layer was adjusted to be the thickness of the antistatic layer shown in Tables 6 and 7. Next, a transparent film 2 (LUMIRROR 16QS62, thickness: 16 μm, manufactured by Toray Industries, Inc., polyethylene terephthalate film) was pressure-bonded onto the antistatic layer.

By the above-described procedure, photosensitive transfer films of Examples 1 to 15 and Comparative Examples 2 and 3 were produced, respectively. Each of the above-described photosensitive transfer films has the transparent film 1, the photosensitive layer, the antistatic layer, and the transparent film 2 in this order.

### Comparative Example 1

A photosensitive transfer film of Comparative Example 1 was produced by the same method as in Example 1, except that the antistatic layer was not formed. The photosensitive transfer film of Comparative Example 1 has the transparent film 1, the photosensitive layer, and the transparent film 2 in this order.

### Comparative Example 4

The composition B-7 for an antistatic layer was applied to a transparent film 2 (polyethylene terephthalate film G2, manufactured by Teijin Film Solution Co., Ltd.) with a gravure coater to a coating thickness of 6 μm, and then dried at 80° C. for 4 minutes to form an antistatic layer having a thickness of 2 μm. The composition A-7 for a photosensitive layer was applied to the above-described antistatic layer with a comma coater to a coating thickness of 50 μm, and then dried at 90° C. for 15 minutes to produce a photosensitive layer having a thickness of 20 Further, by laminating a transparent film 1 (polyethylene film GF-1, manufactured by Tamapoly Co., Ltd.) on the above-described photosensitive layer with a laminating machine at 50° C. and a pressure of 0.5 MPa, a photosensitive transfer film of Comparative Example 4 was produced. The photosensitive transfer film of Comparative Example 4 has the transparent film 1, the photosensitive layer, the antistatic layer, and the transparent film 2 in this order.

### Comparative Example 5

To a surface on which a release layer of a transparent film 1 (Cerapeel 25WZ, thickness: 25 μm, manufactured by TORAY ADVANCED FILM CO., LTD., polyethylene terephthalate film with a release layer) was formed, the composition A-7 for a photosensitive layer was applied with a gravure coater to a coating thickness of 27 μm, and then dried at 80° C. for 4 minutes to form a photosensitive layer having a thickness of 9 μm. To the above-described photosensitive layer, the composition B-1 for an antistatic layer was applied using a slit-shaped nozzle, and dried to form an antistatic layer having a thickness of 0.1 Next, a transparent film 2 (LUMIRROR 16QS62, thickness: 16 manufactured by Toray Industries, Inc., polyethylene terephthalate film) was pressure-bonded onto the antistatic layer, thereby producing a photosensitive transfer film of Comparative Example 5. The photosensitive transfer film of Comparative Example 5 has the transparent film 1, the photosensitive layer, the antistatic layer, and the transparent film 2 in this order.

### Synthesis Example 1: Polystyrene Sulfonic Acid

206 g of sodium styrene sulfonate was dissolved in 1000 mL of ion exchange water, and then while stirring at 80°, an aqueous solution in which 1.14 g of an ammonium persulfate oxidant had been dissolved in 10 mL of water was added dropwise thereto for 20 minutes, and the solution was stirred for 12 hours.

1000 mL of sulfuric acid diluted to 10% by mass was added to the obtained aqueous solution containing sodium polystyrene sulfonate, the 1000 mL solution of the aqueous solution containing polystyrene sulfonic acid was removed by using an ultrafiltration method. After adding 2000 mL of ion exchange water to the residual liquid, approximately 2000 mL of the solution was removed using an ultrafiltration method. The above-described ultrafiltration operation was repeated 3 times.

Further, after adding approximately 2000 mL of ion exchange water to the obtained filtrate, approximately 2000 mL of the solution was removed using an ultrafiltration method. This ultrafiltration operation was repeated 3 times.

Water in the obtained solution was removed under reduced pressure to obtain a colorless solid. As a result of measuring the weight-average molecular weight of the obtained polystyrene sulfonic acid using a high performance liquid chromatography (HPLC) system using a gel permeation chromatography (GPC) column with Pullulan manufactured by SHOWA DENKO K.K. as a standard substance, the molecular weight was 300,000.

<Preparation of Dispersion Liquid AS-1>

14.2 g of 3,4-ethylenedioxythiophene and a solution in which 36.7 g of polystyrene sulfonic acid obtained in Synthesis Example 1 had been dissolved in 2000 mL of ion exchange water were mixed at 20° C. While keeping the mixed solution obtained above at 20° C. and stirring, a solution in which 29.64 g of ammonium persulfate and 8.0 g of a ferric sulfate oxidation catalyst had been dissolved in 200 mL of ion exchange water was slowly added thereto, and the reaction was performed with stirring for 3 hours.

After adding 2000 mL of ion exchange water to the obtained reaction solution, approximately 2000 mL of the solution was removed using an ultrafiltration method. This operation was repeated 3 times.

Next, 200 mL of a 10% by mass sulfuric acid aqueous solution and 2000 mL of ion exchange water were added to the obtained solution, and approximately 2000 mL of the solution was removed using an ultrafiltration method. After adding 2000 mL of ion exchange water to the residual liquid, approximately 2000 mL of the solution was removed using an ultrafiltration method. This operation was repeated 3 times.

Further, after adding 2000 mL of ion exchange water to the obtained solution, approximately 2000 mL of the solution was removed using an ultrafiltration method. This operation was repeated 5 times to obtain a 1.2% by mass blue PEDOT/PSS aqueous solution.

100 g of PEDOT/PSS aqueous solution obtained above and 100 g of methanol were mixed, and while stirring at 50° C., a mixed solution of 200 g of methanol and 12.5 g of C12 and C13 mixed higher alcohol glycidyl ether was added dropwise thereto for 60 minutes, thereby obtaining a dark blue precipitate. This precipitate was collected by filtration and then dispersed in methyl ethyl ketone (MEK) to obtain a MEK dispersion liquid (AS-1) of 1% by mass of PEDOT/PSS.

<Preparation of Composition for Antistatic Layer>

Compositions B-8 to B-13 for an antistatic layer having compositions shown in Table 5 below were prepared, respectively. The unit of the numerical value shown in the column of each component in Table 5 is part by mass.

TABLE 5

| Composition for forming antistatic layer | | | B-8 | B-9 | B-10 | B-11 | B-12 | B-13 |
|---|---|---|---|---|---|---|---|---|
| Radically | 1,10-decanediol diaciylate | | 1.04 | 1.04 | 1.06 | 1.04 | 0.98 | 1.04 |
| polymerizable | [(A-DOD-N, manufactured by Shin-Nakamura | | | | | | | |
| compound | Chemical Co., Ltd.) | | | | | | | |
| | 75% by mass PGMEA solution of dipentaerythritol | | 1.36 | 1.36 | 1.39 | 1.36 | 1.29 | 1.36 |
| | hexaacrylate | | | | | | | |
| | (KAYARAD DPHA, manufactured by Shin-Nakamura | | | | | | | |
| | Chemical Co., Ltd.) | | | | | | | |
| Polymer | 27% by mass PGMEA solution of P-1 (acid value: 113) | | — | 9.59 | — | — | — | — |
| | 27% by mass PGMEA solution of P-3 (acid value: 95) | | 9.59 | — | 9.80 | 9.59 | 9.09 | — |
| | 27% by mass PGMEA solution of P-9 (acid value: 94) | | — | — | — | — | — | 9.59 |
| Photopolymerization | 1-[9-Ethyl-6-(2-methylbenzoyl)-9H-carbazol-3- | | 0.02 | 0.02 | 0.02 | 0.02 | 0.02 | 0.02 |
| initiator | yl]ethanone-1-(O-acetyloxime) | | | | | | | |
| | (Irgacure OXE-02, manufactured by BASF SE) | | | | | | | |
| | 2-Methyl-1-(4-methylthiophenyl)-2-morpholinopro- | | 0.05 | 0.05 | 0.05 | 0.05 | 0.05 | 0.05 |
| | pan-1-one | | | | | | | |
| | (Irgacure 907, manufactured by BASF SE) | | | | | | | |
| Antistatic agent | Electrically | Acryt 1SX-207 | 0.56 | — | — | — | — | — |
| | conductive | (manufactured by Taisei Fine Chemical | | | | | | |
| | polymer | Co., Ltd., 45% by mass methanol/MEK | | | | | | |
| | | solution of quaternary ammonium | | | | | | |
| | | salt-type antistatic polymer) | | | | | | |
| | | AS-1 (1% by mass MEK dispersion | — | 25.00 | 15.00 | 25.00 | 50.00 | 25.00 |
| | | liquid of PEDOT/PSS) | | | | | | |

| | | | | | | | |
|---|---|---|---|---|---|---|---|
| Surfactant | MEGAFACE F551A (manufactured by DIC | 0.05 | 0.05 | 0.05 | 0.05 | 0.05 | 0.05 |
| | Corporation) | | | | | | |
| | (30% by mass PGMEA solution) | | | | | | |
| Solvent | Propylene glycol monomethyl ether acetate | 59.13 | 59.13 | 58.98 | 59.13 | 38.51 | 59.13 |
| | (PGMEA) | | | | | | |
| | Methyl ethyl ketone | 28.19 | 3.75 | 13.65 | 3.75 | — | 3.75 |
| | (MEK) | | | | | | |

### Example 16

The composition B-8 for an antistatic layer was applied to a transparent film 2 (LUMIRROR 16QS62, thickness: 16 μm, manufactured by Toray Industries, Inc., polyethylene terephthalate film) using a slit-shaped nozzle such that the thickness after drying was 0.1 μm, and then dried at 80° C. for 2 minutes to form an antistatic layer. To the above-described antistatic layer, the composition A-3 for a photosensitive layer was applied using a slit-shaped nozzle such that the thickness after drying was 8.0 μm, and then the solvent was volatilized in a drying zone at 120° C. to produce a photosensitive layer. Further, by laminating a transparent film 1 (LUMIRROR 16QS62, thickness: 16 μm, manufactured by Toray Industries, Inc., polyethylene terephthalate film) on the above-described photosensitive layer with a laminating machine at 50° C. and a pressure of 0.5 MPa, a photosensitive transfer film of Example 16 was produced.

### Example 17

A photosensitive transfer film of Example 17 was produced in the same manner as in Example 16, except that the B-9 was used as the composition for an antistatic layer.

### Example 18

A photosensitive transfer film of Example 18 was produced in the same manner as in Example 16, except that the B-10 was used as the composition for an antistatic layer.

### Example 19

A photosensitive transfer film of Example 19 was produced in the same manner as in Example 16, except that the B-11 was used as the composition for an antistatic layer.

### Example 20

A photosensitive transfer film of Example 20 was produced in the same manner as in Example 16, except that the B-12 was used as the composition for an antistatic layer.

### Example 21

A photosensitive transfer film of Example 21 was produced in the same manner as in Example 19, except that the composition A-3 for a photosensitive layer was applied such that the thickness of the photosensitive layer after drying was 4.0 μm.

### Example 22

A photosensitive transfer film of Example 22 was produced in the same manner as in Example 19, except that the composition A-3 for a photosensitive layer was applied such that the thickness of the photosensitive layer after drying was 1.0 μm.

### Example 23

A photosensitive transfer film of Example 23 was produced in the same manner as in Example 19, except that the composition A-3 for a photosensitive layer was applied such that the thickness of the photosensitive layer after drying was 0.5 μm.

By the above-described procedure, the photosensitive transfer films of Examples 16 to 23 were produced, respectively. Each of the above-described photosensitive transfer films has the transparent film 2, the antistatic layer, the photosensitive layer, and the transparent film 1 in this order.

### Examples 24 to 51

With regard to the compositions (A-8 to A-31) for a photosensitive layer, the coating amount of the composition for a photosensitive layer was adjusted according to the description in Tables 9 to 12 such that the thickness of the photosensitive layer was as described in Tables 9 to 12. To the above-described photosensitive layer, the compositions (B-11 to B-13) for an antistatic layer were applied according to the description in Tables 9 to 12 using a slit-shaped nozzle, and dried to form an antistatic layer. The coating amount of the composition for an antistatic layer was adjusted to be the thickness of the antistatic layer shown in Tables 9 to 12. Next, a transparent film 2 (LUMIRROR 16QS62, thickness: 16 μm, manufactured by Toray Industries, Inc., polyethylene terephthalate film) was pressure-bonded onto the antistatic layer. By the above-described procedure, photosensitive transfer films of Examples 24 to 51 were produced, respectively. Each of the above-described photosensitive transfer films has the transparent film 1, the photosensitive layer, the antistatic layer, and the transparent film 2 in this order.

<Measurement of Surface Electrical Resistance Value>

With regard to each of the photosensitive transfer films of Examples 1 to 51 and Comparative Example 2 and 3, by peeling off the transparent film 1 and then laminating the surface of the exposed photosensitive layer on a glass base material (Eagle XG, thickness: 0.7 mm, manufactured by Corning Inc.), a structure body having a laminated structure of transparent film 2/antistatic layer/photosensitive layer/glass base material was obtained, respectively. In the laminating conditions, a roll temperature was set as 110° C., a linear pressure was set as 0.6 MPa, and a linear velocity (laminating speed) was set as 2.0 m/min. The transparent film 2 was peeled off from each of the above-described structure bodies, the structure body having a laminated structure of three layers of antistatic layer/photosensitive layer/glass base material was humidity-controlled for 24 hours under the conditions of a temperature of 23° C. and a humidity of 55%, and then the surface electrical resistance value of the antistatic layer was measured using a resistivity meter (Hiresta-UX MCP-HT800 manufactured by Mitsubishi Chemical Analytech Co., Ltd.) under an applied voltage of 1000 V. In addition, by the same method as described above, using the photosensitive transfer film of Comparative Example 1, a structure body having a laminated structure of photosensitive layer/glass base material was produced, and the surface electrical resistance value of the photosensitive layer was measured.

In addition, with regard to each of the photosensitive transfer films of Comparative Examples 4 and 5, by peeling off the transparent film 1 and then laminating the surface of the exposed photosensitive layer on a glass base material (Eagle XG, thickness: 0.7 mm, manufactured by Corning Inc.), a structure body having a laminated structure of transparent film 2/antistatic layer/photosensitive layer/glass base material was obtained, respectively. In the laminating conditions, a vacuum degree was set as 0.5 hPa, a press pressure (pressurization) was set as 0.5 MPa, a press temperature (dry film temperature) was set as 80° C., and a pressurization time was set as 90 seconds. Next, each of the above-described structure bodies was exposed from above the transparent film 2 with an exposure amount of 600 mJ/cm² without using an exposure mask. As an exposure machine, HMW-532D (manufactured by ORC MANUFACTURING CO., LTD.), in which a high-pressure mercury lamp was used as a lamp, was used. Further, after peeling off the transparent film 2, thermosetting was performed by heating at 140° C. for 20 minutes, 180° C. for 20 minutes, and then 240° C. for 20 minutes. Next, the structure body having a laminated structure of three layers of antistatic layer/photosensitive layer/glass base material was humidity-controlled for 24 hours under the conditions of a temperature of 23° C. and a humidity of 55%, and then the surface electrical resistance value of the antistatic layer was measured using a resistivity meter (Hiresta-UX MCP-HT800 manufactured by Mitsubishi Chemical Analytech Co., Ltd.) under an applied voltage of 1000 V.

The measurement results of the surface electrical resistance value are shown in Tables 6 to 12.

<Evaluation of Patterning Properties of Antistatic Layer>

As one index (that is, developability) of patterning properties of the antistatic layer, the shortest developing time required to resolve a pattern of L/S=100 μm/100 μm was determined by the following method.

With regard to each of the transfer films of Examples 1 to 51 and Comparative Example 2 and 3, by peeling off the transparent film 1 and then laminating the surface of the exposed photosensitive layer on an ITO base material, a structure body having a laminated structure of transparent film 2/antistatic layer/photosensitive layer/base material was obtained, respectively. In the laminating conditions, a roll temperature was set as 110° C., a linear pressure was set as 0.6 MPa, and a linear velocity (laminating speed) was set as 2.0 m/min. Using a proximity type exposure machine (manufactured by Hitachi High-Tech Electronic Engineering Corporation) having an ultra-high pressure mercury lamp, each of the above-described structure bodies was exposed with an exposure amount of 120 mJ/cm² (i ray) through a mask having a pattern of L/S=100 μm/100 μm, without peeling off the transparent film 2. After exposure, the transparent film 2 of each of the above-described structure bodies was peeled off after being left for 1 hour, and the structure body was developed with a 1% by mass aqueous solution of sodium carbonate (liquid temperature: 30° C.) to develop and remove the antistatic layer and the photosensitive layer in the unexposed portion. Further, air was blown to remove water. The development was performed while changing the development time, and the shortest development time required to resolve a pattern of L/S=100 μm/100 μm was determined.

In all the examples after the development, the antistatic layer had the same patterned shape as the patterned shape of the remaining portion of the photosensitive layer (that is, the cured composition layer of the photosensitive composition).

In addition, with regard to each of the photosensitive transfer films of Comparative Examples 4 and 5, by peeling off the transparent film 1 and then laminating the surface of the exposed photosensitive layer on an ITO base material, a structure body having a laminated structure of transparent film 2/antistatic layer/photosensitive layer/base material was obtained, respectively. In the laminating conditions, a vacuum degree was set as 0.5 hPa, a press pressure (pressurization) was set as 0.5 MPa, a press temperature (dry film temperature) was set as 80° C., and a pressurization time was set as 90 seconds. Each of the above-described structure bodies was exposed with an exposure amount of 600 mJ/cm² through a mask having a pattern of L/S=100 μm/100 μm, without peeling off the transparent film 2. As an exposure machine, HMW-532D (manufactured by ORC MANUFACTURING CO., LTD.), in which a high-pressure mercury lamp was used as a lamp, was used. After the transparent film 2 of each of the above-described structure bodies was peeled off, the structure body was developed with a 1% by mass aqueous solution of sodium carbonate (liquid temperature: 30° C.) to develop and remove the antistatic layer and the photosensitive layer in the unexposed portion. Further, air was blown to remove water. The development was performed while changing the development time, and the shortest development time required to resolve a pattern of L/S=100 μm/100 μm was determined.

Patterning properties of the antistatic layer were evaluated according to the following standard. The evaluation results are shown in Tables 6 to 12. In all the examples, the residual pattern after development had a laminated structure of antistatic layer/photosensitive layer/base material.

(Standard)

A: shortest development time was 60 seconds or less.

B: shortest development time was more than 60 seconds and 120 seconds or less.

C: shortest development time was more than 120, or development was not possible.

<Evaluation of Peeling Band Voltage>

With regard to each of the photosensitive transfer films of Examples 1 to 51 and Comparative Example 2 to 5, by peeling off the transparent film 1 and then laminating the surface of the exposed photosensitive layer on a glass base material (Eagle XG, thickness: 0.7 mm, manufactured by Corning Inc.), a structure body having a laminated structure of transparent film 2/antistatic layer/photosensitive layer/glass base material was obtained, respectively. In addition, by the same method as described above, using the photosensitive transfer film of Comparative Example 1, a structure body having a laminated structure of transparent film 2/photosensitive layer/glass base material was obtained. In the laminating conditions for each of the photosensitive transfer films of Examples 1 to 23 and Comparative Examples 1 to 3, a roll temperature was set as 110° C., a linear pressure was set as 0.6 MPa, and a linear velocity (laminating speed) was set as 2.0 m/min. In addition, in the laminating conditions for each of the photosensitive transfer films of Comparative Examples 4 and 5, a vacuum degree was set as 0.5 hPa, a press pressure (pressurization) was set as 0.5 MPa, a press temperature (dry film temperature) was set as 80° C., and a pressurization time was set as 90 seconds. The peeling band voltage generated in a case where the transparent film 2 is peeled off 180° from each of the above-described structure bodies at a peeling rate of 10 m/min under an atmosphere of a temperature of 23° C. and a humidity of 50% RH (relative humidity) was measured using an electrostatic potential measuring device KSD-0103 manufactured by KASUGA DENKI, INC. The measurement position was set to a position 10 cm away from the surface of the transparent film 2 in each of the above-described structure bodies.

The obtained peeling band voltage was evaluated according to the following standard. The evaluation results are shown in Tables 6 to 12.

(Standard)

A: peeling band voltage was 500 V or less.

B: peeling band voltage was more than 500 V and 1000 V or less.

C: peeling band voltage was more than 1000 V.

<Evaluation of Transmittance after Baking>

With regard to each of the photosensitive transfer films of Examples 1 to 51 and Comparative Example 2 and 3, by peeling off the transparent film 1 and then laminating the surface of the exposed photosensitive layer on a glass base material (Eagle XG thickness: 0.7 mm, manufactured by Corning Inc.), a structure body having a laminated structure of transparent film 2/antistatic layer/photosensitive layer/glass base material was obtained. In addition, by the same method as described above, using the photosensitive transfer film of Comparative Example 1, a structure body having a laminated structure of transparent film 2/photosensitive layer/glass base material was obtained. In the laminating conditions for each of the photosensitive transfer films of Examples 1 to 51 and Comparative Examples 1 to 3, a roll temperature was set as 110° C., a linear pressure was set as 0.6 MPa, and a linear velocity (laminating speed) was set as 2.0 m/min. Using a proximity type exposure machine (manufactured by Hitachi High-Tech Electronic Engineering Corporation) having an ultra-high pressure mercury lamp, each of the above-described structure bodies was exposed with an exposure amount of 120 mJ/cm² (i ray), without peeling off the transparent film 2. After peeling off the transparent film 2, exposure was further performed with an exposure amount of 375 mJ/cm² (i ray), and then post baking was performed at 145° C. for 30 minutes to cure the antistatic layer and the photosensitive layer, thereby forming a cured film (that is, a cured composition layer).

With regard to each of the photosensitive transfer films of Comparative Examples 4 and 5, by peeling off the transparent film 1 and then laminating the surface of the exposed photosensitive layer on a glass base material (Eagle XG, thickness: 0.7 mm, manufactured by Corning Inc.), a structure body having a laminated structure of transparent film 2/antistatic layer/photosensitive layer/glass base material was obtained, respectively. In the laminating conditions, a vacuum degree was set as 0.5 hPa, a press pressure (pressurization) was set as 0.5 MPa, a press temperature (dry film temperature) was set as 80° C., and a pressurization time was set as 90 seconds. Each of the above-described structure bodies was exposed from above the transparent film 2 with an exposure amount of 600 mJ/cm². As an exposure machine, HMW-532D (manufactured by ORC MANUFACTURING CO., LTD.), in which a high-pressure mercury lamp was used as a lamp, was used. Further, after peeling off the transparent film 2, the photosensitive layer was cured by heating at 140° C. for 20 minutes, 180° C. for 20 minutes, and then 240° C. for 20 minutes, thereby forming a cured film.

Using a spectrophotometer UV1800 type (manufactured by Shimadzu Corporation), the transmittance at a wavelength of 400 to 800 nm was measured. The obtained transmittance was evaluated according to the following standard. The evaluation results are shown in Tables 6 to 12.

(Standard)

A: average transmittance at a wavelength of 400 to 800 nm was 90% or more.

B: average transmittance at a wavelength of 400 to 800 nm was 85% or more and less than 90%.

C: average transmittance at a wavelength of 400 to 800 nm was less than 85%.

<Measurement of Haze>

With regard to each of the photosensitive transfer films of Examples 1 to 51 and Comparative Example 2 to 5, by peeling off the transparent film 1 and then laminating the surface of the exposed photosensitive layer on a glass base material (Eagle XC; thickness: 0.7 mm, manufactured by Corning Inc.), a structure body having a laminated structure of transparent film 2/antistatic layer/photosensitive layer/glass base material was obtained, respectively. In addition, by the same method as described above, using the photosensitive transfer film of Comparative Example 1, a structure body having a laminated structure of transparent film 2/photosensitive layer/glass base material was obtained. In the laminating conditions for each of the photosensitive transfer films of Examples 1 to 51 and Comparative Examples 1 to 3, a roll temperature was set as 110° C., a linear pressure was set as 0.6 MPa, and a linear velocity (laminating speed) was set as 2.0 m/min. In addition, in the laminating conditions for each of the photosensitive transfer films of Comparative Examples 4 and 5, a vacuum degree was set as 0.5 hPa, a press pressure (pressurization) was set as 0.5 MPa, a press temperature (dry film temperature) was set as 80° C., and a pressurization time was set as 90 seconds.

After peeling off the transparent film 2 from each of the above-described structure bodies, using a haze meter NDH4000 (manufactured by NIPPON DENSHOKU INDUSTRIES Co., Ltd.), the haze of the structure body (Examples 1 to 51 and Comparative Examples 2 to 5) having a laminated structure of three layers of antistatic layer/photosensitive layer/glass base material and the haze of the structure body (Comparative Example 1) having a laminated structure of photosensitive layer/glass base material were measured, respectively. Further, the haze of the glass base material used for producing each of the above-described structure bodies was measured by the same method as described above. By subtracting the haze of the glass base material from the haze of each structure body, the haze of the laminated structure of antistatic layer/photosensitive layer and the haze of the photosensitive layer were obtained, respectively. The obtained haze was evaluated according to the following standard. The evaluation results are shown in Tables 6 to 12.

(Standard)

A: haze was 3% or less.

B: haze was more than 3% and 10% or less.

C: haze was more than 10%.

<Evaluation of Bending Resistance (Bend Resistance)>

—Production of Bending Resistance Evaluation Sample—

With regard to each of the photosensitive transfer films of Examples 1 to 51 and Comparative Example 2 to 5, by peeling off the transparent film 1 and then laminating the surface of the exposed photosensitive layer on one surface of Kapton (thickness: 50 μm) of a polyimide film manufactured by DU PONT-TORAY CO., LTD., which had been heat-treated at 145° for 30 minutes, a structure body having a laminated structure of transparent film 2/antistatic layer/photosensitive layer/Kapton (thickness: 50 μm) was produced, respectively. In addition, by the same method as described above, using the photosensitive transfer film of Comparative Example 1, a structure body having a laminated structure of transparent film 2/photosensitive layer/Kapton (thickness: 50 μm) was produced. In the laminating conditions for each of the transfer films of Examples 1 to 51 and Comparative Examples 1 to 3, a roll temperature was set as 110° C., a linear pressure was set as 0.6 MPa, and a linear velocity (laminating speed) was set as 2.0 m/min. In addition, in the laminating conditions for each of the photosensitive transfer films of Comparative Examples 4 and 5, a vacuum degree was set as 0.5 hPa, a press pressure (pressurization) was set as 0.5 MPa, a press temperature (dry film temperature) was set as 80° C., and a pressurization time was set as 90 seconds.

Next, with regard to Examples 1 to 51 and Comparative Examples 1 to 3, both surfaces were exposed through the transparent film 2 using a proximity type exposure machine (manufactured by Hitachi High-Tech Electronics Engineering Co., Ltd.) including an ultra-high pressure mercury lamp with an exposure amount of 100 mJ/cm² (i ray). After peeling off the transparent film 2, exposure was further performed on the both surfaces with an exposure amount of 375 mJ/cm² (i ray), and then post baking was performed at 145° C. for 30 minutes to cure the antistatic layer and the photosensitive layer, thereby forming a cured film (that is, a cured composition layer).

Next, with regard to Comparative Examples 4 and 5, each of the above-described structure bodies was exposed from above the transparent film 2 in the structure body having a laminated structure of transparent film 2/antistatic layer/photosensitive layer/Kapton (thickness: 50 μm) with an exposure amount of 600 mJ/cm² without using an exposure mask. As an exposure machine, HMW-532D (manufactured by ORC MANUFACTURING CO., LTD.), in which a high-pressure mercury lamp was used as a lamp, was used. Further, after peeling off the transparent film 2, the antistatic layer and the photosensitive layer were cured by heating at 140° C. for 20 minutes, 180° C. for 20 minutes, and then 240° C. for 20 minutes, thereby forming a cured film.

By the above-described procedure, bending resistance evaluation samples having a laminated structure of cured film of antistatic layer/cured film of photosensitive layer/Kapton (thickness: 50 μm) or a laminated structure of cured film of photosensitive layer/Kapton (thickness: 50 μm) were obtained.

—Evaluation of Bending Resistance (Bend Resistance)—

Bending resistance of each of the above-described bending resistance evaluation samples was evaluated by the following method. Hereinafter, the evaluation of bending resistance will be described with reference to the drawing. FIG. 4 is a schematic cross-sectional view showing an example of a state of the bending resistance evaluation sample in a bending resistance evaluation.

First, each of the above-described bending resistance evaluation sample was cut into a rectangle of 5 cm×12 cm. As shown in FIG. 4, in the cut bending resistance evaluation sample 102, a weight 104 of 100 g was attached to one of the short sides and weighted, and was held to be in contact with a metal rod 106 having a diameter of d (unit: millimeter) at an angle of 90° (state of the bending resistance evaluation sample 102 in FIG. 4).

Next, with a state in which the Kapton (thickness: 50 μm) and the metal rod 106 were in contact with each other, the bending resistance evaluation sample 102 was bent 180° to be wound around the metal rod 106 (state of the bending resistance evaluation sample 102A after bending in FIG. 4), the movement (reciprocating direction D) of returning to the original position was reciprocated 10 times, and then the presence or absence of cracks on the surface of the sample was visually confirmed.

The above-described test was performed while changing the diameter d of the above-described metal rod 106, and the smallest diameter d at which cracks did not occur was obtained. The bending resistance was evaluated according to the following standard. In the following standard, A was the best bending resistance and D was the worst bending resistance. A or B is a practically acceptable level.

(Standard)

A: smallest diameter d which did not cause cracks was 3 mm or less.

B: smallest diameter d which did not cause cracks was more than 3 mm and 4 mm or less.

C: smallest diameter d which did not cause cracks was more than 4 mm and 5 mm or less.

D: smallest diameter d which did not cause cracks was more than 5 mm.

<Evaluation of Silver Nanowire Durability (Change in Resistance Value)>

With regard to each of the photosensitive transfer films of Examples 16 to 51, by peeling off the transparent film 1 and then laminating the exposed photosensitive layer on a base material having a layer containing silver nanowires on its surface, a structure body having a laminated structure of transparent film 2/antistatic layer/photosensitive layer/layer containing silver nanowires/base material was obtained. Hereinafter, the “layer containing silver nanowires/base material” is referred to as “silver nanowire base material”. In the laminating conditions for each of the photosensitive transfer films of Examples 16 to 23, a roll temperature was set as 110° C., a linear pressure was set as 0.6 MPa, and a linear velocity (laminating speed) was set as 2.0 m/min. Using a proximity type exposure machine (manufactured by Hitachi High-Tech Electronic Engineering Corporation) having an ultra-high pressure mercury lamp, each of the above-described structure bodies was exposed with an exposure amount of 120 mJ/cm² (i ray), without peeling off the transparent film 2. After peeling off the transparent film 2, exposure was further performed with an exposure amount of 375 mJ/cm² (i ray), and then post baking was performed at 145° C. for 30 minutes to cure the antistatic layer and the photosensitive layer, thereby forming a cured film (that is, a cured composition layer).

By the above-described procedure, a laminated structure of cured film of antistatic layer/cured film of photosensitive layer/silver nanowire base material was obtained. The above-described laminated structure was cut into a square of 10 cm×10 cm. Using a noncontact resistance tester EC-80P (manufactured by NAPSON), the resistance value of the silver nanowire base material in the laminated structure was measured by pressing a probe of the noncontact resistance tester against the laminated structure on the antistatic layer side, and the average of 9 points in the plane was set as an initial resistance value of the laminated structure.

After the laminated structure in which the resistance value was measured above was left to stand in an environment of 85° C. and 85% RH (relative humidity) for 500 hours, the resistance value after durability was measured by the same method as described above, and the rate of change from the initial resistance value was calculated by the following expression (1).

Rate of change in resistance value=Resistance value after durability÷Initial resistance value−1 Expression (1)

The obtained rate of change in resistance value was evaluated according to the following standard. In the following standard, A was the best durability and C was the worst durability. The evaluation results are shown in Tables 8 to 12.

(Standard)

A: change in resistance value was 10% or less.

B: change in resistance value was more than 10% and 30% or less.

C: change in resistance value was more than 30%.

<Evaluation of Region where Antistatic Agent is not Detected>

With regard to each of the photosensitive transfer films of Examples 16 to 51, after peeling off the transparent film 1, using TOF.SIMS5 (product name) manufactured by ION-TOF and an Ar⁺ cluster gun, a region where the antistatic agent was not detected was measured from the surface of the exposed photosensitive layer according to the method described above. The evaluation results are shown in Tables 8 to 12.

TABLE 6

| | | | Example | Example | Example | Example | Example | Example |
|---|---|---|---|---|---|---|---|---|
| | | | 1 | 2 | 3 | 4 | 5 | 6 |
| Photosensitive | Transparent film 1 | | Cerapeel | Cerapeel | Cerapeel | Cerapeel | Cerapeel | Cerapeel |
| transfer film | | | 25 WZ | 25 WZ | 25 WZ | 25 WZ | 25 WZ | 25 WZ |
| | Photosensitive | Composition | A-1 | A-1 | A-1 | A-1 | A-2 | A-3 |
| | layer | Thickness [μm] | 4 | 4 | 4 | 4 | 4 | 4 |
| | Antistatic layer | Composition | B-1 | B-1 | B-2 | B-3 | B-1 | B-1 |
| | | Thickness [μm] | 0.1 | 0.3 | 0.1 | 0.1 | 0.1 | 0.1 |
| | Transparent film 2 | | 16QS62 | 16QS62 | 16QS62 | 16QS62 | 16QS62 | 16QS62 |
| | Surface electrical resistance [Ω/□] | | 2.8 × 10\hat{ }10 | 1.2 × 10\hat{ }10 | 2.3 × 10\hat{ }11 | 7.7 × 10\hat{ }12 | 2.8 × 10\hat{ }10 | 2.8 × 10\hat{ }10 |
| Evaluation | Patterning properties | | A | A | A | A | A | A |
| | Peeling band voltage [V] | | A | A | A | B | A | A |
| | Transmittance [%] | | A | A | A | A | A | A |
| | Haze [%] | | A | A | A | A | A | A |
| | Bend resistance | | A | A | A | A | A | A |
| | | | Example | Example | Example | Example | Example | Example |
| | | | 7 | 8 | 9 | 10 | 11 | 12 |
| Photosensitive | Transparent film 1 | | Cerapeel | Cerapeel | Cerapeel | Cerapeel | Cerapeel | Cerapeel |
| transfer film | | | 25 WZ | 25 WZ | 25 WZ | 25 WZ | 25 WZ | 25 WZ |
| | Photosensitive | Composition | A-4 | A-5 | A-1 | A-1 | A-1 | A-1 |
| | layer | Thickness [μm] | 4 | 4 | 4 | 1 | 7 | 9 |
| | Antistatic layer | Composition | B-1 | B-1 | B-1 | B-1 | B-1 | B-1 |
| | | Thickness [μm] | 0.1 | 0.1 | 0.5 | 0.1 | 0.1 | 0.1 |

| | | | | | | | |
|---|---|---|---|---|---|---|---|
| | Transparent film 2 | 16QS62 | 16QS62 | 16QS62 | 16QS62 | 16QS62 | 16QS62 |
| | Surface electrical resistance [Ω/□] | 2.8 × 10\hat{ }10 | 2.8 × 10\hat{ }10 | 6.4 × 10\hat{ }9 | 2.8 × 10\hat{ }10 | 2.8 × 10\hat{ }10 | 2.8 × 10\hat{ }10 |
| Evaluation | Patterning properties | A | B | A | A | A | A |
| | Peeling band voltage [V] | A | A | A | A | A | A |
| | Transmittance [%] | A | A | A | A | A | A |
| | Haze [%] | A | A | B | A | A | A |
| | Bend resistance | A | A | A | A | A | B |

TABLE 7

| | | | | | | Comparative | Comparative |
|---|---|---|---|---|---|---|---|
| | | | Example | Example | Example | Example | Example |
| | | | 13 | 14 | 15 | 1 | 2 |
| Photosensitive | Transparent film 1 | | Cerapeel | Cerapeel | Cerapeel | Cerapeel | Cerapeel |
| transfer film | | | 25 WZ | 25 WZ | 25 WZ | 25 WZ | 25 WZ |
| | Photosensitive | Composition | A-1 | A-1 | A-1 | A-1 | A-6 |
| | layer | Thickness [μm] | 4 | 4 | 4 | 4 | 4 |
| | Antistatic layer | Composition | B-4 | B-5 | B-6 | — | B-4 |
| | | Thickness [μm] | 0.1 | 0.1 | 0.1 | — | 0.1 |

| | | | | | | |
|---|---|---|---|---|---|---|
| | Transparent film 2 | 16QS62 | 16QS62 | 16QS62 | 16QS62 | 16QS62 |
| | Surface electrical resistance [Ω/□] | 3.1 × 10\hat{ }10 | 2.8 × 10\hat{ }10 | 2.9 × 10\hat{ }10 | (3.1 × 10\hat{ }16) | 2.5 × 10\hat{ }10 |
| Evaluation | Patterning properties | A | A | A | — | C |
| | Peeling band voltage [V] | A | A | A | C | A |
| | Transmittance [%] | A | A | A | A | A |
| | Haze [%] | A | A | A | A | A |
| | Bend resistance | A | A | A | A | A |

| | | | Comparative | Comparative | Comparative |
|---|---|---|---|---|---|
| | | | Example | Example | Example |
| | | | 3 | 4 | 5 |
| Photosensitive | Transparent film 1 | | Cerapeel | Polyethylene film GF-1 | Cerapeel |
| transfer film | | | 25 WZ | (product name, manufactured by | 25 WZ |
| | | | | Tamapoly Co., Ltd.) | |
| | Photosensitive | Composition | A-1 | A-7 | A-7 |
| | layer | Thickness [μm] | 12 | 20 | 9 |
| | Antistatic layer | Composition | B-1 | B-7 | B-1 |
| | | Thickness [μm] | 0.1 | 2 | 0.1 |

| | | | | |
|---|---|---|---|---|
| | Transparent film 2 | 16QS62 | Polyethylene terephthalate film G2 | 16QS62 |
| | | | (product name, manufactured by | |
| | | | Teijin Film Solution Co., Ltd.) | |
| | Surface electrical resistance [Ω/□] | 2.8 × 10\hat{ }10 | 1.0 × 10\hat{ }6 | 2.6 × 10\hat{ }10 |
| Evaluation | Patterning properties | A | A | A |
| | Peeling band voltage [V] | A | A | A |
| | Transmittance [%] | A | C | C |
| | Haze [%] | A | C | A |
| | Bend resistance | C | D | C |

TABLE 8

| | | Example 16 | Example 17 | Example 18 | Example 19 | Example 20 | Example 21 | Example 22 | Example 23 |
|---|---|---|---|---|---|---|---|---|---|
| Transparent film 1 | | Lumirror | Lumirror | Lumirror | Lumirror | Lumirror | Lumirror | Lumirror | Lumirror |
| | | 16QS62 | 16QS62 | 16QS62 | 16QS62 | 16QS62 | 16QS62 | 16QS62 | 16QS62 |
| Photosensitive | Composition | A-3 | A-3 | A-3 | A-3 | A-3 | A-3 | A-3 | A-3 |
| layer | Thickness [μm] | 8 | 8 | 8 | 8 | 8 | 4 | 1 | 0.5 |
| Antistatic layer | Composition | B-8 | B-9 | B-10 | B-11 | B-12 | B-11 | B-11 | B-11 |
| | Thickness [μm] | 0.1 | 0.1 | 0.1 | 0.1 | 0.1 | 0.1 | 0.1 | 0.1 |
| Transparent film 2 | | Lumirror | Lumirror | Lumirror | Lumirror | Lumirror | Lumirror | Lumirror | Lumirror |
| | | 16QS62 | 16QS62 | 16QS62 | 16QS62 | 16QS62 | 16QS62 | 16QS62 | 16QS62 |
| Surface electrical resistance [Ω/□] | | 2.8 × 10 11 | 2.2 × 10 10 | 4.0 × 10 11 | 3.4 × 10 10 | 2.3 × 10 9 | 5.6 × 10 10 | 6.2 × 10 10 | 4.1 × 10 10 |
| Patterning properties | | A | A | A | A | A | A | A | A |
| Peeling band voltage [V] | | A | A | A | A | A | A | A | A |
| Transmittance [%] | | A | A | A | A | A | A | A | A |
| Haze [%] | | A | A | A | A | A | A | A | A |
| Bend resistance | | A | A | A | A | A | A | A | A |
| Silver nanowire durability | | C | A | A | A | A | A | A | B |
| Region where | Detected fragment | C3H9N+ | C8H7SO3− | C8H7SO3− | C8H7SO3− | C8H7SO3− | C8H7SO3− | C8H7SO3− | C8H7SO3− |
| antistatic agent | Depth at which | 2.0 | 7.5 | 7.6 | 7.5 | 7.5 | 3.7 | 0.9 | 0.3 |
| is not detected | antistatic agent is | | | | | | | | |
| | not detected [μm] | | | | | | | | |
| | Proportion | 25% | 93% | 94% | 93% | 93% | 90% | 82% | 50% |

TABLE 9

| | | Example 24 | Example 25 | Example 26 | Example 27 | Example 28 | Example 29 | Example 30 | Example 31 |
|---|---|---|---|---|---|---|---|---|---|
| Transparent film 1 | | Lumirror | Lumirror | Lumirror | Lumirror | Lumirror | Lumirror | Lumirror | Lumirror |
| | | 16QS62 | 16QS62 | 16QS62 | 16QS62 | 16QS62 | 16QS62 | 16QS62 | 16QS62 |
| Photosensitive | Composition | A-8 | A-9 | A-10 | A-11 | A-12 | A-13 | A-14 | A-15 |
| layer | Thickness [μm] | 8 | 8 | 8 | 8 | 8 | 8 | 8 | 8 |
| Antistatic layer | Composition | B-11 | B-11 | B-11 | B-11 | B-11 | B-11 | B-11 | B-11 |
| | Thickness [μm] | 0.1 | 0.1 | 0.1 | 0.1 | 0.1 | 0.1 | 0.1 | 0.1 |
| Transparent film 2 | | Lumirror | Lumirror | Lumirror | Lumirror | Lumirror | Lumirror | Lumirror | Lumirror |
| | | 16QS62 | 16QS62 | 16QS62 | 16QS62 | 16QS62 | 16QS62 | 16QS62 | 16QS62 |
| Surface electrical resistance [Ω/□] | | 3.4 × 10 10 | 3.4 × 10 10 | 3.4 × 10 10 | 3.4 × 10 10 | 3.4 × 10 10 | 3.4 × 10 10 | 3.4 × 10 10 | 3.4 × 10 10 |
| Patterning properties | | A | A | A | A | A | A | A | A |
| Peeling band voltage [V] | | A | A | A | A | A | A | A | A |
| Transmittance [%] | | A | A | A | A | A | A | A | A |
| Haze [%] | | A | A | A | A | A | A | A | A |
| Bend resistance | | B | A | B | A | A | A | A | A |
| Silver nanowire durability | | A | A | A | A | A | A | A | B |
| Region where | Detected fragment | C8H7SO3− | C8H7SO3− | C8H7SO3− | C8H7SO3− | C8H7SO3− | C8H7SO3− | C8H7SO3− | C8H7SO3− |
| antistatic agent | Depth at which | 7.5 | 7.5 | 7.5 | 7.5 | 7.5 | 7.5 | 7.5 | 7.5 |
| is not detected | antistatic agent is | | | | | | | | |
| | not detected [μm] | | | | | | | | |
| | Proportion | 93% | 93% | 93% | 93% | 93% | 93% | 93% | 93% |

TABLE 10

| | | Example 32 | Example 33 | Example 34 | Example 35 | Example 36 | Example 37 | Example 38 | Example 39 |
|---|---|---|---|---|---|---|---|---|---|
| Transparent film 1 | | Lumirror | Lumirror | Lumirror | Lumirror | Lumirror | Lumirror | Lumirror | Lumirror |
| | | 16QS62 | 16QS62 | 16QS62 | 16QS62 | 16QS62 | 16QS62 | 16QS62 | 16QS62 |
| Photosensitive | Composition | A-16 | A-17 | A-17 | A-18 | A-19 | A-20 | A-21 | A-21 |
| layer | Thickness [μm] | 8 | 8 | 0.5 | 8 | 8 | 8 | 8 | 0.5 |
| Antistatic layer | Composition | B-11 | B-11 | B-11 | B-11 | B-11 | B-11 | B-11 | B-11 |
| | Thickness [μm] | 0.1 | 0.1 | 0.1 | 0.1 | 0.1 | 0.1 | 0.1 | 0.1 |
| Transparent film 2 | | Lumirror | Lumirror | Lumirror | Lumirror | Lumirror | Lumirror | Lumirror | Lumirror |
| | | 16QS62 | 16QS62 | 16QS62 | 16QS62 | 16QS62 | 16QS62 | 16QS62 | 16QS62 |
| Surface electrical resistance [Ω/□] | | 3.4 × 10 10 | 3.4 × 10 10 | 3.4 × 10 10 | 3.4 × 10 10 | 3.4 × 10 10 | 3.4 × 10 10 | 3.4 × 10 10 | 3.4 × 10 10 |
| Patterning properties | | A | A | A | A | A | A | A | A |
| Peeling band voltage [V] | | A | A | A | A | A | A | A | A |
| Transmittance [%] | | A | A | A | A | A | A | A | A |
| Haze [%] | | A | A | A | A | A | A | A | A |
| Bend resistance | | A | A | A | A | A | A | A | A |
| Silver nanowire durability | | A | A | B | A | A | A | A | A |
| Region where | Detected fragment | C8H7SO3− | C8H7SO3− | C8H7SO3− | C8H7SO3− | C8H7SO3− | C8H7SO3− | C8H7SO3− | C8H7SO3− |
| antistatic agent | Depth at which | 7.5 | 7.5 | 0.3 | 7.5 | 7.5 | 7.5 | 7.5 | 0.3 |
| is not detected | antistatic agent is | | | | | | | | |
| | not detected [μm] | | | | | | | | |
| | Proportion | 93% | 93% | 50% | 93% | 93% | 93% | 93% | 50% |

TABLE 11

| | | Example 40 | Example 41 | Example 42 | Example 43 | Example 44 | Example 45 | Example 46 | Example 47 |
|---|---|---|---|---|---|---|---|---|---|
| Transparent film 1 | | Lumirror | Lumirror | Lumirror | Lumirror | Lumirror | Lumirror | Lumirror | Lumirror |
| | | 16QS62 | 16QS62 | 16QS62 | 16QS62 | 16QS62 | 16QS62 | 16QS62 | 16QS62 |
| Photosensitive | Composition | A-22 | A-23 | A-24 | A-25 | A-26 | A-27 | A-28 | A-29 |
| layer | Thickness [μm] | 8 | 8 | 0.5 | 8 | 8 | 8 | 8 | 0.5 |
| Antistatic layer | Composition | B-11 | B-11 | B-11 | B-11 | B-11 | B-11 | B-11 | B-11 |
| | Thickness [μm] | 0.1 | 0.1 | 0.1 | 0.1 | 0.1 | 0.1 | 0.1 | 0.1 |
| Transparent film 2 | | Lumirror | Lumirror | Lumirror | Lumirror | Lumirror | Lumirror | Lumirror | Lumirror |
| | | 16QS62 | 16QS62 | 16QS62 | 16QS62 | 16QS62 | 16QS62 | 16QS62 | 16QS62 |
| Surface electrical resistance [Ω/□] | | 3.4 × 10 10 | 3.4 × 10 10 | 3.4 × 10 10 | 3.4 × 10 10 | 3.4 × 10 10 | 3.4 × 10 10 | 3.4 × 10 10 | 3.4 × 10 10 |
| Patterning properties | | A | A | A | A | A | A | A | A |
| Peeling band voltage [V] | | A | A | A | A | A | A | A | A |
| Transmittance [%] | | A | A | A | A | A | A | A | A |
| Haze [%] | | A | A | A | A | A | A | A | A |
| Bend resistance | | A | A | A | A | A | A | A | A |
| Silver nanowire durability | | A | A | B | A | A | A | A | A |
| Region where | Detected fragment | C8H7SO3− | C8H7SO3− | C8H7SO3− | C8H7SO3− | C8H7SO3− | C8H7SO3− | C8H7SO3− | C8H7SO3− |
| antistatic agent | Depth at which | 7.5 | 7.5 | 7.5 | 7.5 | 7.5 | 7.5 | 7.5 | 7.5 |
| is not detected | antistatic agent is | | | | | | | | |
| | not detected [μm] | | | | | | | | |
| | Proportion | 93% | 93% | 93% | 93% | 93% | 93% | 93% | 93% |

TABLE 12

| | | Example 48 | Example 49 | Example 50 | Example 51 |
|---|---|---|---|---|---|
| | | Lumirror | Lumirror | Lumirror | Lumirror |
| Transparent film 1 | | 16QS62 | 16QS62 | 16QS62 | 16QS62 |
| Photosensitive layer | Composition | A-30 | A-31 | A-28 | A-31 |
| | Thickness [μm] | 8 | 8 | 8 | 8 |
| Antistatic layer | Composition | B-11 | B-11 | B-13 | B-13 |
| | Thickness [μm] | 0.1 | 0.1 | 0.1 | 0.1 |
| | | Lumirror | Lumirror | Lumirror | Lumirror |
| Transparent film 2 | | 16QS62 | 16QS62 | 16QS62 | 16QS62 |
| Surface electrical resistance [Ω/□] | | 3.4 × 10\hat{ }10 | 3.4 × 10\hat{ }10 | 3.4 × 10\hat{ }10 | 3.4 × 10\hat{ }10 |
| Patterning properties | | A | A | A | A |
| Peeling band voltage [V] | | A | A | A | A |
| Transmittance [%] | | A | A | A | A |
| Haze [%] | | A | A | A | A |
| Bend resistance | | A | A | A | A |
| Silver nanowire durability | | A | A | B | A |
| Region where antistatic | Detected fragment | C8H7SO3— | C8H7SO3— | C8H7SO3— | C8H7SO3— |
| agent is not detected | Depth at which antistatic | 7.5 | 7.5 | 7.5 | 7.5 |
| | agent is not detected [μm] | | | | |
| | Proportion | 93% | 93% | 93% | 93% |

In Tables 8 to 12, the numerical value described in the column of “Proportion” is a value obtained by dividing the length (numerical value described in the column of “Depth at which antistatic agent is not detected” in Tables 8 to 12) from the surface of the photosensitive layer opposite to the antistatic layer to the region where fragment ions due to the antistatic agent were not detected by the total thickness of the photosensitive layer and the antistatic layer.

From Tables 6 to 12, it was found that, in each of the photosensitive transfer films of Examples 1 to 51, the antistatic layer can be patterned. In addition, it was found that, in each of the photosensitive transfer films of Examples 1 to 51, compared with the photosensitive transfer film of Comparative Example 2, in which the acrylic resin in the photosensitive layer is not alkali-soluble, the patterning properties were excellent.

From Tables 6 to 12, it was found that Examples 1 to 51 were superior in bend resistance as compared with Comparative Example 3 in which the thickness of the photosensitive layer exceeded 10 μm.

From Tables 6 to 12, it was found that Examples 1 to 51 were superior in transparency and bend resistance as compared with Comparative Example 4 in which the thickness of the photosensitive layer exceeded 10 μm and the photosensitive layer did not contain the alkali-soluble acrylic resin and Comparative Example 5 in which the photosensitive layer did not contain the alkali-soluble acrylic resin.

From Tables 4 to 6, it was found that Examples 1 to 23 can suppress peeling charge as compared with Comparative Example 1 having no antistatic layer.

From Tables 4 to 6, it was found that Examples 1 to 23 had a smaller haze than Comparative Example 4.

From Tables 8 to 12, it was found that, in Examples 17 to 51 in which the antistatic agent was a solvent-dispersed antistatic agent, compared with Example 16 in which the antistatic agent was not a solvent-dispersed antistatic agent, the region where the antistatic agent was not detected was larger, and silver nanowire durability was excellent.

### Examples 101 to 105

<Preparation of Additive Solution A>

0.51 g of silver nitrate powder was dissolved in 50 mL of pure water. 1 mol/L of aqueous ammonia was added to the obtained solution until the liquid became transparent. Thereafter, pure water was added to the obtained solution such that the total amount of the solution became 100 mL to prepare an additive solution A.

<Preparation of Additive Solution G>

0.5 g of glucose powder was dissolved in 140 mL of pure water to prepare an additive solution G

<Preparation of Additive Solution H>

0.5 g of hexadecyl-trimethylammonium bromide (HTAB) powder was dissolved in 27.5 mL of pure water to prepare an additive solution H.

<Preparation of Coating Liquid for Forming Silver Nanowire Layer>

After putting pure water (410 mL) into a three-neck flask, the additive solution H (82.5 mL) and the additive solution G (206 mL) were added thereto with a funnel while stirring at 20° C. The additive solution A (206 mL) was added to the obtained solution at a flow rate of 2.0 mL/min and a stirring rotation speed of 800 rpm (revolutions per minute; the same applies hereinafter). After 10 minutes, 82.5 mL of the additive solution H was added to the obtained solution. Thereafter, the obtained solution was heated to an internal temperature of 75° C. at 3° C./min. Thereafter, the stirring rotation speed was reduced to 200 rpm, and the solution was heated for 5 hours. After cooling the obtained solution, the solution was placed in a stainless steel cup, and ultrafiltration was performed using an ultrafiltration device in which an ultrafiltration module SIP1013 (manufactured by Asahi Kasei Corporation, molecular weight cut off: 6,000), a magnet pump, a stainless steel cup was connected with a silicon tube. In a case where the filtrate from the module reached 50 mL, 950 mL of distilled water was added to the stainless steel cup for washing. After repeating the above-described washing 10 times, concentration was performed until the amount of the solution reached 50 mL. The additive solution A, the additive solution and the additive solution H were repeatedly prepared by the above-described method and used for preparing a coating liquid for forming a silver nanowire layer.

The obtained concentrated solution was diluted with pure water and methanol (volume ratio of pure water and methanol: 60/40) to obtain a coating liquid for forming a silver nanowire layer.

<Production of Laminate for Evaluation>

A cycloolefin polymer (COP) film having a thickness of 100 μm was prepared as a transparent substrate. Next, a copper film was formed on one side of the substrate by a sputtering method to a thickness of 500 nm to produce a laminate having a laminated structure of copper film/substrate.

<Treatment of Laminate>

As a treatment liquid for the laminate produced above, treatment liquids C-1 to C-4 having the compositions shown in Table 13 below were prepared. Specifically, the specific azole compound was added to ion exchange water, and the mixture was stirred and mixed for 30 minutes to prepare a treatment liquid.

Next, the copper film side of the above-described laminate was showered for 40 seconds with the treatment liquid prepared above. After the treatment, the laminate was washed with pure water, air was blown to remove water, and heat treatment was performed at 80° C. for 1 minute to obtain a treated laminate.

<Etching of Copper Film>

Next, using a photosensitive transfer film with a negative type acrylic photosensitive layer (hereinafter, may be simply referred to as a “resist layer” in this paragraph) which could be developed with a 1% by mass sodium carbonate aqueous solution, a resist layer having a thickness of 1 μm was transferred to the surface of the laminate produced above on the copper film side to obtain a laminate having a laminated structure of resist layer/copper film/substrate. Next, the surface of the obtained laminate on the resist layer side was exposed with a metal halide lamp through a mask, and the laminate was immersed in a 1% by mass sodium carbonate aqueous solution to perform development treatment to the resist layer.

Next, the copper film in a portion where the patterned resist layer was not laminated was removed by etching using a ferric chloride aqueous solution as an etchant, and then the resist layer was peeled off using a stripper.

As a result, a laminate in which the copper film (lead wire) was formed on a peripheral portion on the transparent substrate was obtained.

<Formation of Patterned Layer Containing Silver Nanowires (Transparent Electrode for Touch Panel)>

Next, the coating liquid for forming a silver nanowire layer prepared above was applied to the copper film (lead wire) side of the laminate obtained above, and heated at 80° C. for 1 minute to produce a laminate having a laminated structure of layer containing silver nanowires/copper film (lead wire)/substrate. The amount of the coating liquid for forming a layer containing silver nanowires was set such that the wet film thickness was 20 μm, the layer thickness of the layer containing silver nanowires after drying was 30 nm, and the diameter of the silver nanowire was 17 nm and the major axis length thereof was 35 μm.

Next, using a photosensitive transfer film with a negative type acrylic photosensitive layer (hereinafter, may be simply referred to as a “resist layer” in this paragraph) which could be developed with a 1% by mass sodium carbonate aqueous solution, a resist layer having a thickness of 1 μm was transferred to the surface of the laminate produced above on the layer containing silver nanowires side to obtain a laminate having a laminated structure of resist layer/layer containing silver nanowires/copper film (lead wire)/substrate. Next, the surface of the obtained laminate on the resist layer side was exposed with a metal halide lamp through a mask of the touch panel electrode pattern, and the laminate was immersed in a 1% by mass sodium carbonate aqueous solution to perform development treatment to the resist layer.

Next, the layer containing silver nanowires and layer containing silver nanowires/copper film in a portion where the patterned resist layer was not laminated were removed by etching using a ferric chloride aqueous solution as an etchant, and then the resist layer was peeled off using a stripper.

By the above-described procedure, a patterned layer containing silver nanowires was obtained.

<Laminate of Photosensitive Transfer Film>

With regard to the photosensitive transfer film shown in Table 13 (that is, the photosensitive transfer film produced in Example 19), by peeling off the transparent film 1 and then laminating the exposed photosensitive layer on the laminate on a side of the layer containing silver nanowires, from which the resist layer had been peeled off, the photosensitive layer and the antistatic layer were transferred. The lamination process was performed using a vacuum laminator manufactured by MCK under conditions of a cycloolefin polymer film temperature: 40° C., a rubber roller temperature: 100° C., a linear pressure: 3 N/cm, and a transportation speed: 2 m/min.

Next, using a proximity type exposure machine (manufactured by Hitachi High-Tech Electronics Engineering Co., Ltd.) including an ultra-high pressure mercury lamp, the photosensitive layer was exposed in a patterned shape through the transparent film 2 with an exposure amount of 60 mJ/cm² (i ray) through a mask of protective film pattern.

After peeling off the transparent film 2, development treatment was performed at 32° C. in a 1% by mass aqueous solution of sodium carbonate for 60 seconds to remove the photosensitive layer and the antistatic layer at a connection portion with the outside. After the development treatment, ultrapure water was injected onto the photosensitive layer and the laminate with the antistatic layer from an ultrahigh pressure washing nozzle, and air was blown to remove the moisture.

Next, the photosensitive layer and the antistatic layer were further exposed to an exposure amount of 375 mJ/cm² without using an exposure mask, and then heat-cured by heating at 140° C. for 20 minutes, thereby producing a laminate having a laminated structure of cured layer of antistatic layer/cured layer of photosensitive layer/layer containing silver nanowires/copper film (lead wire)/substrate.

<Discoloration Evaluation of Copper>

After the laminate produced above was left to stand in an environment of 85° C. and 85% RH (relative humidity) for 100 hours, the copper film (lead wire) portion was observed from the cured layer side through the cured layer using an optical microscope (magnification: 50 times), and evaluation was performed based on the following evaluation standard.

A: no discolored portion was confirmed.

B: proportion of the discolored portion was 50% or less of the area of the copper film (wire).

C: proportion of the discolored portion was more than 50% and 80% or less of the area of the copper film (wire).

D: proportion of the discolored portion was more than 80% of the area of the copper film (wire).

The evaluation results are summarized in Table 13.

TABLE 13

| | | | Composition of treatment liquid (% by mass) | | | | Evaluation |
|---|---|---|---|---|---|---|---|
| | | | Specific azole compound | | | | result |
| | Photosensitive | Treatment | Benzimidazole | 1,2,4-Triazole | 5-Amino-1H-tetrazole | Ion exchange | Discoloration |
| | transfer film | liquid | pKa 5.67 | pKa 2.70 | pKa 1.29 | water | of copper |
| Example 101 | Example 19 | — | — | — | — | — | D |
| Example 102 | Example 19 | C-1 | 0.1 | — | — | 99.9 | C |
| Example 103 | Example 19 | C-2 | — | 0.1 | — | 99.9 | B |
| Example 104 | Example 19 | C-3 | — | — | 0.1 | 99.9 | A |
| Example 105 | Example 19 | C-4 | — | — | 1 | 99.0 | A |

The pKa values shown in Table 13 represent the pKa of the conjugate acid.

### Examples 201 to 204

A photosensitive transfer film and a laminate were produced in the same manner as in Example 51, except that the transparent film 1 and the transparent film 2 in Example 51 were changed as shown in Table 14, and the photosensitive transfer film and the laminate were evaluated in the same manner as in Example 51. All had the same evaluation results as in Example 51.

TABLE 14

| Example | Transparent film 2 | Transparent film 1 |
|---|---|---|
| 201 | LUMIRROR (registered trademark) 16FB40 | LUMIRROR (registered trademark) 16FB40 |
| | manufactured by Toray Industries, Inc. | manufactured by Toray Industries, Inc. |
| 202 | LUMIRROR (registered trademark) 16FB40 | ALPHAN (REGISTERED TRADEMARK) |
| | manufactured by Toray Industries, Inc. | FG-201 |
| | | manufactured by Oji F-Tex Co., Ltd. |
| 203 | LUMIRROR (registered trademark) 16FB40 | ALPHAN (REGISTERED TRADEMARK) |
| | manufactured by Toray Industries, Inc. | E-201F |
| | | manufactured by Oji F-Tex Co., Ltd. |
| 204 | COSMOSHINE (registered trademark) A4100 | ALPHAN (REGISTERED TRADEMARK) |
| | (thickness: 50 μm) | FG-201 |
| | manufactured by TOYOBO Co., Ltd. | manufactured by Oji F-Tex Co., Ltd. |

The disclosure of Japanese Patent Application No. 2019-064595 filed on Mar. 28, 2019, the disclosure of Japanese Patent Application No. 2019-091114 filed on May 14, 2019, and the disclosure of Japanese Patent Application No. 2019-175547 filed on Sep. 26, 2019 are incorporated in the present specification by reference. All documents, patent applications, and technical standards described in the present specification are incorporated herein by reference to the same extent as in a case of being specifically and individually noted that individual documents, patent applications, and technical standards are incorporated by reference.

What is claimed is:

1. A photosensitive transfer film comprising:
a photosensitive layer having a thickness of 10 μm or less; and
an antistatic layer,
wherein the photosensitive layer contains an alkali-soluble acrylic resin, a radically polymerizable compound having an ethylenically unsaturated group, and a photopolymerization initiator.

2. The photosensitive transfer film according to claim 1,
wherein a transparent film 1, the photosensitive layer, the antistatic layer, and a transparent film 2 are provided in this order.

3. The photosensitive transfer film according to claim 1,
wherein a surface electrical resistance value of the antistatic layer is 1.0×10¹²Ω/□ or less.

4. The photosensitive transfer film according to claim 1,
wherein an acid value of the alkali-soluble acrylic resin is 60 mgKOH/g or more.

5. The photosensitive transfer film according to claim 1,
wherein a thickness of the antistatic layer is 0.4 μm or less.

6. The photosensitive transfer film according to claim 1,
wherein the antistatic layer contains, as an antistatic agent, at least one compound selected from the group consisting of an ionic liquid, an ionic conductive polymer, an ionic conductive filler, and an electrically conductive polymer.

7. The photosensitive transfer film according to claim 1,
wherein an antistatic agent is not detected in a region from a surface of the photosensitive layer opposite to the antistatic layer to 40% of a total thickness of the photosensitive layer and the antistatic layer.

8. A manufacturing method of an antistatic pattern comprising, in the following order:
laminating the photosensitive layer and the antistatic layer of the photosensitive transfer film according to claim 1 on a base material in this order;
performing a pattern exposure of the photosensitive layer; and
developing the photosensitive layer.

9. A manufacturing method of the photosensitive transfer film according to claim 2, comprising:
applying a composition for the antistatic layer and a composition for the photosensitive layer on the transparent film 2 in this order.

10. A laminate comprising, in the following order:
a base material;
a transparent electrode layer;
a cured composition layer of a photosensitive composition, which has a patterned shape; and
an antistatic layer having the same patterned shape as the patterned shape of the cured composition layer.

11. The laminate according to claim 10,
wherein a surface electrical resistance value of the antistatic layer is 1.0×10¹²Ω/□ or less.

12. The laminate according to claim 10,
wherein a thickness of the antistatic layer is 0.4 μm or less.

13. The laminate according to claim 10,
wherein the antistatic layer contains, as an antistatic agent, at least one compound selected from the group consisting of an ionic liquid, an ionic conductive polymer, an ionic conductive filler, and an electrically conductive polymer.

14. The laminate according to claim 10,
wherein a thickness of the cured composition layer is 10 μm or less.

15. The laminate according to claim 10,
wherein an antistatic agent is not detected in a region from a surface of the cured composition layer opposite to the antistatic layer to 40% of a total thickness of the cured composition layer and the antistatic layer.

16. The laminate according to claim 10,
wherein the transparent electrode layer is a layer containing a silver nanowire.

17. A touch panel comprising:
the laminate according to claim 10.

18. A manufacturing method of a touch panel, comprising in the following order:
preparing a base material;
forming a transparent electrode for a touch panel on the base material using a silver conductive material;
forming a metal layer on the transparent electrode for a touch panel;
treating the metal layer with a treatment liquid containing at least one azole compound selected from the group consisting of an imidazole compound, a triazole compound, a tetrazole compound, a thiazole compound, and a thiadiazole compound;
forming a lead wire from the metal layer;
laminating the photosensitive layer and the antistatic layer of the photosensitive transfer film according to claim 1 on a surface of the base material on a side where the lead wire and the transparent electrode for a touch panel are arranged;
performing a pattern exposure of the photosensitive layer and the antistatic layer; and
developing the photosensitive layer and the antistatic layer to form a pattern.

19. A manufacturing method of a touch panel, comprising in the following order:
preparing a base material;
forming a metal layer on the base material;
treating the metal layer with a treatment liquid containing at least one azole compound selected from the group consisting of an imidazole compound, a triazole compound, a tetrazole compound, a thiazole compound, and a thiadiazole compound;
forming a lead wire from the metal layer;
forming a transparent electrode for a touch panel on the lead wire using a silver conductive material;
laminating the photosensitive layer and the antistatic layer of the photosensitive transfer film according to claim 1 on a surface of the base material on a side where the lead wire and the transparent electrode for a touch panel are arranged;
performing a pattern exposure of the photosensitive layer and the antistatic layer; and
developing the photosensitive layer and the antistatic layer to form a pattern.

20. The manufacturing method of a touch panel according to claim 18,
wherein a pKa of a conjugate acid of the at least one azole compound selected from the group consisting of the imidazole compound, the triazole compound, the tetrazole compound, the thiazole compound, and the thiadiazole compound is 4.00 or less.

21. A display device with a touch panel, comprising:
the touch panel according to claim 17; and
a display device.
